(19) United States
(12) Patent Application Publication
(10) Pub. No.: US 2026/0304835 A1
(43) Pub. Date: Oct. 1, 2026

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Masami JINTYOU, Shimotsuga (JP); Takahiro IGUCHI, Nikko (JP); Daisuke KUROSAKI, Utsunomiya (JP); Junichi KOEZUKA, Tochigi (JP)

(21) Appl. No.: 19/480,875

(22) PCT Filed: May 13, 2024
(86) PCT No.: PCT/IB2024/054612

§ 371 Date: Nov. 3, 2025

(30) Foreign Application Priority Data
May 19, 2023 (JP) 2023-082694

(51) Int. Cl. H10D 30/67

(52) U.S. Cl. CPC H10D 30/6728; H10D 30/6755

(57) ABSTRACT

A semiconductor device including a transistor having a minute size is provided. A semiconductor device includes a semiconductor layer, first to fourth conductive layers, and first and second insulating layers. The second conductive layer is provided over the first conductive layer and includes a first opening overlapping with the first conductive layer. The third conductive layer is provided over the second conductive layer and includes a second opening overlapping with the first opening. The first insulating layer is in contact with a sidewall of the first opening. The semiconductor layer is provided over the first conductive layer, the first insulating layer, and the third conductive layer. The semiconductor layer includes a first region in contact with the top surface of the first conductive layer, a second region in contact with the side surface of the first insulating layer, and a third region in contact with the top surface of the third conductive layer. The second insulating layer is provided over the semiconductor layer. The fourth conductive layer is provided over the second insulating layer. The fourth conductive layer faces the second conductive layer with the second insulating layer, the semiconductor layer, and the first insulating layer therebetween. Each of the first region and the third region has a lower resistance than the second region.

### TECHNICAL FIELD

One embodiment of the present invention relates to a transistor, a semiconductor device, a display apparatus, a display module, and an electronic device. One embodiment of the present invention relates to a method for manufacturing a transistor, a method for manufacturing a semiconductor device, and a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, a lighting device, an input device (e.g., a touch sensor), an input/output device (e.g., a touch panel), an electronic device including any of them, a method of driving any of them, and a method for manufacturing of any of them.

### BACKGROUND ART

Semiconductor devices including transistors have been widely used in display apparatuses and electronic devices, and the semiconductor devices have been required increasingly to achieve high integration and high-speed operation. In the case where semiconductor devices are used for high-resolution display apparatuses, highly integrated semiconductor devices are required, for example. The development of transistors having minute sizes is ongoing as one way of increasing the degree of integration of transistors.

In recent years, display apparatuses applicable to virtual reality (VR), augmented reality (AR), substitutional reality (SR), or mixed reality (MR) have been needed. VR, AR, SR, and MR are collectively referred to as XR (Extended Reality). Display apparatuses for XR have been desired to have higher resolution and higher color reproducibility so that realistic feeling and the sense of immersion can be enhanced. Examples of devices applicable to such display apparatuses include a liquid crystal display apparatus and a light-emitting apparatus including a light-emitting device (also referred to as a light-emitting element) such as an organic EL (Electro Luminescence) device or a light-emitting diode (LED).

Patent Document 1 discloses a display apparatus for VR using an organic EL device (also referred to as an organic EL element).

### REFERENCE

### Patent Document

[Patent Document 1] PCT International Publication No. 2018/087625

### SUMMARY OF THE INVENTION

### Problems to be Solved by the Invention

One object of one embodiment of the present invention is to provide a semiconductor device including a transistor having a minute size and a manufacturing method thereof. Another object of one embodiment of the present invention is to provide a small semiconductor device and a manufacturing method thereof. Another object of one embodiment of the present invention is to provide a semiconductor device including a transistor having high on-state current and a manufacturing method thereof. Another object of one embodiment of the present invention is to provide a semiconductor device having favorable electrical characteristics and a manufacturing method thereof. Another object of one embodiment of the present invention is to provide a semiconductor device having high reliability and a manufacturing method thereof. Another object of one embodiment of the present invention is to provide a method for manufacturing a semiconductor device with high productivity. Another object of one embodiment of the present invention is to provide a novel semiconductor device and a manufacturing method thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a semiconductor layer, a first conductive layer, a second conductive layer, a third conductive layer, a fourth conductive layer, a first insulating layer, a second insulating layer, a third insulating layer, and a fourth insulating layer. The first insulating layer is provided over the first conductive layer. The second conductive layer is provided over the first insulating layer and includes a first opening overlapping with the first conductive layer. The second insulating layer is provided over the second conductive layer. The third conductive layer is provided over the second insulating layer and includes a second opening overlapping with the first opening. The third insulating layer is in contact with a sidewall of the first opening. The semiconductor layer is provided over the first conductive layer, the third insulating layer, and the third conductive layer and includes a first region in contact with the top surface of the first conductive layer, a second region in contact with the side surface of the third insulating layer, and a third region in contact with the top surface of the third conductive layer. The fourth insulating layer is provided over the semiconductor layer. The fourth conductive layer is provided over the fourth insulating layer and faces the second conductive layer with the fourth insulating layer, the semiconductor layer, and the third insulating layer therebetween. The second region has a higher resistance than one or both of the first region and the third region.

In the above, the semiconductor layer preferably includes a metal oxide.

In the above, each of the first insulating layer and the second insulating layer preferably includes one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride.

In the above, it is preferable that the third insulating layer include a fifth insulating layer and a sixth insulating layer. It is preferable that the fifth insulating layer be provided in contact with the sidewall of the first opening and include one or more of silicon nitride, silicon nitride oxide, hafnium oxide, and aluminum oxide. It is preferable that the sixth insulating layer be provided over the fifth insulating layer to face the sidewall of the first opening with the fifth insulating layer therebetween and include one or more of silicon oxide and silicon oxynitride.

Another embodiment of the present invention is a semiconductor device including a semiconductor layer, a first conductive layer, a second conductive layer, a third conductive layer, a first insulating layer, a second insulating layer, a third insulating layer, and a fourth insulating layer. The first insulating layer is provided over the first conductive layer. The second conductive layer is provided over the first insulating layer and includes an opening overlapping with the first conductive layer. The second insulating layer is provided over the second conductive layer. The third insulating layer is in contact with a sidewall of the opening. The semiconductor layer is provided over the first conductive layer and the third insulating layer, is in contact with the top surface of the first conductive layer, the side surface of the third insulating layer, and the top surface of the second insulating layer, and includes a region extending beyond the first conductive layer and the second conductive layer in the plan view. The fourth insulating layer is provided over the semiconductor layer. The third conductive layer is provided over the fourth insulating layer and faces the second conductive layer with the fourth insulating layer, the semiconductor layer, and the third insulating layer therebetween.

In the above, the semiconductor layer preferably includes a metal oxide.

In the above, each of the first insulating layer and the second insulating layer preferably includes one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride.

In the above, it is preferable that the third insulating layer include a fifth insulating layer and a sixth insulating layer. It is preferable that the fifth insulating layer be provided in contact with the sidewall of the opening and include one or more of silicon nitride, silicon nitride oxide, hafnium oxide, and aluminum oxide. It is preferable that the sixth insulating layer be provided over the fifth insulating layer to face the sidewall of the opening with the fifth insulating layer therebetween and include one or more of silicon oxide and silicon oxynitride.

Another embodiment of the present invention is a semiconductor device including a semiconductor layer, a first conductive layer, a second conductive layer, a first insulating layer, a second insulating layer, and a third insulating layer. The first insulating layer is provided over the first conductive layer. The second conductive layer is provided over the first insulating layer and includes an opening overlapping with the first conductive layer. The second insulating layer is provided over the second conductive layer. The third insulating layer is in contact with a sidewall of the opening. The semiconductor layer is provided over the first conductive layer and the third insulating layer, is in contact with the top surface of the first conductive layer, the side surface of the third insulating layer, and the top surface of the second insulating layer, and includes a region extending beyond the first conductive layer and the second conductive layer in the plan view, and faces the second conductive layer with the third insulating layer therebetween.

In the above, the semiconductor layer preferably includes a metal oxide.

In the above, each of the first insulating layer and the second insulating layer preferably includes one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride.

In the above, it is preferable that the third insulating layer include a fourth insulating layer and a fifth insulating layer. It is preferable that the fourth insulating layer be provided in contact with the sidewall of the opening and include one or more of silicon nitride, silicon nitride oxide, hafnium oxide, and aluminum oxide. It is preferable that the fifth insulating layer be provided over the fourth insulating layer to face the sidewall of the opening with the fourth insulating layer therebetween and include one or more of silicon oxide and silicon oxynitride.

One embodiment of the present invention is a method for manufacturing a semiconductor device, including the following steps: forming a first conductive layer; forming a first insulating film over the first conductive layer; forming a second conductive layer over the first insulating film to include a region overlapping with the first conductive layer; forming a second insulating film over the second conductive layer and the first insulating film; forming a first conductive film over the second insulating film; removing part of the first insulating film, part of the second conductive layer, part of the second insulating film, and part of the first conductive film to expose the first conductive layer and to form a first insulating layer, a third conductive layer, a second insulating layer, and a fourth conductive layer; forming a third insulating film in contact with the top surface of the first conductive layer, the side surface of the first insulating layer, the side surface of the third conductive layer, the side surface of the second insulating layer, and the side surface and the top surface of the fourth conductive layer; removing a region of the third insulating film overlapping with the top surface of the first conductive layer and a region of the third insulating film overlapping with the top surface of the fourth conductive layer to form a third insulating layer in contact with the side surface of the first insulating layer, the side surface of the third conductive layer, the side surface of the second insulating layer, and the side surface of the fourth conductive layer; forming a semiconductor layer in contact with the top surface of the first conductive layer, the side surface of the third insulating layer, and the top surface of the fourth conductive layer; forming a fourth insulating layer in contact with the top surface of the semiconductor layer; and forming a fifth conductive layer being in contact with the top surface of the fourth insulating layer and including a region overlapping with the semiconductor layer and the third insulating layer in the plan view.

In the above, after the fourth insulating layer is formed, one or more of hydrogen, boron, carbon, nitrogen, phosphorus, sulfur, arsenic, aluminum, magnesium, silicon, and a noble gas are preferably supplied to the semiconductor layer through the fourth insulating layer.

### Effect of the Invention

An embodiment of the present invention can provide a semiconductor device including a miniaturized transistor and a manufacturing method thereof. Alternatively, one embodiment of the present invention can provide a small semiconductor device and a manufacturing method thereof. Another embodiment of the present invention can provide a semiconductor device including a transistor having high on-state current and a manufacturing method thereof. Another embodiment of the present invention can provide a semiconductor device having favorable electrical characteristics and a manufacturing method thereof. Another embodiment of the present invention can provide a semiconductor device having high reliability and a manufacturing method thereof. Another embodiment of the present invention can provide a method for manufacturing a semiconductor device with high productivity. Another embodiment of the present invention can provide a novel semiconductor device and a manufacturing method thereof.

Note that the description of these effects does not preclude the existence of other effects. One embodiment of the present invention does not necessarily have all of these effects.

Other effects can be derived from the description of the specification, the drawings, and the claims.

### BRIEF DESCRIPTION OF THE DRAWINGS

FIG. 1A is a plan view illustrating an example of a semiconductor device. FIG. 1B is a cross-sectional view illustrating an example of a semiconductor device.

FIG. 2 is a cross-sectional view illustrating an example of a semiconductor device.

FIG. 3 is a cross-sectional view illustrating an example of a semiconductor device.

FIG. 4A to FIG. 4D are cross-sectional views illustrating examples of a semiconductor device.

FIG. 5A and FIG. 5B are cross-sectional views illustrating examples of a semiconductor device.

FIG. 6A and FIG. 6B are cross-sectional views illustrating examples of a semiconductor device.

FIG. 7A and FIG. 7B are cross-sectional views illustrating examples of a semiconductor device.

FIG. 8A and FIG. 8B are cross-sectional views illustrating examples of a semiconductor device.

FIG. 9A and FIG. 9B are cross-sectional views illustrating examples of a semiconductor device.

FIG. 10 is a cross-sectional view illustrating an example of the semiconductor device.

FIG. 11A to FIG. 11C are cross-sectional views illustrating an example of a semiconductor device.

FIG. 12A to FIG. 12D are cross-sectional views illustrating an example of a method for manufacturing a semiconductor device.

FIG. 13A to FIG. 13D are cross-sectional views illustrating an example of a method for manufacturing a semiconductor device.

FIG. 14A to FIG. 14C are cross-sectional views illustrating the example of the method for manufacturing the semiconductor device.

FIG. 15 is a perspective view illustrating an example of a display apparatus.

FIG. 16 is a cross-sectional view illustrating an example of a display apparatus.

FIG. 17 is a cross-sectional view illustrating an example of a display apparatus.

FIG. 18 is a cross-sectional view illustrating an example of a display apparatus.

FIG. 19 is a cross-sectional view illustrating an example of a display apparatus.

FIG. 20 is a cross-sectional view illustrating an example of a display apparatus.

FIG. 21A and FIG. 21B are diagrams each illustrating a structure example of a display apparatus.

FIG. 22 is a cross-sectional view illustrating a structure example of a display apparatus.

FIG. 23 is a cross-sectional view illustrating a structure example of a display apparatus.

FIG. 24 is a cross-sectional view illustrating a structure example of a display apparatus.

FIG. 25 is a block diagram of a display apparatus.

FIG. 26A to FIG. 26D are each a circuit diagram of a pixel circuit.

FIG. 27A to FIG. 27D are each a circuit diagram of a pixel circuit.

FIG. 28A and FIG. 28B are each a circuit diagram of a pixel circuit.

FIG. 29A to FIG. 29D are diagrams each illustrating an example of an electronic device.

FIG. 30A to FIG. 30F are diagrams each illustrating an example of an electronic device.

FIG. 31A to FIG. 31G are diagrams each illustrating an example of an electronic device.

FIG. 32A is an optical micrograph relating to Example. FIG. 32B is a cross-sectional STEM image relating to Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

In addition, the position, size, range, or the like of each structure illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

A transistor is a kind of semiconductor element and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification and the like.

Functions of a “source” and a “drain” are sometimes replaced with each other when a transistor of opposite polarity is used or when the direction of current is changed in circuit operation, for example. Thus, the terms “source” and “drain” can be used interchangeably in this specification and the like. Note that a source and a drain of a transistor can also be referred to as a source terminal and a drain terminal or a source electrode and a drain electrode, for example, as appropriate depending on circumstances.

A “gate” and a “back gate” can be interchanged with each other. Thus, the terms “gate” and “back gate” can be used interchangeably in this specification and the like. Note that a gate and a back gate of a transistor can also be referred to as a gate electrode and a back gate electrode, for example, as appropriate depending on circumstances.

In this specification and the like, “connection” includes “electrical connection”.

The expression “A and B are electrically connected” means the structure in which transmission and reception of an electric signal or interaction of a potential occurs between A and B at a certain timing during a circuit operation, among structures in which A and B are connected to each other without an insulator therebetween (a structure in which A and B are connected with a conductor or a semiconductor therebetween and a structure in which A and B are in contact with each other). In other words, even when the circuit operation has a timing during which neither transmission and reception of an electric signal nor interaction of a potential occurs between A and B, the expression “A and B are electrically connected” can be used as long as transmission and reception of an electric signal or interaction of a potential occurs between A and B in another timing in the circuit operation.

The expression “electrical connection” includes connection not through a circuit element (e.g., a transistor, with the exception of a wiring) (direct connection) and connection through one or more circuit elements (indirect connection).

Examples where “A and B are electrically connected” include the case where A and B are connected to each other not through a circuit element and the case where A and B are connected to each other through a source and a drain of one or more transistors. Note that this is based on the assumption that transmission and reception of an electrical signal or interaction of a potential occurs between A and B at a certain timing.

Examples of the case where the expression “A and B are electrically connected” cannot be used because A and B are connected through an insulator include the case where a dielectric of a capacitor, a gate insulating film of a transistor, or the like is positioned between A and B.

Examples of the case where the expression “A and B are electrically connected” cannot be used because neither transmission and reception of an electric signal nor interaction of a potential occurs between A and B although A and B are connected not through an insulator include the case where a potential V is supplied from a power source, a signal source, or the like to the path between A and B (except for the case where the potential V is supplied through a circuit element), and the case where A and C are connected through a source and a drain of a transistor TrP and B and C are connected through a source and a drain of a transistor TrQ, but both of the transistors TrP and TrQ are not in the on state at the same time.

In this specification and the like, a structure where at least light-emitting layers of light-emitting devices having different emission wavelengths are separately formed is sometimes referred to as an SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In this specification and the like, a tapered shape refers to a shape such that at least part of the side surface of a component is inclined with respect to a substrate surface or a formation surface. For example, a tapered shape refers to a shape including a region where the angle formed by the inclined side surface and the substrate surface or the formation surface (also referred to as a taper angle) is less than 90°. Note that the side surface, the substrate surface, and the formation surface of the component are not necessarily completely flat and may have a substantially planar shape with a small curvature or a substantially planar shape with slight unevenness.

In this specification and the like, step disconnection refers to a phenomenon in which a layer, a film, or an electrode is split because of the shape of the formation surface (e.g., a step).

In this specification and the like, the expression “top surface shapes (also referred to as shapes in the plan view or outline shapes) are substantially the same” means that outlines of stacked layers at least partly overlap with each other. For example, the case of processing the upper layer and the lower layer with use of the same mask pattern or mask patterns that are partly the same is included. Note that, in some cases, the outlines do not strictly overlap with each other and the upper layer is positioned inward from the lower layer or the upper layer is positioned outward from the lower layer; such cases are also represented by the expression “top surface shapes are substantially the same”.

In this specification and the like, the expression “substantially level” indicates a structure in which levels from a reference surface (e.g., a flat surface such as a substrate surface) are substantially the same in a cross-sectional view. For example, surfaces processed by planarization treatment (typically, chemical mechanical polishing (CMP) treatment) are substantially level with each other. Note that surfaces processed by planarization treatment are not exactly level with each other in some cases depending on materials of films or the like; such a case is also represented by the expression “substantially level” in this specification and the like.

### Embodiment 1

In this embodiment, a transistor of one embodiment of the present invention, a manufacturing method thereof, and the like will be described.

One embodiment of the present invention is a semiconductor device that includes a transistor. The transistor has a structure in which a source electrode and a drain electrode are provided at different levels with respect to a substrate surface to overlap each other and drain current flows in a height direction (vertical direction). Thus, the transistor can be reduced in size as compared with a transistor having a structure in which a source electrode and a drain electrode are provided on the same plane. The transistor having the above-described structure enables miniaturization and high integration of the semiconductor device.

The transistor includes a first gate electrode (also referred to as a top gate electrode or a front gate electrode) provided with a semiconductor layer functioning as a channel formation region therebetween and a second gate electrode (also referred to as a bottom gate electrode or a back gate electrode). When the transistor includes two gate electrodes provided with the semiconductor layer therebetween, the controllability of carriers in the channel formation region can be increased as compared with the case where the transistor includes only one gate electrode. Thus, the transistor including two gate electrodes can improve the saturation characteristics of current that flows when operating in a saturation region (i.e., the amount of drain current hardly changes with respect to an increase in drain voltage), compared with a transistor including only one gate electrode, for example.

A gate insulating layer (a first gate insulating layer, a second gate insulating layer) of the transistor includes oxygen and can supply oxygen to the semiconductor layer (specifically, a channel formation region) by heat treatment or the like. Accordingly, in the case of using a metal oxide as a material of the semiconductor layer, for example, oxygen vacancies in the metal oxide can be repaired, whereby the electrical characteristics and reliability of the transistor can be improved.

In manufacture of the transistor, treatment for supplying (also referred to as adding or implanting) impurities such as boron to a semiconductor layer (mainly, a source region and a drain region) is performed. Thus, the resistance of the source region and the drain region can be lower than that of channel formation region. Thus, a higher on-state current than that of a transistor not subjected to the above-described treatment for supplying impurities can be obtained.

A specific structure example of a transistor of one embodiment of the present invention will be described below.

### Structure Example

### Structure Example 1

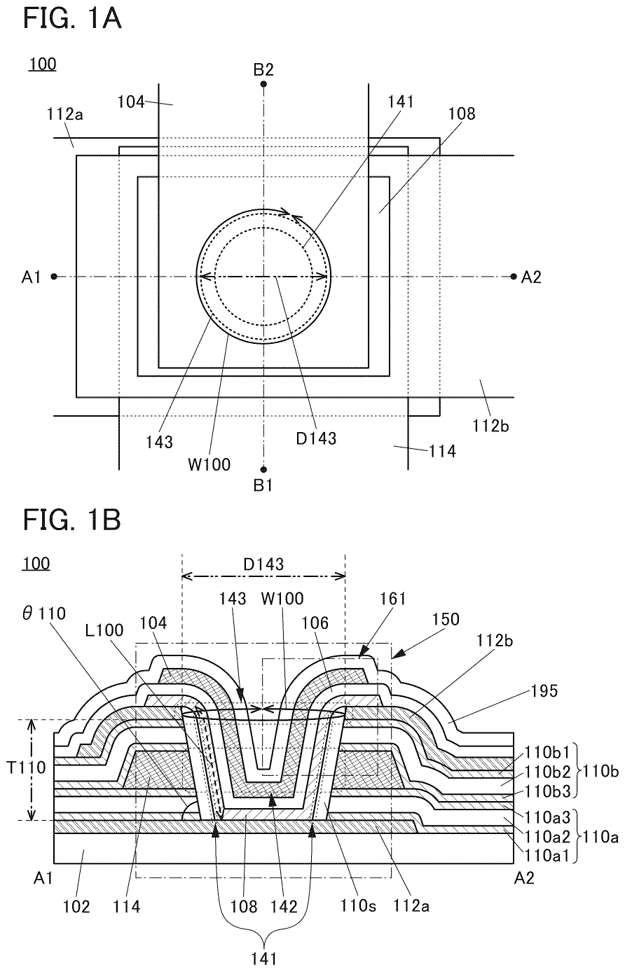

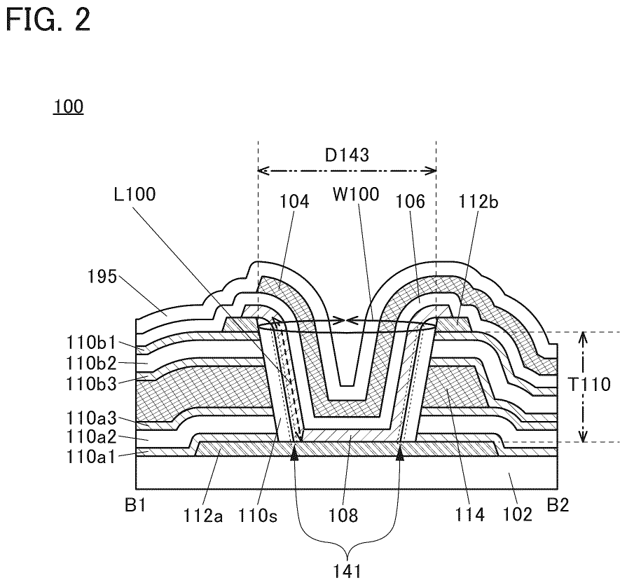

FIG. 1A illustrates a plan view (also referred to as a top view) of a transistor 100. FIG. 1B illustrates a cross-sectional view along the dashed-dotted line A1-A2 in FIG. 1A, and FIG. 2 is a cross-sectional view along the dashed-dotted line B1-B2 in FIG. 1A. Note that some components (e.g., an insulating layer) of the transistor 100 are not illustrated in FIG. 1A. Some components are not illustrated in plan views of transistors and the like in the following drawings, as in FIG. 1A.

The transistor 100 is provided over the substrate 102. The transistor 100 includes a conductive layer 104, an insulating layer 106, a semiconductor layer 108, a conductive layer 114, an insulating layer 110s, a conductive layer 112a, and a conductive layer 112b. The conductive layer 104 functions as a first gate electrode. The conductive layer 114 functions as a second gate electrode. Part of the insulating layer 106 functions as a first gate insulating layer. The insulating layer 110s functions as a second gate insulating layer. The conductive layer 112a functions as one of a source electrode and a drain electrode, and the conductive layer 112b functions as the other of the source electrode and the drain electrode. In the semiconductor layer 108 between the source electrode and the drain electrode, the whole region overlapping with the gate electrode with the gate insulating layer therebetween functions as a channel formation region. In the semiconductor layer 108, a region in contact with the source electrode functions as a source region, and a region in contact with the drain electrode functions as a drain region.

The detailed structure of the transistor 100 will be described.

The conductive layer 112a is provided over the substrate 102. An insulating layer 110a (an insulating layer 110a1, an insulating layer 110a2, and an insulating layer 110a3) is provided over the conductive layer 112a and the substrate 102. The conductive layer 114 is provided over the insulating layer 110a. An insulating layer 110b (an insulating layer 110b1, an insulating layer 110b2, and an insulating layer 110b3) is provided over the insulating layer 110a and the conductive layer 114. The conductive layer 112b is provided over the insulating layer 110b. The insulating layer 110a and the insulating layer 110b each include a region sandwiched between the conductive layer 112a and the conductive layer 112b. The conductive layer 112a includes a region overlapping with the conductive layer 112b with the insulating layer 110a and the insulating layer 110b therebetween.

FIG. 1B, FIG. 2, and the like illustrate a structure in which the insulating layer 110a has a stacked-layer structure of the insulating layer 110a1, the insulating layer 110a2 over the insulating layer 110a1 , and the insulating layer 110a3 over the insulating layer 110a2. FIG. 1B, FIG. 2, and the like also illustrate a structure in which the insulating layer 110b has a stacked-layer structure of the insulating layer 110b3, the insulating layer 110b2 over the insulating layer 110b3, and the insulating layer 110b1 over the insulating layer 110b2.

In FIG. 1B, FIG. 2, and the like, the conductive layer 114 includes a region sandwiched between the insulating layer 110a3 and the insulating layer 110b3. The insulating layer 110a3 includes a region in contact with the bottom surface (the surface on the substrate 102 side) of the conductive layer 114, for example. The insulating layer 110b3 includes a region in contact with the top surface of the conductive layer 114, for example.

The insulating layer 110a, the conductive layer 114, the insulating layer 110b, and the conductive layer 112b each have an opening. The openings each include a region overlapping with the conductive layer 112a, for example.

The insulating layer 110s is formed over the conductive layer 112a. The insulating layer 110s is provided along the sidewall of each of an opening included in the insulating layer 110a (the region is not illustrated in the drawing), an opening 142 included in the conductive layer 114, an opening included in the insulating layer 110b (the region is not illustrated in the drawing), and an opening 143 included in the conductive layer 112b (i.e., the side surface of the insulating layer 110a, the side surface of the conductive layer 114, the side surface of the insulating layer 110b, and the side surface of the conductive layer 112b at the side facing the openings). In FIG. 1B, FIG. 2, and the like, the sidewalls of the openings in the insulating layer 110a, the conductive layer 114, the insulating layer 110b, and the conductive layer 112b form a continuous side surface, and the insulating layer 110s is formed along the continuous side surface. The insulating layer 110s is in contact with the top surface of the conductive layer 112a, the side surface of the insulating layer 110a, the side surface of the conductive layer 114, the side surface of the insulating layer 110b, and the side surface of the conductive layer 112b in the openings. The insulating layer 110s is sometimes referred to as a sidewall, a sidewall insulating layer, a sidewall protective layer, or the like.

Each of the opening 142 and the opening 143 includes a region overlapping with the conductive layer 112a. The opening 142 and the opening 143 have an overlapping region.

The transistor 100 includes a concave portion (also referred to as a depression) whose bottom portion is the top surface of the conductive layer 112a and whose inner wall is the side surface (a sidewall 141) of the insulating layer 110s. The semiconductor layer 108 is provided along the concave portion.

The semiconductor layer 108 overlaps with the conductive layer 112a in a region located inward from the sidewall 141 of the insulating layer 110s in the plan view. In the region, the semiconductor layer 108 is in contact with the top surface of the conductive layer 112a, for example.

The semiconductor layer 108 overlaps with the conductive layer 112b in a region located outward from the sidewall 141 of the insulating layer 110s in the plan view. In the region, the semiconductor layer 108 is in contact with the top surface of the conductive layer 112b, for example.

Since the bottom surface of the semiconductor layer 108 (the substrate 102 side) is in contact with the source electrode and the drain electrode, the transistor 100 can be referred to as a bottom-contact transistor.

The semiconductor layer 108 includes a region provided along the top surface of the conductive layer 112a, a region provided along the sidewall 141 of the insulating layer 110s, and a region provided along the top surface of the conductive layer 112b.

The semiconductor layer 108 includes a region facing the sidewall of the opening 142 (i.e., the side surface of the conductive layer 114 on the side facing the opening 142) with the insulating layer 110s therebetween. In the region, the semiconductor layer 108 is preferably in contact with the sidewall 141 of the insulating layer 110s.

The insulating layer 106 is provided over the semiconductor layer 108. The insulating layer 106 includes a region overlapping with the conductive layer 112a with the semiconductor layer 108 therebetween, a region facing the conductive layer 114 with the semiconductor layer 108 and the insulating layer 110s therebetween, and a region overlapping with the conductive layer 112b with the semiconductor layer 108 therebetween.

In FIG. 1B, FIG. 2, and the like, the insulating layer 106 includes a region facing the top surface of the conductive layer 112a with the semiconductor layer 108 therebetween, a region facing the side surface of the conductive layer 114 with the semiconductor layer 108 and the insulating layer 110s therebetween, and a region facing the top surface of the conductive layer 112b with the semiconductor layer 108 therebetween.

The conductive layer 104 is provided over the insulating layer 106. The conductive layer 104 includes a region facing the semiconductor layer 108, which is positioned between the conductive layer 112a and the conductive layer 112b, with the insulating layer 106 therebetween. The conductive layer 104 includes a region facing the conductive layer 114 with the insulating layer 106, the semiconductor layer 108, and the insulating layer 110s therebetween.

In the transistor 100, the conductive layer 104 and the conductive layer 112a are insulated from each other by the insulating layer 106 provided therebetween. In the transistor 100, the conductive layer 104 and the conductive layer 112b are insulated from each other by the insulating layer 106 provided therebetween.

The semiconductor layer 108 is provided along the concave portion whose bottom portion is the top surface of the conductive layer 112a and whose inner wall is the sidewall 141 of the insulating layer 110s; the semiconductor layer 108 has a shape along the concave portion. The insulating layer 106 is provided over the semiconductor layer 108 and has a shape along the concave portion. The conductive layer 104 is provided over the insulating layer 106. Although FIG. 1B and the like illustrate an example in which the conductive layer 104 has a shape along the concave portion, one embodiment of the present invention is not limited thereto. The conductive layer 104 can be provided over the semiconductor layer 108 and the insulating layer 106 to fill the concave portion. Thus, the conductive layer 104 can be formed thick and have a lower electric resistance.

The insulating layer 195 is provided to cover the conductive layer 112a, the semiconductor layer 108, the conductive layer 112b, the insulating layer 106, the conductive layer 104, and the like included in the transistor 100. The insulating layer 195 functions as a protective layer of the transistor 100.

One of the conductive layer 104 and the conductive layer 114 can function as a gate electrode (a first gate electrode), and the other can function as a back gate electrode (a second gate electrode), for example. The conductive layer 104 and the conductive layer 114 are preferably placed such that the channel formation region of the semiconductor layer 108 is sandwiched between them.

By supplying a potential to the back gate (a second gate), the field-effect mobility of the transistor can be increased. By changing the potential of the back gate, the threshold voltage of the transistor can be changed. The potential of the back gate can be the same as the potential of the gate (a first gate). Alternatively, the potential of the back gate may be a ground potential or a given potential. The potential of the back gate may be the same as the potential of the source or the drain.

In the case where the same potential is supplied to the back gate and the gate, the back gate and the gate are electrically connected to each other to establish electrical continuity. In the case where the same potential is supplied to the back gate and the source or the drain, the back gate and the source or the drain are electrically connected to each other to establish electrical continuity. When the gate or the back gate is electrically connected to the source, the reliability can be increased, for example. When the gate or the back gate is electrically connected to the drain, the transistor can function as a diode, for example.

In the case where the potential of the back gate is a ground potential or a given potential, a common wiring electrically connected to back gates of a plurality of transistors may be provided and a potential may be supplied to the common wiring.

When including back gates, a plurality of transistors can have smaller variations in characteristics in some cases. For example, variations in threshold voltage between a plurality of transistors can be reduced in some cases.

The top surface shape of each of the opening 142, the opening 143, and the sidewall 141 can be a circle or an ellipse, for example. The top surface shape of each of the opening 142, the opening 143, and the sidewall 141 may be a polygon such as a triangle, a tetragon (including a rectangle, a rhombus, and a square), or a pentagon or a polygon with rounded corners. The top surface shape of each of the opening 142 and the opening 143 is preferably a circle as illustrated in FIG. 1A. When the top surface shape of each of the opening 142 and the opening 143 is a circle, the processing accuracy at the time of forming the opening 142 and the opening 143 can be enhanced so that the opening 142 and the opening 143 having minute sizes can be formed. In this specification and the like, a circular shape is not necessarily a perfect circular shape.

The top surface shape of the sidewall 141 of the insulating layer 110s changes depending on the shapes of the opening in the insulating layer 110a, the opening 142 in the conductive layer 114, the opening in the insulating layer 110b, and the opening 143 in the conductive layer 112b. When the shapes of the openings are each a circle, the top surface shape of the sidewall 141 can also be a circle. The sidewall 141 having a circular top surface shape can improve coverage with the semiconductor layer 108 provided along the sidewall 141. In the case where the top surface of the sidewall 141 has a corner, for example, the thickness of the semiconductor layer 108 and the thickness of the insulating layer 106 formed over the semiconductor layer 108 in the corner region are sometimes non-uniform as compared to those in a region where the top surface is linear or circular. In the region where the thicknesses are non-uniform, the concentration of the electric field between the semiconductor layer 108 and the gate electrode might occur. The concentration of the electric field might degrade the transistor. The sidewall 141 having a circular top surface shape can increase the reliability of the transistor.

The opening in the insulating layer 110a, the opening 142 in the conductive layer 114, the opening in the insulating layer 110b, and the opening 143 in the conductive layer 112b can be formed in the following manner, for example: a mask is formed on a surface to be processed, and an etching step is performed. A resist mask or a hard mask formed of an insulating layer or a conductive layer may be used as the mask. After the mask is formed, the opening 143 of the conductive layer 112b, the opening of the insulating layer 110b, the opening 142 of the conductive layer 114, and the opening of the insulating layer 110a are successively formed, whereby the mask formation step and the opening formation steps can be successively performed. In addition, the diameters and the positions of the openings can be the same as or substantially to the same as each other. In this specification and the like, a step of successively forming a plurality of openings using the same mask as described above is sometimes referred to as collective formation of openings.

The insulating layer 110s is formed after the collective formation of the openings, whereby the structure illustrated in FIG. 1B, FIG. 2, and the like can be formed. Since the openings are formed to have substantially equal diameters through the step of forming the openings, coverage with the insulating layer 110s can be improved.

Note that the opening in the insulating layer 110a, the opening 142 in the conductive layer 114, the opening in the insulating layer 110b, and the opening 143 in the conductive layer 112b are not necessarily formed successively. For example, a mask may be formed every time the opening is formed.

The channel length and the channel width of the transistor 100 will be described.

In the semiconductor layer 108, a region in contact with the conductive layer 112a functions as one of the source region and the drain region, a region in contact with the conductive layer 112b functions as the other of the source region and the drain region, and a region between the source region and the drain region functions as the channel formation region.

The channel length of the transistor 100 is a distance between the source region and the drain region. In each of FIG. 1B and FIG. 2, a channel length L100 of the transistor 100 is indicated by a dashed double-headed arrow. In FIG. 1B and FIG. 2, the distance along the insulating layer 110s of the semiconductor layer 108 between the top surface of the conductive layer 112a and the top surface of the conductive layer 112b is shown as the channel length L100 of the transistor 100.

Note that as the channel length L100 of the transistor 100, a thickness T110 that is the total thickness of the insulating layer 110a, the conductive layer 114, and the insulating layer 110b in a region between the top surface of the conductive layer 112a and the bottom surface of the conductive layer 112b (the thickness T110 is indicated by a dashed-dotted double-headed arrow in FIG. 1B and FIG. 2) is sometimes used. Alternatively, the sum of the thickness T110 and the thickness of the conductive layer 112b is sometimes used as the channel length L100 of the transistor 100.

Here, the channel length L100 of the transistor 100 is determined by, for example the thickness of the insulating layer 110a, the thickness of the conductive layer 114, the thickness of the insulating layer 110b, an angle θ110 formed between the formation surface of the insulating layer 110s (here, the side surface of the insulating layer 110a, the side surface of the conductive layer 114, and the side surface of the insulating layer 110b) and the formation surface of the insulating layer 110a (here, the top surface of the conductive layer 112a), and is not affected by the performance of a light-exposure apparatus used to manufacture the transistor. Thus, the channel length L100 can be a value smaller than that of the definition limit of a light-exposure apparatus, which enables a transistor having a minute size.

The channel length L100 can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm. For example, the channel length L100 can be greater than or equal to 100 nm and less than or equal to 1 μm.

The thickness T110 can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm. The thickness T110 can be set as appropriate so as to be the desired channel length L100.

The angle θ110 can be, for example, greater than or equal to 30° and less than or equal to 90°, greater than or equal to 35° and less than or equal to 85°, greater than or equal to 40° and less than or equal to 80°, greater than or equal to 45° and less than or equal to 80°, greater than or equal to 50° and less than or equal to 80°, greater than or equal to 55° and less than or equal to 80°, greater than or equal to 60° and less than or equal to 80°, greater than or equal to 65° and less than or equal to 80°, or greater than or equal to 70° and less than or equal to 80°. The angle θ110 can be set as appropriate so as to be the desired channel length L100.

Note that the insulating layer 110s is sometimes not along the entire regions of the sidewalls of the openings in the insulating layer 110a, the conductive layer 114, the insulating layer 110b, and the conductive layer 112b, but for example, provided along the sidewalls of the openings included in the insulating layer 110a, the conductive layer 114, and the insulating layer 110b, and part of the sidewall of the opening 143 included in the conductive layer 112b.

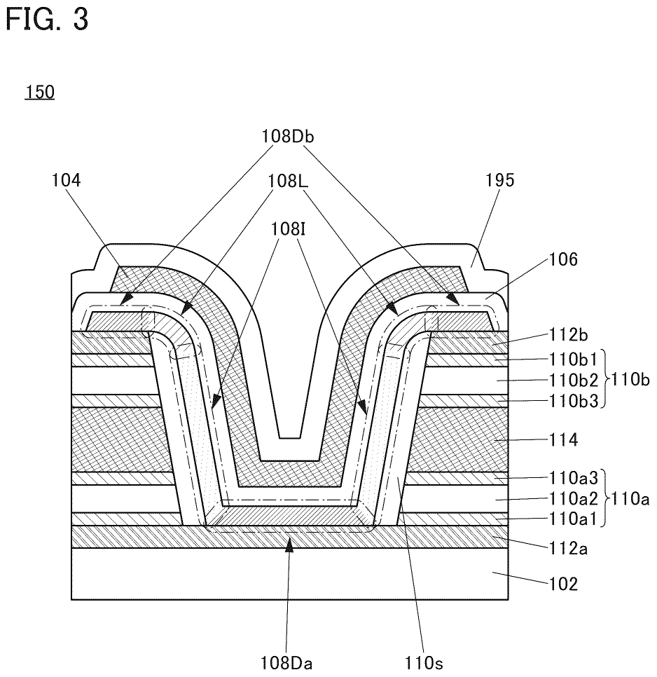

FIG. 3 illustrates an enlarged cross-sectional view of a region 150 of the transistor 100 illustrated in FIG. 1B.

As illustrated in FIG. 3, the semiconductor layer 108 includes a region 108I, a region 108Da and a region 108Db provided to sandwich the region 108I, and a region 108L sandwiched between the region 108I and the region 108Db.

The region 108Da corresponds to a region of the semiconductor layer 108 that is in contact with the conductive layer 112a. At least part of the region 108Da functions as one of the source region and the drain region of the transistor 100. The region 108Db corresponds to a region of the semiconductor layer 108 that is in contact with the conductive layer 112b. At least part of the region 108Db functions as the other of the source region and the drain region of the transistor 100. As illustrated in FIG. 1A, the conductive layer 112b is in contact with the entire outer circumference of the opening 143 overlapping with the semiconductor layer 108. Thus, the other of the source region and the drain region of the transistor 100 can be formed in the entire outer circumference of a portion of the semiconductor layer 108 that is formed at the same level as the conductive layer 112b.

The region 108I functions as the channel formation region of the transistor 100. Part of the region 108L (the region on the region 108Db side) can function as the other of the source region and the drain region of the transistor 100, and another part (the region on the region 108I side) can function as the channel formation region of the transistor 100. In FIG. 3, a substantially flat region of the region of the semiconductor layer 108 sandwiched between the region 108Da and the region 108Db that is in contact with the sidewall 141 of the insulating layer 110s is denoted by the region 108I, and a region of the semiconductor layer 108 that is in contact with a curved region of the insulating layer 110s is denoted by the region 108L.

The region 108Da and the region 108Db functioning as the source region and the drain region are each a region having a lower resistance than the region 108I functioning as the channel formation region and part of the region 108L that can function as the channel formation region. It can also be said that the region 108I and part of the region 108L have higher resistance than the region 108Da and the region 108Db. That is, the region 108Da and the region 108Db can each be regarded as a region having a higher density of oxygen vacancies or a higher impurity concentration than the region 108I and part of the region 108L.

As described above, part of the region 108L (the region on the region 108Db side) can function as the other of the source region and the drain region, and another part of the region 108L (the region on the region 108I side) can function as the channel formation region. Thus, the region 108L can be regarded as a region including both a region having a resistance value substantially equal to or close to that of the region 108Da and the region 108Db and a region having a resistance value substantially equal to or close to that of the region 108I. That is, the region 108L can be regarded as a region including both a region having a density of oxygen vacancy or an impurity concentration substantially equal to or close to those of the region 108Da and the region 108Db and a region having a density of oxygen vacancy or an impurity concentration substantially equal to or close to that of the region 108I.

In the transistor of one embodiment of the present invention, the concentration of the impurity element, for example, the concentration of one or more of hydrogen, boron, carbon, nitrogen, phosphorus, sulfur, arsenic, aluminum, magnesium, silicon, and a noble gas in each of the region 108Da and the region 108Db is higher than the concentration of the impurity element in the region 108I and part of the region 108L. Note that typical examples of a noble gas include helium, neon, argon, krypton, and xenon. It is particularly preferable that the concentration of one or more of boron, phosphorus, aluminum, magnesium, and silicon in each of the region 108Da and the region 108Db be higher than the concentration of the impurity element in the region 108I and part of the region 108L. Accordingly, the resistance of the region 108Da and the region 108Db can be reduced, so that the on-state current of the transistor can be increased.

As described above, in the transistor of one embodiment of the present invention, the channel formation region, the source region, and the drain region can be formed in a region overlapping with the opening 143 in the plan view. Thus, the area occupied by the transistor can be reduced as compared with a planar transistor in which a channel formation region, a source region, and a drain region are provided separately on a plane parallel to the substrate surface. Accordingly, high integration of the semiconductor device can be achieved.

Although FIG. 3 and the like illustrate an example in which the sidewalls of the openings in the insulating layer 110a, the conductive layer 114, the insulating layer 110b, and the conductive layer 112b each have a tapered shape with respect to the substrate surface, one embodiment of the present invention is not limited thereto. The sidewalls may be formed perpendicular to the substrate surface. In that case, the area occupied by a transistor can be reduced as described above, which is preferable. Meanwhile, as illustrated in FIG. 3 and the like, the sidewalls preferably each have a tapered shape to improve coverage with a film (e.g., the semiconductor layer 108) formed to cover the sidewalls.

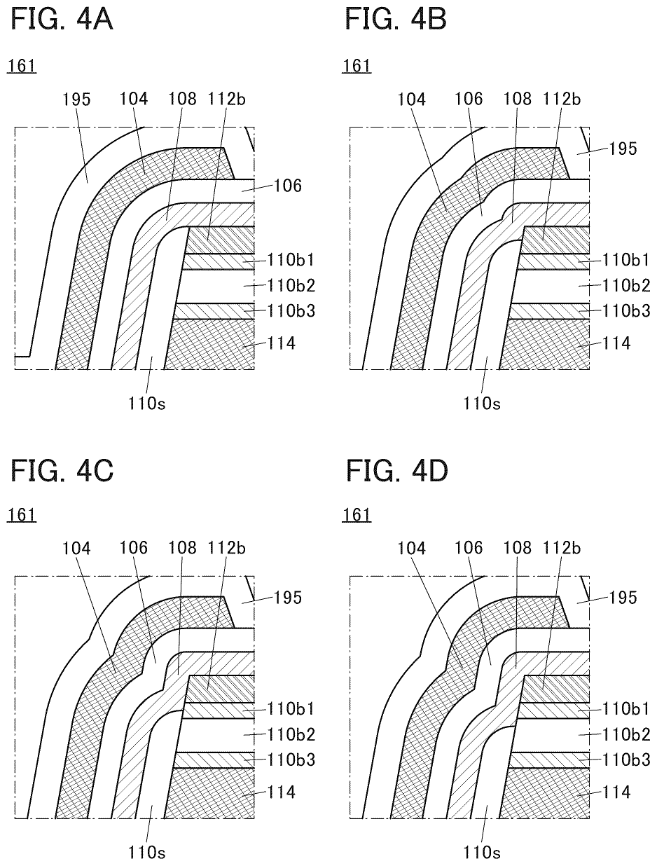

FIG. 4A is an enlarged view of a region 161 illustrated in FIG. 1B. FIG. 4A illustrates a structure in which an upper end portion of the insulating layer 110s is level with or substantially level with the top surface of the conductive layer 112b (a structure illustrated in FIG. 1B and the like).

FIG. 4B to FIG. 4D each illustrate an example of a structure in which the level of upper end portion of the insulating layer 110s and the like are different from those in FIG. 4A.

FIG. 4B illustrates a structure in which the level of the upper end portion of the insulating layer 110s is lower than the level of the top surface of the conductive layer 112b and higher than the level of the top surface of the insulating layer 110b1 positioned below the conductive layer 112b. In the structure illustrated in FIG. 4B, for example, the side surface of the conductive layer 112b includes a region in contact with the semiconductor layer 108. When the semiconductor layer 108 is in contact with the side surface of the conductive layer 112b, the contact area between the semiconductor layer 108 and the conductive layer 112b increases, so that the contact resistance therebetween is sometimes reduced.

FIG. 4C illustrates a structure in which the level of the upper end portion of the insulating layer 110s is lower than the level of the top surface of the insulating layer 110b1. In the structure illustrated in FIG. 4B, for example, the side surface of the conductive layer 112b includes a region in contact with the semiconductor layer 108, and the side surface of the insulating layer 110b1 includes a region in contact with the semiconductor layer 108.

FIG. 4D illustrates a structure in which the level of the upper end of the insulating layer 110s is lower than the level of the top surface of the insulating layer 110b2. In the structure illustrated in FIG. 4B, for example, the side surface of the conductive layer 112b includes a region in contact with the semiconductor layer 108, the side surface of the insulating layer 110b1 includes a region in contact with the semiconductor layer 108, and the side surface of the insulating layer 110b2 includes a region in contact with the semiconductor layer 108.

In etching at the time of forming the insulating layer 110s, a longer etching time can sometimes lower the level of the upper end portion of the insulating layer 110s. A longer etching time sometimes makes the level of the upper end portion of the insulating layer 110s lower than the level of the top surface of the conductive layer 112b. The level of the upper end portion of the insulating layer 110s is preferably higher than at least the level of the top surface of the conductive layer 114. That is, the insulating layer 110s is preferably in contact with the entire side surface of the conductive layer 114 in the opening 142. It is preferable that the conductive layer 114 not include a region in contact with the semiconductor layer 108 in the opening 142.

The reduction in the channel length L100 can increase the on-state current of the transistor 100. With the use of the transistor 100, a circuit capable of high-speed operation can be manufactured. Furthermore, the area occupied by the circuit can be reduced. Thus, in the case where the transistor of one embodiment of the present invention is used in a semiconductor device, the semiconductor device can be downsized.

For example, when the transistor of one embodiment of the present invention is used in a display apparatus, the bezel of the display apparatus can be narrowed. For another example, when the transistor of one embodiment of the present invention is used in a large display apparatus or a high-resolution display apparatus, signal delay in wirings can be reduced so that display unevenness can be inhibited even if the number of wirings is increased.

The channel width of the transistor 100 is the length of the source region or the length of the drain region in the plan view. In other words, the channel width of the transistor 100 is the length of a region where the semiconductor layer 108 is in contact with the conductive layer 112a or the length of a region where the semiconductor layer 108 is in contact with the conductive layer 112b in the plan view.

The semiconductor layer 108 is provided along the concave portion whose bottom portion is the top surface of the conductive layer 112a and whose inner wall is the sidewall 141 of the insulating layer 110s. Thus, the length of the perimeter of the inner wall of the insulating layer 110s in the plan view is sometimes used as the channel width. The insulating layer 110s can also be expressed as having a shape having an opening in the center or the vicinity of the center of a cylinder in the plan view, for example. The perimeter of the opening can also be used as the channel width of the semiconductor layer 108.

Here, the channel width of the transistor 100 is described as the length of the region where the semiconductor layer 108 is in contact with the conductive layer 112b in the plan view. In FIG. 1A, FIG. 1B, and FIG. 2, a channel width W100 of the transistor 100 is indicated by a solid double-headed arrow. The channel width W100 is the length of the perimeter of the opening 143 in the plan view.

The channel width W100 is determined depending on the top surface shape of the opening 143. In FIG. 1A and FIG. 1B, and FIG. 2, a width D143 of the opening 143 is indicated by a dashed double-dotted double-headed arrow. In the plan view, the width D143 refers to the short side of the smallest rectangle that is circumscribed around the opening 143. In the case where the opening 143 is formed by a photolithography method, the width D143 of the opening 143 is larger than or equal to the resolution limit of a light exposure apparatus. For example, the width D143 is greater than or equal to 0.20 μm and less than 5.0 μm. In the case where the top surface shape of the opening 143 is a circle, the width D143 corresponds to the diameter of the opening 143, and the channel width W100 can be calculated to be “D143×π”.

### Semiconductor Layer 108

A semiconductor material that can be used for the semiconductor layer 108 is not particularly limited. For example, a single-element semiconductor or a compound semiconductor can be used. Examples of the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. These semiconductor materials may include an impurity as a dopant.

There is no particular limitation on the crystallinity of the semiconductor material used for the semiconductor layer 108, and an amorphous semiconductor or a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case degradation of the transistor characteristics can be inhibited.

Silicon can be used for the semiconductor layer 108. Examples of silicon include single crystal silicon, polycrystalline silicon, microcrystalline silicon, and amorphous silicon. An example of polycrystalline silicon is low-temperature polysilicon (LTPS).

The transistor using amorphous silicon for the semiconductor layer 108 can be formed over a large glass substrate, and can be manufactured at low cost. The transistor including polycrystalline silicon in the semiconductor layer 108 has high field-effect mobility and can operate at high speed. The transistor including microcrystalline silicon in the semiconductor layer 108 has higher field-effect mobility and can operate at higher speed than the transistor including amorphous silicon.

The semiconductor layer 108 preferably includes a metal oxide (an oxide semiconductor). Examples of the metal oxide that can be used for the semiconductor layer 108 include indium oxide, gallium oxide, and zinc oxide. The metal oxide preferably includes at least indium (In) or zinc (Zn). The metal oxide preferably includes two or three selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin. The element M is further preferably gallium.sss

For the semiconductor layer 108, for example, indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), indium gallium aluminum zinc oxide (In—Ga—Al—Zn oxide, also referred to as IGAZO or IAGZO), or the like can be used. Alternatively, indium tin oxide including silicon or the like can be used.

A sputtering method or an atomic layer deposition (ALD) method can be suitably used to form the metal oxide. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc included in the metal oxide may be approximately 40% to 90% of the atomic ratio of zinc included in the target.

Specific examples of ALD methods used to form the semiconductor layer 108 include deposition methods such as a thermal ALD method and a plasma enhanced ALD (PEALD) method. A thermal ALD method is preferable because it offers extremely high step coverage. The PEALD method is preferable because of its capability of depositing a film at low temperatures, in addition to its capability of forming a film with high step coverage.

The composition of the metal oxide included in the semiconductor layer 108 greatly affects the electrical characteristics and reliability of the transistor 100.

For example, a metal oxide with a higher indium content percentage enables the transistor to have a higher on-state current. For another example, the use of a metal oxide that does not include gallium or has a low gallium content percentage for the semiconductor layer 108 enables the transistor to be highly reliable against positive bias application. For another example, the use of a metal oxide having a low element M content percentage for the semiconductor layer 108 enables the transistor to be highly reliable against positive bias application. For another example, a metal oxide with a high element M content percentage enables the transistor to be highly reliable against light.

The composition of the metal oxide included in the semiconductor layer 108 will be described later in detail.

It is preferable to use a metal oxide layer having crystallinity as the semiconductor layer 108. For example, a metal oxide layer having a CAAC (c-axis aligned crystal) structure, a polycrystalline (poly-crystal) structure, a nano-crystal (nc) structure, or the like can be used. With the use of a metal oxide layer having crystallinity as the semiconductor layer 108, the density of defect states in the semiconductor layer 108 can be reduced, which enables the transistor to have high reliability. Note that the CAAC structure is a crystal structure in which a plurality of microcrystals (typically, a plurality of IGZO microcrystals) have c-axis alignment and the above plurality of microcrystals are connected in an a-b plane without alignment. The CAAC structure has a smaller amount of crystal grain boundary, grain, or the like in the a-b plane than a polycrystalline structure, and thus can achieve a highly reliable transistor.

The higher the crystallinity of the metal oxide layer used as the semiconductor layer 108 is, the lower the density of defect states in the semiconductor layer 108 can be. By contrast, the use of a metal oxide layer having low crystallinity achieves a transistor through which a large amount of current can flow.

The semiconductor layer 108 may have a stacked-layer structure of two or more metal oxide layers having different crystallinities. For example, a stacked-layer structure of the first metal oxide layer and the second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target, for example. For example, with use of the same sputtering target and making the proportion of the flow rate of oxygen gas to the flow rate of the entire deposition gas used at the time of forming the metal oxide layer (hereinafter, also referred to as the oxygen flow rate ratio) different, a stacked-layer structure of two or more metal oxide layers having different crystallinities can be formed. The two or more metal oxide layers included in the semiconductor layer 108 may have different compositions.

The thickness of the semiconductor layer 108 (the thickness on the formation surface) is preferably larger than or equal to 3 nm and smaller than or equal to 100 nm, further preferably larger than or equal to 5 nm and smaller than or equal to 100 nm, still further preferably larger than or equal to 10 nm and smaller than or equal to 100 nm, yet further preferably larger than or equal to 10 nm and smaller than or equal to 70 nm, yet still further preferably larger than or equal to 15 nm and smaller than or equal to 70 nm, yet still further preferably larger than or equal to 15 nm and smaller than or equal to 50 nm, yet still further preferably larger than or equal to 20 nm and smaller than or equal to 50 nm, yet still further preferably larger than or equal to 20 nm and smaller than or equal to 40 nm, yet still further preferably larger than or equal to 25 nm and smaller than or equal to 40 nm.

Here, oxygen vacancies that might be formed in the semiconductor layer 108 will be described.

In the case where an oxide semiconductor is used for the semiconductor layer 108, hydrogen included in the oxide semiconductor reacts with oxygen bonded to a metal atom to be water, and thus may form an oxygen vacancy (Vo) in the oxide semiconductor. In some cases, a defect that is an oxygen vacancy into which hydrogen enters (hereinafter referred to as VoH) functions as a donor and generates an electron serving as a carrier. In some cases, bonding of part of hydrogen to oxygen bonded to a metal atom generates electrons serving as carriers. Thus, a transistor using an oxide semiconductor that includes a large amount of hydrogen is likely to have normally-on characteristics. Moreover, hydrogen in the oxide semiconductor is easily transferred by a stress such as heat or an electric field; thus, a large amount of hydrogen in the oxide semiconductor might reduce the reliability of the transistor.

VoH can function as a donor of the oxide semiconductor. However, it is difficult to evaluate the defect quantitatively. Thus, the oxide semiconductor is sometimes evaluated not by its donor concentration but by its carrier concentration. Therefore, in this specification and the like, the carrier concentration assuming the state where an electric field is not applied is sometimes used as the parameter of the oxide semiconductor, instead of the donor concentration. That is, “carrier concentration” described in this specification and the like can be replaced with “donor concentration” in some cases.

Accordingly, in the case where an oxide semiconductor is used for the semiconductor layer 108, the amount of VoH in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced VoH, it is important to remove impurities such as water and hydrogen in the oxide semiconductor (this treatment is sometimes referred to as dehydration or dehydrogenation treatment) and supply oxygen to the oxide semiconductor to fill an oxygen vacancy (Vo). When an oxide semiconductor with a sufficiently reduced amount of impurities such as VoH is used for the channel formation region of the transistor, the transistor can have stable electrical characteristics. Supplying oxygen to an oxide semiconductor to fill an oxygen vacancy (Vo) is sometimes referred to as oxygen adding treatment.

When an oxide semiconductor is used for the semiconductor layer 108, the carrier concentration of the oxide semiconductor in the region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter, also referred to as off-state current), and charge accumulated in a capacitor that is connected in series with the transistor can be held for a long period. With the use of the OS transistor in a semiconductor device, the power consumption of the semiconductor device can be reduced.

The OS transistor can be used for a display apparatus. To increase the emission luminance of a light-emitting device included in a pixel circuit in the display apparatus, it is necessary to increase the amount of current flowing through the light-emitting device. To increase the current amount, the source-drain voltage of a drive transistor included in the pixel circuit needs to be increased. Since the OS transistor has a higher breakdown voltage between a source and a drain than a transistor using silicon (hereinafter, referred to as a Si transistor), a high voltage can be applied between the source and the drain of the OS transistor. Accordingly, when the OS transistor is used as the driving transistor in the pixel circuit, the amount of current flowing through the light-emitting device can be increased, so that the emission luminance of the light-emitting device can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be finely set by a change in gate source voltage; thus, the amount of current flowing through the light-emitting device can be controlled finely. Thus, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made to flow through an OS transistor than through a Si transistor. Thus, with the use of an OS transistor as a driving transistor, a current can be made flow stably to the light-emitting device, for example, even when a variation in current-voltage characteristics of the light-emitting device occurs. In other words, when the OS transistor operates in the saturation region, the source-drain current hardly changes even with an increase in the source-drain voltage; thus, the emission luminance of the light-emitting device can be stable.

As described above, with use of an OS transistor as the driving transistor included in the pixel circuit, it is possible to achieve “inhibition of black floating”, “increase in emission luminance”, “increase in the number of gray levels”, “inhibition of variation in light-emitting devices”, and the like.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, neutron beams, and proton beams).

### Insulating Layer

In the transistor of one embodiment of the present invention and a semiconductor device, a display apparatus, and the like each using the transistor of one embodiment of the present invention, insulating layers can be formed using an inorganic insulating material or an organic insulating material. The insulating layers may each have a stacked-layer structure of an inorganic insulating material and an organic insulating material.

As the inorganic insulating material, one or more of an oxide, an oxynitride, a nitride oxide, and a nitride can be used.

In this specification and the like, an oxynitride refers to a material that includes more oxygen than nitrogen in its composition. A nitride oxide refers to a material that includes more nitrogen than oxygen in its composition. For example, silicon oxynitride refers to a material that includes more oxygen than nitrogen in its composition, and silicon nitride oxide refers to a material that includes more nitrogen than oxygen in its composition.

The contents of oxygen and nitrogen can be analyzed by secondary ion mass spectrometry (SIMS) or X-ray photoelectron spectrometry (XPS), for example. When the content percentage of a target element is high (e.g., higher than or equal to 0.5 atomic %, or higher than or equal to 1 atomic %), XPS is suitable. By contrast, when the content percentage of a target element is low (e.g., lower than 0.5 atomic %, or lower than 1 atomic %), SIMS is suitable. To compare the contents of elements, a combined analysis using both SIMS and XPS is further preferably performed.

The film density of an insulating layer or the like can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Note that when insulating layers formed using the same material have different film densities, it is sometimes possible to identify the boundary between the insulating layers by a difference in contrast in a TEM image of a cross section.

The nitrogen content of an insulating layer can be confirmed by energy dispersive X-ray spectrometry (EDX), for example. In the case where silicon nitride, silicon oxynitride, or the like is used for the insulating layer, for example, the nitrogen content can be evaluated with the ratio of the peak height of nitrogen to the peak height of silicon. Note that in EDX, the peak of a certain element refers to a point at which the number of counts of the element reaches a local maximum value in a spectrum where the horizontal axis represents the energy of characteristic X-rays and the vertical axis represents the number of counts (the detected value) of characteristic X-rays. Alternatively, the number of counts at an energy of a characteristic X-ray unique to the element may be used to confirm a difference in nitrogen content with the ratio of the number of counts of nitrogen to the number of counts of silicon. For example, the number of counts at 1.739 keV (Si—Kα) can be used for silicon, and the number of counts at 0.392 keV (N—Kα) can be used for nitrogen.

The hydrogen concentration in an insulating layer can be evaluated by SIMS, for example.

When an insulating layer that releases oxygen is used as an insulating layer in contact with the semiconductor layer 108 or an insulating layer positioned around the semiconductor layer 108, oxygen can be supplied from the insulating layer to the semiconductor layer 108. Supplying oxygen to the channel formation region in the semiconductor layer 108 allows the amount of oxygen vacancy (Vo) and VoH to be reduced in the semiconductor layer 108, so that the transistor can have excellent electrical characteristics and high reliability. Examples of treatment for supplying oxygen to the semiconductor layer 108 include heat treatment in an oxygen-containing atmosphere and plasma treatment in an oxygen-containing atmosphere.

Hydrogen diffusing into the semiconductor layer 108 reacts with an oxygen atom included in an oxide semiconductor to be water, and thus sometimes forms an oxygen vacancy (Vo) in the semiconductor layer 108. Furthermore, VoH is formed in the semiconductor layer 108 and the carrier concentration in the semiconductor layer 108 is increased in some cases. When a blocking film that inhibits hydrogen diffusion is used as the insulating layer in contact with the semiconductor layer 108 or the insulating layer positioned around the semiconductor layer 108, the amount of oxygen vacancy (Vo) and VoH can be reduced in the semiconductor layer 108, so that the transistor can have excellent electrical characteristics and high reliability.

It is preferable that the amount of oxygen vacancy (Vo) and VoH be small in the channel formation region of the transistor 100. Particularly in the case where the channel length L100 is short, an oxygen vacancy (Vo) and VoH in the channel formation region greatly affect the electrical characteristics and the reliability of the transistor 100. For example, diffusion of VoH from the source region or the drain region into the channel formation region increases the carrier concentration in the channel formation region, which might cause a change in the threshold voltage or a reduction in the reliability of the transistor 100. As the channel length L100 of the transistor 100 is shorter, the influence of such diffusion of VoH on the electrical characteristics and the reliability of the transistor 100 becomes greater. Reducing the amount of oxygen vacancy (Vo) and VoH in the semiconductor layer 108, particularly in the channel formation region in the semiconductor layer 108, enables the transistor with a short channel length to have excellent electrical characteristics and high reliability.

The amount of impurities (e.g., water and hydrogen) released from the insulating layer in contact with the semiconductor layer 108 or the insulating layer positioned around the semiconductor layer 108 is preferably small. When the released amount of impurities is small, diffusion of impurities into the semiconductor layer 108 is inhibited, and the transistor can have excellent electrical characteristics and high reliability.

Due to heat applied in a step after the formation of the semiconductor layer 108, oxygen might be released from the semiconductor layer 108. However, supply of oxygen to the semiconductor layer 108 from the insulating layer in contact with the semiconductor layer 108 or the insulating layer positioned around the semiconductor layer 108 can inhibit an increase in the amount of oxygen vacancy (Vo) and VoH in the semiconductor layer 108. Furthermore, in a step after the formation of the semiconductor layer 108, the flexibility of the treatment temperature can be increased. Specifically, also in a step after the formation of the semiconductor layer 108, the treatment temperature can be high. Consequently, the transistor 100 can have excellent electrical characteristics and high reliability.

### Insulating Layer 110a and Insulating Layer 110b

For each of the insulating layer 110a and the insulating layer 110b, an inorganic insulating material or an organic insulating material can be used. The insulating layer 110a and the insulating layer 110b may each have a stacked-layer structure of an inorganic insulating material and an organic insulating material.

For each of the insulating layer 110a and the insulating layer 110b, an inorganic insulating material can be suitably used. As the inorganic insulating material, one or more of an oxide, an oxynitride, a nitride oxide, and a nitride can be used. For each of the insulating layer 110a and the insulating layer 110b, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

The insulating layer 110a and the insulating layer 110b may each have a stacked-layer structure of two or more layers. FIG. 1B and the like illustrate a structure in which the insulating layer 110a has a stacked-layer structure of the insulating layer 110a1 , the insulating layer 110a2 over the insulating layer 110a1 , and the insulating layer 110a3 over the insulating layer 110a2, and the insulating layer 110b has a stacked-layer structure of the insulating layer 110b3, the insulating layer 110b2 over the insulating layer 110b3, and the insulating layer 110b1 over the insulating layer 110b2. For each of the insulating layer 110a1 , the insulating layer 110a2, the insulating layer 110a3, the insulating layer 110b3, the insulating layer 110b2, and the insulating layer 110b1, any of the materials that can be used for the insulating layer 110a and the insulating layer 110b can be used. Note that for the insulating layer 110a1 , the insulating layer 110a2, the insulating layer 110a3, the insulating layer 110b3, the insulating layer 110b2, and the insulating layer 110b1, the same material or different materials may be used.

The amount of impurities (e.g., water and hydrogen) released from the insulating layer 110a1, the insulating layer 110a2, the insulating layer 110a3, the insulating layer 110b3, the insulating layer 110b2, and the insulating layer 110b1 is preferably small.

The thickness of the insulating layer 110a2 can be larger than the thickness of each of the insulating layer 110al and the insulating layer 110a3. The thickness of the insulating layer 110b2 can be larger than the thickness of each of the insulating layer 110b1 and the insulating layer 110b3. The deposition rate of the insulating layer 110a2 is preferably higher than those of the insulating layer 110al and the insulating layer 110a3. The deposition rate of the insulating layer 110b2 is preferably higher than those of the insulating layer 110b1 and the insulating layer 110b3. By increasing the deposition rate of the film having a large thickness, the productivity can be increased.

The insulating layer 110al and the insulating layer 110a3 function as blocking films that inhibit release of gas from the insulating layer 110a2. Each of the insulating layer 110b1 and the insulating layer 110b3 function as a blocking film that inhibits release of gas from the insulating layer 110b2. Each of the insulating layer 110a1 , the insulating layer 110a3, the insulating layer 110b1, and the insulating layer 110b3 is preferably formed using a material that does not easily allow diffusion of gas. Each of the insulating layer 110al and the insulating layer 110a3 preferably includes a region having a higher film density than the insulating layer 110a2. Each of the insulating layer 110b1 and the insulating layer 110b3 preferably includes a region having a higher film density than the insulating layer 110b2. An insulating layer having a higher film density can have a higher blocking property against gas. An insulating layer formed at a lower deposition rate can have a higher film density and a higher blocking property against gas.

It is preferable to use an oxide or an oxynitride for each of the insulating layer 110a2 and the insulating layer 110b2. A film from which oxygen is released by heating is preferably used as each of the insulating layer 110a2 and the insulating layer 110b2. For example, silicon oxide or silicon oxynitride can be suitably used for each of the insulating layer 110a2 and the insulating layer 110b2.

When oxygen is released from the insulating layer 110a2 and the insulating layer 110b2, oxygen can be supplied to the semiconductor layer 108 from the insulating layer 110a2 and the insulating layer 110b2. The insulating layer 110a2 and the insulating layer 110b2 each preferably have a high oxygen diffusion coefficient. With a high oxygen diffusion coefficient, oxygen easily diffuses in the insulating layer 102a and the insulating layer 110b2, so that oxygen can be efficiently supplied to the semiconductor layer 108. When the thickness of the insulating layer 110a2 is larger than the thicknesses of the insulating layer 110al and the insulating layer 110a3 as described above, a larger amount of oxygen can be supplied to the semiconductor layer 108. Similarly, when the thickness of the insulating layer 110b2 is larger than the thicknesses of the insulating layer 110b1 and the insulating layer 110b3 as described above, a larger amount of oxygen can be supplied to the semiconductor layer 108.

The insulating layer 110a1 , the insulating layer 110a2, the insulating layer 110a3, the insulating layer 110b1, the insulating layer 110b2, and the insulating layer 110b3 are preferably formed by a deposition method such as a sputtering method, an ALD method, or a plasma CVD method.

In particular, when the insulating layer 110a1 , the insulating layer 110a2, the insulating layer 110a3, the insulating layer 110b1, the insulating layer 110b2, and the insulating layer 110b3 are deposited by a sputtering method, which is a deposition method that does not use a gas including hydrogen as a deposition gas, they can be films having an extremely low hydrogen content. In that case, supply of hydrogen to the semiconductor layer 108 is inhibited and the electrical characteristics of the transistor 100 can be stabilized. In the case where silicon oxide is deposited by a sputtering method, the silicon oxide can be deposited using a silicon target in an atmosphere including an oxygen gas, for example. In the case where silicon nitride is deposited by a sputtering method, the silicon nitride can be deposited using a silicon target in an atmosphere including a nitrogen gas, for example. In the case where aluminum oxide is deposited by a sputtering method, the aluminum oxide can be deposited using an aluminum target in an atmosphere including an oxidizing gas, for example.

Silicon oxide and silicon nitride can be deposited by a PEALD method, for example. Aluminum oxide and hafnium oxide can be deposited by a thermal ALD method, for example. An insulating layer deposited by a PEALD method or a thermal ALD method can be dense and thus can have a high blocking property against oxygen and hydrogen.

For each of the insulating layer 110al and the insulating layer 110a3, a material having a higher nitrogen content than a material for the insulating layer 110a2 can be used. For each of the insulating layer 110b1 and the insulating layer 110b3, a material having a higher nitrogen content than a material for the insulating layer 110b2 can be used. An insulating layer having a higher nitrogen content can have a higher blocking property against oxygen and hydrogen.

The insulating layer 110al and the insulating layer 110a3 may each include a region having a lower hydrogen concentration in the film than the insulating layer 110a2. The insulating layer 110b1 and the insulating layer 110b3 may each include a region having a lower hydrogen concentration in the film than the insulating layer 110b2.

It is preferable that the insulating layer 110a1 , the insulating layer 110a3, the insulating layer 110b1, and the insulating layer 110b3 not easily transmit oxygen. Furthermore, it is preferable that the insulating layer 110a1 , the insulating layer 110a3, the insulating layer 110b1, and the insulating layer 110b3 not easily transmit hydrogen. The insulating layer 110al and the insulating layer 110a3 function as blocking films that inhibit diffusion of hydrogen into the semiconductor layer 108 from the outside of the transistor through the insulating layer 110al and the insulating layer 110a3. The insulating layer 110b1 and the insulating layer 110b3 function as blocking films that inhibit diffusion of hydrogen into the semiconductor layer 108 from the outside of the transistor through the insulating layer 110b1 and the insulating layer 110b3. The film densities of the insulating layer 110al and the insulating layer 110a3 are preferably higher than the film density of the insulating layer 110a2. The film densities of the insulating layer 110b1 and the insulating layer 110b3 are preferably higher than the film density of the insulating layer 110b2. The insulating layer having a higher film density can have a higher blocking property against oxygen and hydrogen. In the case where silicon oxide or silicon oxynitride is used for each of the insulating layer 110a2 and the insulating layer 110b2, silicon nitride or silicon nitride oxide can be used for each of the insulating layer 110a1, the insulating layer 110a3, the insulating layer 110b1, and the insulating layer 110b3. In addition, hafnium oxide or aluminum oxide can be suitably used for each of the insulating layer 110a1, the insulating layer 110a3, the insulating layer 110b1, and the insulating layer 110b3.

The insulating layer 110a1, the insulating layer 110a3, the insulating layer 110b1, and the insulating layer 110b3 can each have a structure in which two or more selected from silicon nitride, silicon nitride oxide, hafnium oxide, and aluminum oxide are stacked.

When oxygen included in the insulating layer 110b2 diffuses upward from the insulating layer 110b2, oxygen supplied from the insulating layer 110b2 to the semiconductor layer 108 is reduced in some cases. Provision of the insulating layer 110b1 over the insulating layer 110b2 can inhibit upward diffusion of oxygen included in the insulating layer 110b2 from the insulating layer 110b2. Provision of the insulating layer 110b3 under the insulating layer 110b2 can inhibit downward diffusion of oxygen included in the insulating layer 110b2 from the insulating layer 110b2. Similarly, when oxygen included in the insulating layer 110a2 is diffused upward from the insulating layer 110a2, the amount of oxygen supplied from the insulating layer 110a2 to the semiconductor layer 108 is reduced in some cases. Provision of the insulating layer 110a3 over the insulating layer 110a2 can inhibit upward diffusion of oxygen included in the insulating layer 110a2 from the insulating layer 110a3. Provision of the insulating layer 110al under the insulating layer 110a2 can inhibit downward diffusion of oxygen included in the insulating layer 110a2 from the insulating layer 110a2. Accordingly, the amount of oxygen supplied from the insulating layer 110a2 and the insulating layer 110b2 to the semiconductor layer 108 is increased, whereby the amount of oxygen vacancy (Vo) and VoH in the semiconductor layer 108 can be reduced.

The conductive layer 112a and the conductive layer 114 are oxidized by oxygen included in the insulating layer 110a2 and have high resistance in some cases. Moreover, when the conductive layer 112a and the conductive layer 114 are oxidized, the amount of oxygen supplied from the insulating layer 110a2 to the semiconductor layer 108 might be reduced. Provision of the insulating layer 110a1 between the insulating layer 110a2 and the conductive layer 112a and provision of the insulating layer 110a3 between the insulating layer 110a2 and the conductive layer 114 can inhibit the conductive layer 112a and the conductive layer 114 from being oxidized and having a high resistance. Similarly, provision of the insulating layer 110b1 between the insulating layer 110b2 and the conductive layer 112b and provision of the insulating layer 110b3 between the insulating layer 110b2 and the conductive layer 114 can inhibit the conductive layer 112b and the conductive layer 114 from being oxidized and having a high resistance. In addition, the amount of oxygen supplied from the insulating layer 110a2 and the insulating layer 110b2 to the semiconductor layer 108 is increased and the amount of oxygen vacancy (Vo) and VoH in the semiconductor layer 108 can be reduced.

Provision of the insulating layer 110a1, the insulating layer 110a3, the insulating layer 110b1, and the insulating layer 110b3 can inhibit diffusion of hydrogen into the semiconductor layer 108 and reduce the amount of oxygen vacancy (Vo) and VoH in the semiconductor layer 108.

Each of the insulating layer 110a1, the insulating layer 110a3, the insulating layer 110b1, and the insulating layer 110b3 preferably has a thickness with which the insulating layer functions as a blocking film against oxygen and hydrogen. When the thickness is small, the function of a blocking film deteriorates in some cases. Meanwhile, when the thickness is large, regions of the semiconductor layer 108 facing the insulating layer 110a2 and the insulating layer 110b2 are narrowed and the amount of oxygen supplied to the semiconductor layer 108 is reduced in some cases. The thickness of each of the insulating layer 110a1, the insulating layer 110a3, the insulating layer 110b1, and the insulating layer 110b3 (the thickness on the film formation surface) is preferably greater than or equal to 1 nm and less than or equal to 200 nm, greater than or equal to 1 nm and less than or equal to 100 nm, greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, greater than or equal to 1 nm and less than or equal to 10 nm, greater than or equal to 1 nm and less than or equal to 5 nm, or greater than or equal to 2 nm and less than or equal to 5 nm.

### Insulating Layer 106 and Insulating Layer 110s

The insulating layer 106 and the insulating layer 110s each functioning as a gate insulating layer preferably have a low defect density. With the insulating layer 106 and the insulating layer 110s having a low defect density, the transistor can have excellent electrical characteristics. In addition, the insulating layer 106 and the insulating layer 110s each preferably have a high breakdown voltage. With the insulating layer 106 and the insulating layer 110s having a high breakdown voltage, the transistor can have high reliability.

For each of the insulating layer 106 and the insulating layer 110s, one or more of an insulating oxide, an insulating oxynitride, an insulating nitride oxide, and an insulating nitride can be used, for example. For each of the insulating layer 106 and the insulating layer 110s, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga-Zn oxide can be used. The insulating layer 106 and the insulating layer 110s may each be a single layer or stacked layers. The insulating layer 106 and the insulating layer 110s may each have a stacked-layer structure of an oxide and a nitride, for example.

A transistor having a minute size and including a thin gate insulating layer may have a high leakage current. When a high dielectric constant material (also referred to as a high-k material) is used for the gate insulating layer, voltage at the time of operation of the transistor can be reduced while the physical thickness is maintained. Examples of the high-k material include gallium oxide, hafnium oxide, zirconium oxide, an oxide including aluminum and hafnium, an oxynitride including aluminum and hafnium, an oxide including silicon and hafnium, an oxynitride including silicon and hafnium, and a nitride including silicon and hafnium.

The amount of impurities (e.g., water and hydrogen) released from the insulating layer 106 and the insulating layer 110s is preferably small. With the insulating layer 106 and the insulating layer 110s from which a small amount of impurities is released, diffusion of impurities into the semiconductor layer 108 is inhibited, and the transistor can have excellent electrical characteristics and high reliability.

The insulating layer 106 is formed over the semiconductor layer 108, and thus is preferably a film formed under conditions where damage to the semiconductor layer 108 is small. For example, the insulating layer 106 is preferably formed under conditions where the deposition speed (also referred to as a deposition rate) is sufficiently low. For example, when the insulating layer 106 is formed by a plasma CVD method under a low-power condition, damage to the semiconductor layer 108 can be small.

Here, the insulating layer 106 and the insulating layer 110s will be specifically described using a structure in which a metal oxide is used for the semiconductor layer 108 as an example.

In order to improve the properties of the interface with the semiconductor layer 108, one or more of an oxide and an oxynitride is preferably used at least for the side of each of the insulating layer 106 and the insulating layer 110s that is in contact with the semiconductor layer 108. For example, one or more of silicon oxide and silicon oxynitride can be suitably used for each of the insulating layer 106 and the insulating layer 110s. A film from which oxygen is released by heating is further preferably used for each of the insulating layer 106 and the insulating layer 110s.

Note that the insulating layer 106 and the insulating layer 110s may each have a stacked-layer structure. The insulating layer 106 can have a stacked-layer structure of an oxide film and an oxynitride film on the side in contact with the semiconductor layer 108 and a nitride film on the side in contact with the conductive layer 104. Similarly, the insulating layer 110s can have a stacked-layer structure of an oxide film or an oxynitride film on the side in contact with the semiconductor layer 108 and a nitride film on the side in contact with the conductive layer 114. For example, one or more of silicon oxide and silicon oxynitride can be suitably used for the oxide film or the oxynitride film. Silicon nitride can be suitably used for the nitride film.

The thickness of each of the insulating layer 106 and the insulating layer 110s (the thickness on the film formation surface) is preferably greater than or equal to 1 nm and less than or equal to 100 nm. At least part of each of the insulating layer 106 and the insulating layer 110s includes a region having the above-described thickness.

The insulating layer 106 and the insulating layer 110s preferably have a function of supplying oxygen.

### Conductive Layer 112a and Conductive Layer 112b

The conductive layer 112a and the conductive layer 112b functioning as a source electrode and a drain electrode can each be formed using one or more of chromium, copper, aluminum, gold, silver, zinc, tantalum, titanium, tungsten, manganese, nickel, iron, cobalt, molybdenum, and niobium; or an alloy including one or more of these metals as its components. For each of the conductive layer 112a and the conductive layer 112b, a low-resistance conductive material that includes one or more of copper, silver, gold, and aluminum can be suitably used. Copper or aluminum is particularly preferable because of its high mass-productivity.

As each of the conductive layer 112a and the conductive layer 112b, a metal oxide film (also referred to as an oxide conductor) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a and the conductive layer 112b may have a stacked-layer structure of a conductive film including the oxide conductor (the metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 112a and the conductive layer 112b. The use of a Cu—X alloy film enables the manufacturing cost to be reduced because processing can be performed by a wet etching method.

Note that the conductive layer 112a and the conductive layer 112b may be formed using the same material or different materials.

Here, the conductive layer 112a and the conductive layer 112b will be specifically described using a structure in which a metal oxide is used for the semiconductor layer 108 as an example.

When an oxide semiconductor is used for the semiconductor layer 108, the conductive layer 112a and the conductive layer 112b are oxidized by oxygen included in the semiconductor layer 108 and have high resistance in some cases. The conductive layer 112a and the conductive layer 112b are oxidized by oxygen included in the insulating layer 110a, the insulating layer 110b, and the insulating layer 110s and have high resistance in some cases. Moreover, when the conductive layer 112a and the conductive layer 112b are oxidized by oxygen included in the semiconductor layer 108, the amount of oxygen vacancy (Vo) in the semiconductor layer 108 is increased in some cases. When the conductive layer 112a and the conductive layer 112b are oxidized by oxygen included in the insulating layer 110a, the insulating layer 110b, and the insulating layer 110s, the amount of oxygen supplied from the insulating layer 110a, the insulating layer 110b, and the insulating layer 110s to the semiconductor layer 108 is reduced in some cases.

A material that is less likely to be oxidized is preferably used for each of the conductive layer 112a and the conductive layer 112b. An oxide conductor is preferably used for each of the conductive layer 112a and the conductive layer 112b. For example, In—Sn oxide (ITO) or In—Sn—Si oxide (ITSO) can be suitably used. For each of the conductive layer 112a and the conductive layer 112b, a nitride conductor may be used. Examples of the nitride conductor include tantalum nitride and titanium nitride. The conductive layer 112a and the conductive layer 112b may each have a stacked-layer structure of the above-described materials.

With the use of a material that is less likely to be oxidized, the conductive layer 112a and the conductive layer 112b can be inhibited from being oxidized by oxygen included in the semiconductor layer 108 or oxygen included in the insulating layer 110a, the insulating layer 110b, and the insulating layer 110s and having high resistance. Furthermore, it is possible to increase the amount of oxygen supplied from the insulating layer 110a, the insulating layer 110b, and the insulating layer 110s to the semiconductor layer 108 while an increase in the amount of oxygen vacancy (Vo) in the semiconductor layer 108 is inhibited.

### Conductive Layer 104 and Conductive Layer 114

The conductive layer 104 and the conductive layer 114 functioning as a gate electrode and a back gate electrode can each be formed using one or more of chromium, copper, aluminum, gold, silver, zinc, molybdenum, tantalum, titanium, tungsten, manganese, nickel, iron, cobalt, and niobium; or an alloy including one or more of these metals as its components, for example. The above material that can be used for the conductive layer 112a and the conductive layer 112b may be used for the conductive layer 104 and the conductive layer 114.

Although the conductive layer 104 has a single-layer structure in FIG. 1B and the like, one embodiment of the present invention is not limited thereto. For example, the conductive layer 104 may have a stacked-layer structure of two or more layers. For example, in a case where the conductive layer 104 has a stacked-layer structure of two layers, a nitride or an oxide can be used for the first layer of the conductive layer (a conductive layer at the insulating layer 106 side) and one or more of chromium, copper, aluminum, gold, silver, zinc, molybdenum, tantalum, titanium, tungsten, manganese, nickel, iron, cobalt, and niobium or an alloy including one or more of these metals as its components can be used for the second layer of the conductive layer. As another example, when the conductive layer 104 has a three-layer stack structure, the first conductive layer (a conductive layer on the insulating layer 106 side) can be formed using an alloy including one or more of the above metals as a component or a nitride of the metal(s) or the alloy; the second conductive layer can be formed using an alloy including one or more of the above metals as its components; and the third conductive layer can be formed using an alloy including one or more of the above metals as its components or a nitride of the metal(s) or the alloy.

### Insulating Layer 195

It is preferable to use a material that does not easily allow diffusion of impurities for the insulating layer 195 functioning as a protective layer of the transistor 100. Provision of the insulating layer 195 can effectively inhibit diffusion of impurities into the transistor from the outside and increase the reliability of the transistor. Examples of the impurities include water and hydrogen. The insulating layer 195 can be an insulating layer including an inorganic material or an insulating layer including an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of an acrylic resin and a polyimide resin can be used. As an organic material, a photosensitive material may be used. A stack including two or more of the above insulating films may also be used. The insulating layer 195 may have a stacked-layer structure of an insulating layer including an inorganic material and an insulating layer including an organic material.

### Substrate 102

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. Alternatively, any of these substrates over which a semiconductor element is provided may be used as the substrate 102. Note that the shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. The separation layer can be used for separation of part or the whole of a semiconductor device completed thereover from the substrate 102 and transferring the part or the whole of the semiconductor device onto another substrate. In such a case, the transistor 100 and the like can be transferred to a substrate having low heat resistance or a flexible substrate as well.

### Composition of Metal Oxide Included in Semiconductor Layer 108

The composition of the metal oxide included in the semiconductor layer 108 will be described below.

The composition of the metal oxide included in the semiconductor layer 108 greatly affects the electrical characteristics and reliability of the transistor 100.

For example, a metal oxide with a higher indium content percentage enables the transistor to have a higher on-state current.

In the case of using In—Zn oxide for the semiconductor layer 108, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn =3:1, In:Zn=4:1, In:Zn=5:1, In:Zn=7:1, or In:Zn=10:1, or in the neighborhood thereof.

In the case of using In—Sn oxide for the semiconductor layer 108, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case of using In—M—Zn oxide for the semiconductor layer 108, it is possible to use a metal oxide in which the atomic proportion of indium to the metal elements is higher than the atomic proportion of the element M. It is further preferable to use a metal oxide in which the atomic ratio of zinc is higher than the atomic ratio of the element M. For example, it is possible to use, for the semiconductor layer 108, a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, or In:M:Zn=40:1:10, or in the neighborhood thereof.

In the case where a plurality of metal elements are included as the element M, the sum of the atomic ratios of the metal elements can be the atomic ratio of the element M. In the case of In—Ga—Al—Zn oxide in which gallium and aluminum are included as the element M, for example, the sum of the atomic ratio of gallium and the atomic ratio of aluminum can be the atomic ratio of the element M. The atomic ratio of indium, the element M, and zinc is preferably within the ranges given above. In the case of In—Ga—Sn—Zn oxide in which gallium and tin are included as the element M, for example, the sum of the proportion of the number of gallium atoms and the proportion of the number of tin atoms can be the proportion of the number of element M atoms. The atomic ratio of indium, the element M, and zinc is preferably within the ranges given above.

It is preferable to use a metal oxide in which the atomic proportion of indium in the metal elements included in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, still further preferably higher than or equal to 35 atomic % and lower than or equal to 90 atomic %, yet still further preferably higher than or equal to 40 atomic % and lower than or equal to 90 atomic %, yet still further preferably higher than or equal to 45 atomic % and lower than or equal to 90 atomic %, yet still further preferably higher than or equal to 50 atomic % and lower than or equal to 80 atomic %, yet still further preferably higher than or equal to 60 atomic % and lower than or equal to 80 atomic %, yet still further preferably higher than or equal to 70 atomic % and lower than or equal to 80 atomic %. For example, in the case of using In—Ga—Zn oxide for the semiconductor layer 108, the proportion of the number of indium atoms in the sum of the numbers of atoms of indium, the element M, and zinc is preferably within the ranges described above.

In this specification and the like, the proportion of indium atoms to the atoms of metal elements included is sometimes referred to as indium content percentage. The same applies to other metal elements.

A metal oxide with a higher indium content percentage enables a transistor to have a higher on-state current. By using such a transistor as a transistor required to have a high on-state current, a semiconductor device having excellent electrical characteristics can be provided.

For analysis of the composition of the metal oxide, for example, EDX, XPS, inductively coupled plasma-mass spectrometry (ICP-MS), or inductively coupled plasma-atomic emission spectrometry (ICP-AES) can be used. Alternatively, a combination of those methods may be used for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage or difficult to quantify or the element M is sometimes not detected.

A composition in the neighborhood in this specification and the like includes the range of ±30% of an intended atomic ratio. For example, in the case of describing an atomic ratio of In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. In the case of describing an atomic ratio of In:M:Zn=5:1:6 or a composition in the neighborhood thereof, the case is included where the atomic ratio of M is greater than 0.1 and less than or equal to 2 and the atomic ratio of zinc is greater than or equal to 5 and less than or equal to 7 with the atomic ratio of indium being 5. In the case of describing an atomic ratio of In:M:Zn=1:1:1 or a composition in the neighborhood thereof, the case is included where the atomic ratio of M is greater than 0.1 and less than or equal to 2 and the atomic ratio of zinc is greater than 0.1 and less than or equal to 2 with the atomic ratio of indium being 1.

Here, the reliability of a transistor is described. One of indexes for evaluating the reliability of a transistor is a GBT (Gate Bias Temperature) stress test in which the transistor is kept at a high temperature with an electric field applied to its gate. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation with light is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state (a state where current flows); thus, the amount of change in threshold voltage in the PBTS test is one important item to be focused on as an indicator of the reliability of the transistor.

With the use of a metal oxide that does not include gallium or has a low gallium content percentage in the semiconductor layer 108, the transistor can be highly reliable against positive bias application. In other words, the amount of change in the threshold voltage of the transistor in the PBTS test can be small. In the case of using a metal oxide that includes gallium, the gallium content percentage is preferably lower than the indium content percentage. Thus, a highly reliable transistor can be achieved.

One of the factors in change in the threshold voltage in the PBTS test is carrier trapping by defect states at the interface between a semiconductor layer and a gate insulating layer or in the vicinity of the interface. As the density of defect states increases, the amount of carrier traps by defect states increases; thus, degradation in the PBTS test becomes more significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not include gallium or has a low gallium content percentage is used for the semiconductor layer. Gallium included in the metal oxide has a property of attracting oxygen more easily than another metal element (e.g., indium or zinc) does. Thus, when, at the interface between a metal oxide including a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case of using In—Ga—Zn oxide for the semiconductor layer 108, a metal oxide in which the atomic proportion of indium is higher than the atomic proportion of gallium can be used for the semiconductor layer 108. It is further preferable to use a metal oxide in which the atomic proportion of zinc is higher than the atomic proportion of gallium. In other words, a metal oxide in which the atomic proportions of metal elements satisfy In>Ga and Zn>Ga is preferably used for the semiconductor layer 108.

It is preferable to use, for the semiconductor layer 108, a metal oxide in which the proportion of the number of gallium atoms to the number of atoms of the metal elements included is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, still further preferably higher than or equal to 0.1 atomic % and lower than or equal to 30 atomic %, yet further preferably higher than or equal to 0.1 atomic % and lower than or equal to 25 atomic %, yet still further preferably higher than or equal to 0.1 atomic % and lower than or equal to 20 atomic %, yet still further preferably higher than or equal to 0.1 atomic % and lower than or equal to 15 atomic %, yet still further preferably higher than or equal to 0.1 atomic % and lower than or equal to 10 atomic %. The reduction in the gallium content percentage in the semiconductor layer enables the transistor to be highly resistant to the PBTS test. Note that oxygen vacancies (Vo) are less likely to be generated in the metal oxide when the metal oxide includes gallium.

A metal oxide not including gallium may be used for the semiconductor layer 108. For example, In—Zn oxide can be used for the semiconductor layer 108. In this case, when the ratio of the number of indium atoms in the number of atoms of the metal elements included in the metal oxide is increased, the field-effect mobility of the transistor can be increased. By contrast, when the ratio of the number of zinc atoms in the number of atoms of the metal elements included in the metal oxide is increased, the metal oxide has high crystallinity; thus, a change in the electrical characteristics of the transistor can be inhibited and the reliability can be increased. Alternatively, a metal oxide that includes neither gallium nor zinc, such as indium oxide, may be used for the semiconductor layer 108. The use of a metal oxide not including gallium can make a change in the threshold voltage particularly in the PBTS test extremely small.

For example, an oxide including indium and zinc can be used for the semiconductor layer 108. In that case, for example, a metal oxide in which the atomic ratio of metal elements is In:Zn=2:3 or in the neighborhood thereof can be used.

Although the case of using gallium is described as a typical example, the same applies to the case where the element M is used instead of gallium. A metal oxide in which the atomic proportion of indium is higher than the atomic proportion of the element M is preferably used for the semiconductor layer 108. Furthermore, a metal oxide in which the atomic ratio of zinc is higher than the atomic ratio of the element M is preferably used.

The use of a metal oxide having a low element M content percentage for the semiconductor layer 108 enables the transistor to be highly reliable against positive bias application. With the use of the transistor as a transistor that is required to have high reliability against positive bias application, a highly reliable semiconductor device can be provided.

Next, the reliability of a transistor against light is described.

Light incidence on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in an NBTIS test, for example.

The high content percentage of the element M in the metal oxide enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide included in the semiconductor layer 108 is preferably greater than or equal to 2.0 eV, further preferably greater than or equal to 2.5 eV, still further preferably greater than or equal to 3.0 eV, yet further preferably greater than or equal to 3.2 eV, yet still further preferably greater than or equal to 3.3 eV, yet still further preferably greater than or equal to 3.4 eV, yet still further preferably greater than or equal to 3.5 eV.

For example, it is possible to use, for the semiconductor layer 108, a metal oxide in which the atomic ratio of the metal elements is In:M:Zn=1:1:1, In:M:Zn=1:1:1.2, In: M: Zn =1:3:2, In:M:Zn=1:3:3, or In:M:Zn=1:3:4, or in the neighborhood thereof.

In particular, a metal oxide in which the proportion of the number of element M atoms to the number of atoms of the metal elements included is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet still further preferably higher than or equal to 50 atomic % and lower than or equal to 60 atomic % can be suitably used for the semiconductor layer 108.

In the case of using In—Ga—Zn oxide for the semiconductor layer 108, a metal oxide in which the atomic ratio of indium to the metal elements is lower than or equal to the atomic ratio of gallium can be used. For example, it is possible to use a metal oxide in which the atomic ratio of the metal elements is In:Ga:Zn=1:1:1, In:Ga:Zn=1:1:1.2, In:Ga:Zn=1:3:2, In:Ga:Zn=1:3:3, or In:Ga:Zn=1:3:4, or in the neighborhood thereof.

In particular, a metal oxide in which the proportion of the number of gallium atoms to the number of atoms of the metal elements included is higher than or equal to 20 atomic % and lower than or equal to 60 atomic %, further preferably higher than or equal to 30 atomic % and lower than or equal to 60 atomic %, still further preferably higher than or equal to 40 atomic % and lower than or equal to 60 atomic %, yet still further preferably higher than or equal to 50 atomic % and lower than or equal to 60 atomic % can be suitably used for the semiconductor layer 108.

The use of a metal oxide having a high element M content percentage for the semiconductor layer 108 enables the transistor to be highly reliable against light. With the use of the transistor as a transistor that is required to have high reliability against light, a highly reliable semiconductor device can be provided.

As described above, the electrical characteristics and reliability of a transistor depend on the composition of the metal oxide used for the semiconductor layer 108. Therefore, by determining the composition of the metal oxide in accordance with the electrical characteristics and reliability required for the transistor, the semiconductor device can have both excellent electrical characteristics and high reliability.

The semiconductor layer 108 may have a stacked-layer structure including two or more metal oxide layers. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target, for example.

The two or more metal oxide layers included in the semiconductor layer 108 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

### Structure Example 2

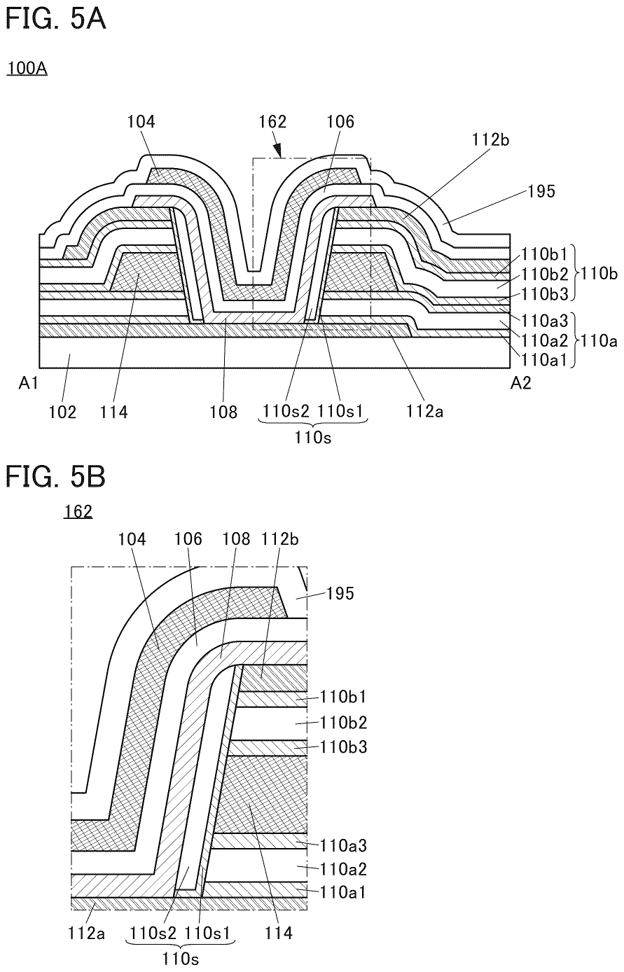

FIG. 5A illustrates a structure example of a transistor 100A having a structure different from that of the transistor 100 illustrated in FIG. 1A to FIG. 2. FIG. 5A is a cross-sectional view of the transistor 100A corresponding to the dashed-dotted line A1-A2 in the plan view of FIG. 1A. FIG. 5B is an enlarged view of a region 162 illustrated in FIG. 5A.

The transistor 100A illustrated in FIG. 5A differs from the transistor 100 illustrated in FIG. 1B mainly in that the insulating layer 110s has a stacked-layer structure of an insulating layer 110s1 and an insulating layer 110s2 over the insulating layer 110s1. The insulating layer 110s1 is provided in contact with the top surface of the conductive layer 112a, the side surface of the insulating layer 110a, the side surface of the conductive layer 114, the side surface of the insulating layer 110b, and the side surface of the conductive layer 112b. The insulating layer 110s2 is provided to face the top surface of the conductive layer 112a, the side surface of the insulating layer 110a, the side surface of the conductive layer 114, the side surface of the insulating layer 110b, and the side surface of the conductive layer 112b with the insulating layer 110s1 therebetween.

For the insulating layer 110s1, the material, the manufacturing method, and the like used for the insulating layer 110a1, the insulating layer 110a3, the insulating layer 110b1, and the insulating layer 110b3 can be used, for example. For the insulating layer 110s2, the material, the manufacturing method, and the like used for the insulating layer 110a2 and the insulating layer 110b2 can be used, for example.

In the case where the insulating layer 110s2 having a function of supplying oxygen is in contact with the conductive layer 114, there is concern that the conductive layer 114 is oxidized, the amount of oxygen included in the insulating layer 110s2 is reduced, and thus the amount of oxygen supplied from the insulating layer 110s2 to the semiconductor layer 108 is reduced. When the insulating layer 110s has a stacked-layer structure of the insulating layer 110s1 and the insulating layer 110s2, a structure in which the insulating layer 110s2 is not in contact with the conductive layer 114 can be obtained. Accordingly, oxidation of the conductive layer 114 due to oxygen included in the insulating layer 110s2 can be inhibited. Moreover, a reduction in the amount of oxygen supplied from the insulating layer 110s2 to the semiconductor layer 108 can be inhibited.

### Structure Example 3

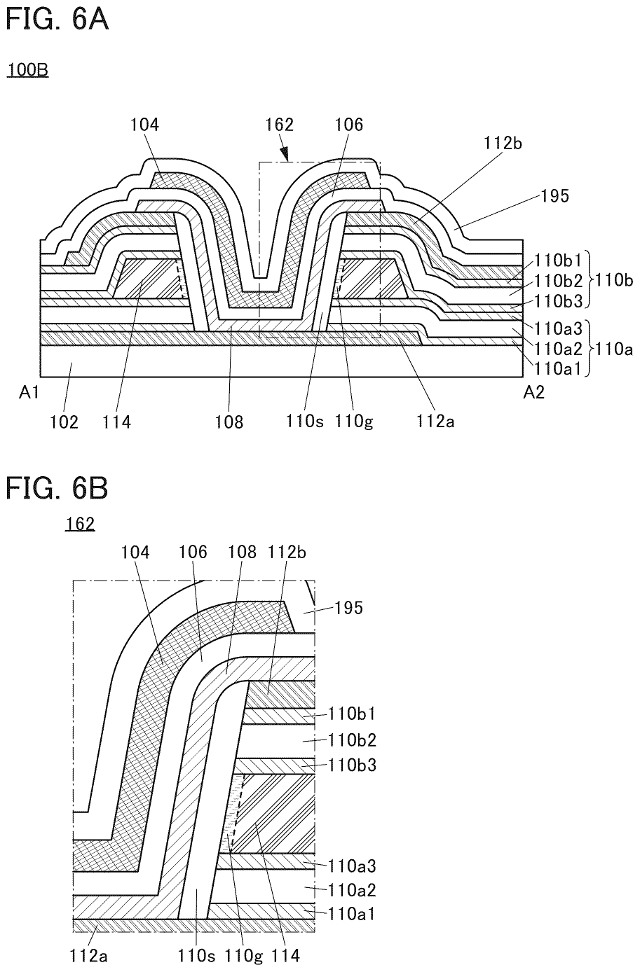

FIG. 6A illustrates a structure example of a transistor 100B having a structure different from that of the transistor 100 illustrated in FIG. 1A to FIG. 2. FIG. 6A is a cross-sectional view of the transistor 100B corresponding to the dashed-dotted line A1-A2 in the plan view of FIG. 1A. FIG. 6B is an enlarged view of the region 162 illustrated in FIG. 6A.

The transistor 100B illustrated in FIG. 6A is different from the transistor 100 illustrated in FIG. 1B mainly in including an insulating layer 110g between the conductive layer 114 and the insulating layer 110s.

The insulating layer 110g includes an oxide of an element included in the conductive layer 114, for example. In the case where the conductive layer 114 is a metal, for example, the insulating layer 110g is an oxide of the metal. For another example, in the case where the conductive layer 114 is silicon, the insulating layer 110g is a silicon oxide. As the insulating layer 110g, for example, a metal oxide such as aluminum oxide or tantalum oxide can be used, and aluminum oxide is particularly preferably used.

The insulating layer 110g can function as a gate insulating layer (a second gate insulating layer) of the transistor 100B. In the structure illustrated in FIG. 6A, a stacked-layer structure of the insulating layer 110s and the insulating layer 110g functions as the gate insulating layer (the second gate insulating layer) of the transistor 100B, for example.

Note that in the transistor 100B, the stacked-layer structure of the insulating layer 110s and the insulating layer 110g is used as the gate insulating layer (the second gate insulating layer) ; thus, even when the insulating property of the insulating layer 110g is lower than the insulating property of the insulating layer 110s, the electrical characteristics and reliability of the transistor 100B can sometimes be adequately ensured in the case where stacking together with the insulating layer 110s can offer an adequate insulating property.

When the transistor 100B includes the insulating layer 110g, the thickness of the insulating layer 110s can sometimes be reduced. When the thickness of the insulating layer 110s is reduced, the effect of the electric field applied to the semiconductor layer 108 from the second gate electrode (the conductive layer 114) of the transistor 100B can be enhanced. For the insulating layer 110g, a material having a higher relative dielectric constant than the material used for the insulating layer 110s can be suitably used, for example.

The insulating layer 110g can be formed in a self-aligned manner as follows, for example: a layer capable of supplying oxygen is formed to be in contact with a surface of the conductive layer 114 and the surface of the conductive layer 114 is oxidized by supply of oxygen from the insulating layer 110a2 and the insulating layer 110b2 through the layer capable of supplying oxygen. In the case where the level of the upper end portion of the insulating layer 110s is lower than the level of the top surface of the conductive layer 114 in etching at the time of forming the insulating layer 110s or the case where the level of the upper end portion of the insulating layer 110s is higher than the level of the top surface of the conductive layer 114 but the level difference is small, leakage current might flow between the semiconductor layer 108 and the conductive layer 114 and the electrical characteristics of the transistor 100B might decrease. Even in such a case, the insulating layer 110g included in the transistor 100B can inhibit leakage between the semiconductor layer 108 and the conductive layer 114.

### Structure Example 4

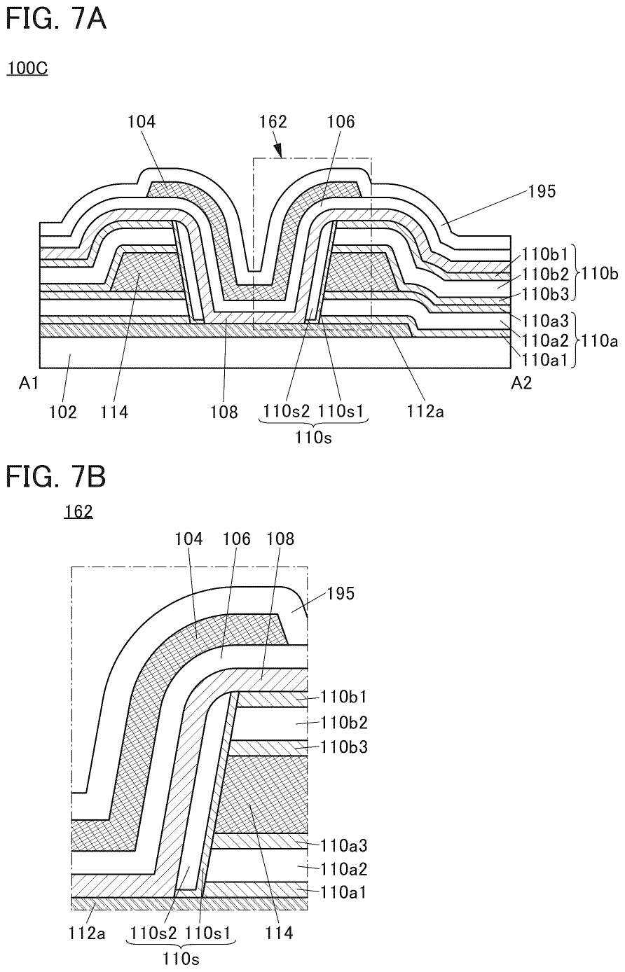

FIG. 7A illustrates a structure example of a transistor 100C having a structure different from that of the transistor 100 illustrated in FIG. 1A to FIG. 2. FIG. 7A is a cross-sectional view of the transistor 100C corresponding to the dashed-dotted line A1-A2 in the plan view of FIG. 7A. FIG. 7B is an enlarged view of the region 162 shown in FIG. 7A.

The transistor 100C illustrated in FIG. 7A differs from the transistor 100 illustrated in FIG. 1B mainly in that the conductive layer 112b is not provided and the end portion of the semiconductor layer 108 extends beyond the end portions of the conductive layer 114 and the conductive layer 112a in the plan view.

In the transistor 100C, the semiconductor layer 108 includes regions in contact with the top surface of the conductive layer 112a, the side surface of the insulating layer 110s, and the top surface of the insulating layer 110b. The semiconductor layer 108 in the transistor 100C can have both the function of the semiconductor layer including the channel formation region and the function of the other of the source electrode and the drain electrode. For example, a region of the semiconductor layer 108 facing the insulating layer 110s can function as the channel formation region. A region positioned outside the channel formation region (a region in contact with the top surface of the insulating layer 110b) can function as the other of the source electrode and the drain electrode.

For example, the resistance of the semiconductor layer 108 can be reduced by supplying an impurity such as boron to the semiconductor layer 108 from a direction perpendicular to the substrate surface by an ion implantation method, an ion doping method, a plasma immersion ion implantation method, plasma treatment, or the like. Alternatively, in the case where an oxide semiconductor is used for the semiconductor layer 108, a silicon nitride film or the like is formed over a region of the semiconductor layer 108 that overlaps with the insulating layer 110b to change part of the semiconductor layer 108 into an oxide conductor (OC), whereby a low-resistance region can be formed in the semiconductor layer 108. In such a manner, the resistance of the regions of the semiconductor layer 108 corresponding to the source region and the drain region can be made lower than that of the channel formation region. Thus, the channel formation region and the source region and the drain region having lower resistance than the channel formation region can be formed in the semiconductor layer 108. Accordingly, in the transistor 100C, the regions corresponding to the source electrode and the drain electrode can be formed in the semiconductor layer 108 without providing the conductive layer 112b. Since the conductive layer 112b is not provided in the transistor 100C, the number of steps for manufacturing the transistor can be reduced.

### Structure Example 5

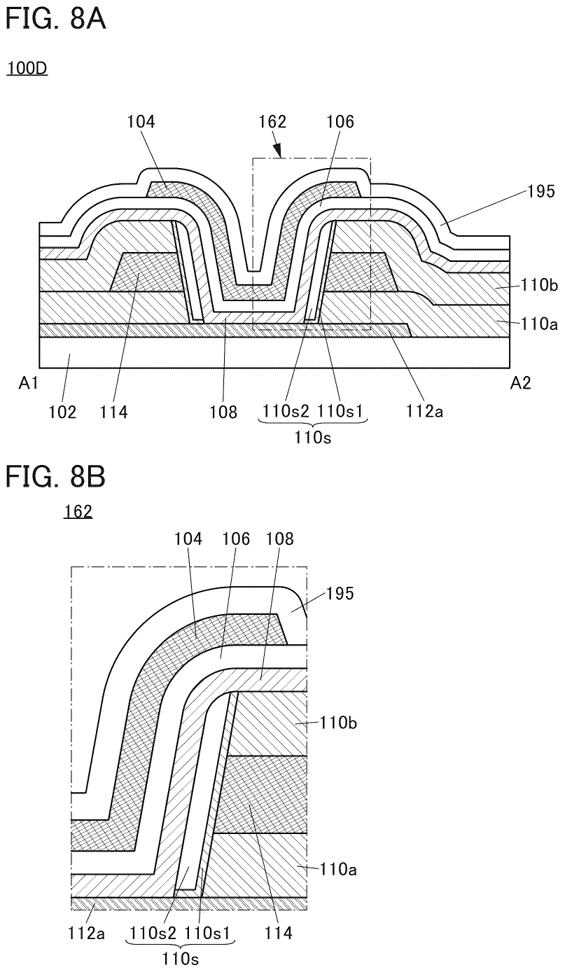

FIG. 8A illustrates a structure example of a transistor 100D having a structure different from that of the transistor 100 illustrated in FIG. 1A to FIG. 2. FIG. 8A is a cross-sectional view of the transistor 100D corresponding to the dashed-dotted line A1-A2 in the plan view of FIG. 1A. FIG. 8B is an enlarged view of the region 162 illustrated in FIG. 8A.

The transistor 100D illustrated in FIG. 8A is different from the transistor 100C illustrated in FIG. 7A mainly in that the insulating layer 110a and the insulating layer 110b each have a single-layer structure.

In the transistor 100D, the above-described materials that can be used for the insulating layer 110a1, the insulating layer 110a3, the insulating layer 110b1, and the insulating layer 110b3 are preferably used for the insulating layer 110a and the insulating layer 110b. That is, a material having a high blocking property against oxygen and hydrogen is preferably used. In that case, the conductive layer 114 can be inhibited from being oxidized by diffusion of oxygen from the outer side of the insulating layer 110a and the insulating layer 110b. Furthermore, oxygen in the semiconductor layer 108 can be inhibited from diffusing towards the insulating layer 110a and the insulating layer 110b and forming oxygen vacancies (Vo) in the semiconductor layer 108. With the insulating layer 110a and the insulating layer 110b each having a single-layer structure, the number of steps for forming the insulating layer 110a and the insulating layer 110b can be smaller than that in the transistor 100 and the like.

### Structure Example 6

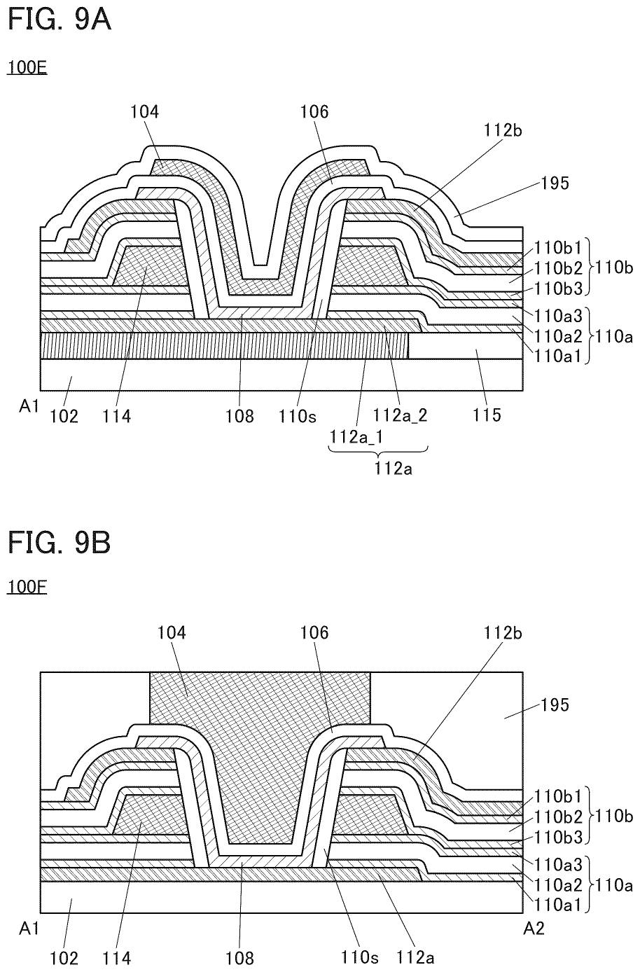

FIG. 9A illustrates a structure example of a transistor 100E having a structure different from that of the transistor 100 illustrated in FIG. 1A to FIG. 2. FIG. 9A is a cross-sectional view of the transistor 100E corresponding to the dashed-dotted line A1-A2 in the plan view of FIG. 1A.

The transistor 100E illustrated in FIG. 9A differs from the transistor 100 illustrated in FIG. 1B mainly in that the conductive layer 112a has a stacked-layer structure.

In the transistor 100E, the conductive layer 112a has a stacked-layer structure of a conductive layer 112a_1 and a conductive layer 112a_2 over the conductive layer 112a_1. The conductive layer 112a_1 is provided to be embedded in an opening formed in an insulating layer 115, and the top surface of the conductive layer 112a_1 and the top surface of the insulating layer 115 are planarized. The conductive layer 112a_2 is positioned over the conductive layer 112a_1 and the insulating layer 115. In the transistor 100E, the top surface of the insulating layer 115 and the top surface of the conductive layer 112a_1 are level or substantially level with respect to the substrate surface.

In the transistor 100E, the level of the top surface of the insulating layer 115 and the level of the top surface of the conductive layer 112a_1 are equal to or substantially equal to each other, so that steps on the formation surfaces of the insulating layer 110a, the insulating layer 110b, and the conductive layer 112b can be smaller than those of the structure in which the levels are not equal or substantially not equal. Thus, a step that might be generated on the top surface of the conductive layer 112b and a step that might be generated on the top surface of the insulating layer 110b can be small. Thus, in the formation step (e.g., an etch-back step) of the insulating layer 110s, the insulating layer can be inhibited from remaining on the top surface of the conductive layer 112b and the top surface of the insulating layer 110b, so that the insulating layer can be selectively formed on the sidewall of the opening in each of the insulating layer 110a, the insulating layer 110b, the conductive layer 114, and the conductive layer 112b.

Note that illustrated is an example in which the end portion of the conductive layer 112a_2 in the transistor 100E is positioned outward from the end portion of the conductive layer 112a_1, the end portion of the conductive layer 112a_2 may be positioned inward from the end portion of the conductive layer 112a_1. In the case of providing a plug (not illustrated) that connects the conductive layer 112a and a conductive layer thereover, the conductive layer 112a_2 may be made to extend beyond the conductive layer 112a_1 so that the top surface of the conductive layer 112a_2 is in contact with the plug in the extending region. The plug is provided to fill an opening (not illustrated) formed in the insulating layer 110a, the insulating layer 110b, the insulating layer 195, and the like.

As described above, a material that is less likely to be oxidized is preferably used for each of the conductive layer 112a and the conductive layer 112b in contact with the semiconductor layer 108. However, the use of a material that is less likely to be oxidized might increase the resistance of the conductive layer 112a and the conductive layer 112b. The conductive layer 112a and the conductive layer 112b function as wirings and thus preferably have low resistance. In view of this, a material that is less likely to be oxidized is used for the conductive layer 112a_2 including a region in contact with the semiconductor layer 108, and a low-resistance material is used for the conductive layer 112a_1 not including a region in contact with the semiconductor layer 108, whereby the resistance of the conductive layer 112a can be reduced. Furthermore, the amount of oxygen vacancy (Vo) and VoH in the semiconductor layer 108 can be reduced.

Particularly in the case where the channel length L100 is short, an oxygen vacancy (Vo) and VoH in the channel formation region greatly affect the electrical characteristics and the reliability of the transistor, as described above. When a material that is less likely to be oxidized is used for the conductive layer 112a_2, an increase in the amount of oxygen vacancy (Vo) and VoH in the semiconductor layer 108 can be inhibited. Thus, the transistor with a short channel length having favorable electrical characteristics and high reliability can be provided.

One or more of an oxide conductor and a nitride conductor can be suitably used for the conductive layer 112a_2. The conductive layer 112a_1 is preferably formed using a material having lower resistance than a material for the conductive layer 112a_2. For the conductive layer 112a_1, one or more of copper, aluminum, titanium, tungsten, and molybdenum or an alloy including one or more of these metals as its components can be suitably used, for example. Specifically, In—Sn-Si oxide (ITSO) and tungsten can be suitably used for the conductive layer 112a_2 and the conductive layer 112a_1, respectively.

Note that the structure of the conductive layer 112a is determined in accordance with wiring resistance required for the conductive layer 112a. For example, when it is not a problem if the wiring (the conductive layer 112a) has a short length and requires relatively high wiring resistance, the conductive layer 112a may have a single-layer structure using a material that is less likely to be oxidized. Meanwhile, when the wiring (the conductive layer 112a) is long and requires relatively low wiring resistance, the conductive layer 112a preferably has a stacked-layer structure using a material that is less likely to be oxidized and a low-resistance material.

For the insulating layer 115, an inorganic insulating material or an organic insulating material can be used. The insulating layer 115 may have a stacked-layer structure of an inorganic insulating material and an organic insulating material. For example, any of the materials and structures given as examples for the insulating layer 110a2, the insulating layer 110b2, the insulating layer 195, and the like can be suitably used for the insulating layer 115.

### Structure Example 7

FIG. 9B illustrates a structure example of a transistor 100F having a structure different from that of the transistor 100 illustrated in FIG. 1A to FIG. 2. FIG. 9B is a cross-sectional view of the transistor 100F corresponding to the dashed-dotted line A1-A2 in the plan view of FIG. 1A.

The transistor 100F illustrated in FIG. 9B differs from the transistor 100 illustrated in FIG. 1B mainly in the structure of the conductive layer 104 and the structure of the insulating layer 195.

In the transistor 100F, the conductive layer 104 is provided over the semiconductor layer 108 and the insulating layer 106 to fill a concave portion that has a shape along the side surface of the insulating layer 110s and the top surface of the conductive layer 112a, and the insulating layer 195 is provided to make the conductive layer 104 embedded therein. In the transistor 100F, the top surface of the conductive layer 104 and the top surface of the insulating layer 195 are planarized. In the transistor 100F, the top surface of the conductive layer 104 with respect to the substrate surface is level or substantially level with the top surface of the insulating layer 195 with respect to the substrate surface.

In the transistor 100F having the above structure, coverage with a film provided over the conductive layer 104 and the insulating layer 195 can be improved.

### Structure Example 8

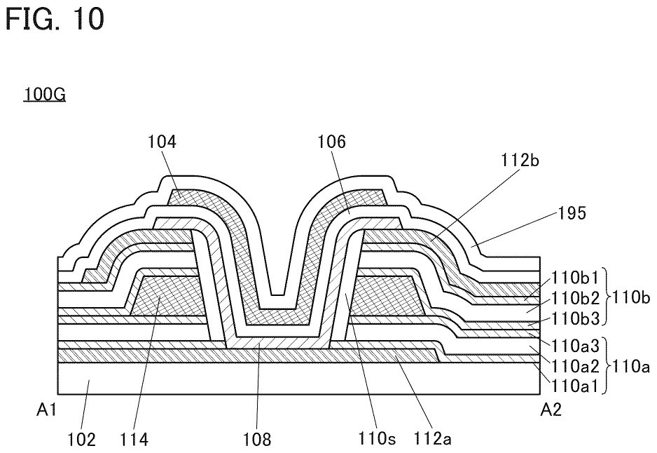

FIG. 10 illustrates a structure example of a transistor 100G having a structure different from that of the transistor 100 illustrated in FIG. 1A to FIG. 2. FIG. 10 is a cross-sectional view of the transistor 100G corresponding to the dashed-dotted line A1-A2 in the plan view of FIG. 1A.

The transistor 100G illustrated in FIG. 10 is different from the transistor 100 illustrated in FIG. 1B mainly in the structure of the insulating layer 110s.

In the transistor 100G, the bottom surface of the insulating layer 110s is in contact with the top surface of the insulating layer 110a1, and the side surface of the insulating layer 110a1 is in contact with the semiconductor layer 108. That is, in the transistor 100G, the insulating layer 110s is not in contact with the conductive layer 112a.

As described above, the insulating layer 110s can have a function of supplying oxygen to the semiconductor layer 108 together with the insulating layer 110a2 and the insulating layer 110b2. Thus, in the case where the bottom surface of the insulating layer 110s is in contact with the conductive layer 112a as in the transistor 100 or the like, there is a risk that oxygen diffused from the insulating layer 110s oxidizes part of the top surface of the conductive layer 112a to increase the resistance and induce a defect of lowering the on-state current of the transistor. In contrast, a structure in which the insulating layer 110s and the conductive layer 112a are not in contact with each other as in the transistor 100G can reduce the risk of inducing the above defect.

### Structure Example 9

The semiconductor device of one embodiment of the present invention can include any one or more of the transistor 100 and the transistor 100A to the transistor 100G described above. The transistor 100 and the transistor 100A to the transistor 100G each include a second gate electrode (the conductive layer 114). Meanwhile, in the semiconductor device of one embodiment of the present invention, not all the transistors included in the semiconductor device necessarily include a second gate electrode (the conductive layer 114), and some of the transistors may include no second gate electrode (the conductive layer 114).

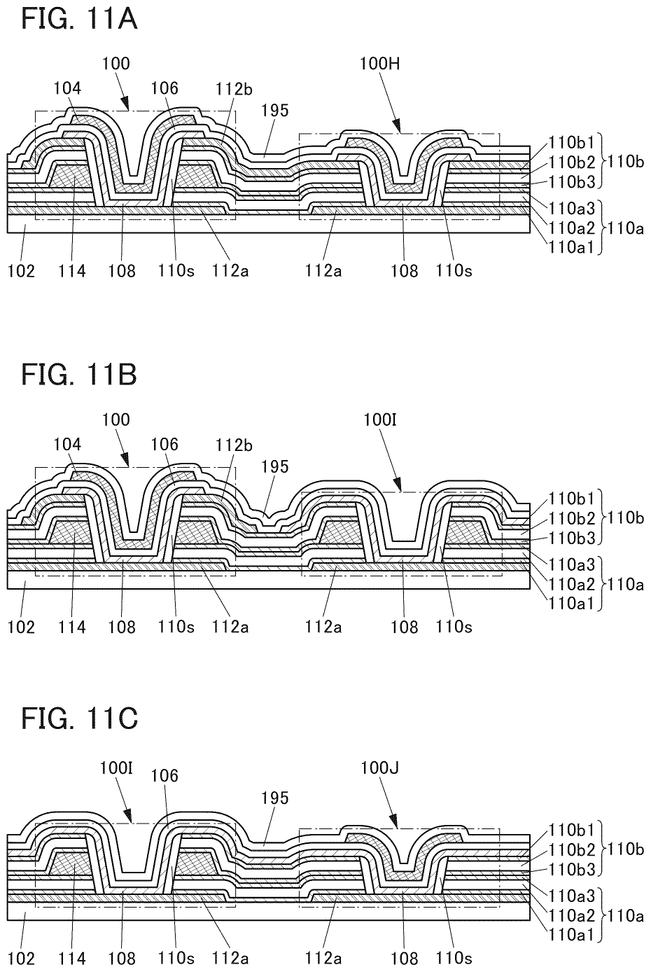

FIG. 11A illustrates an example of a semiconductor device including a transistor including the second gate electrode (the conductive layer 114) and a transistor not including the second gate electrode (the conductive layer 114). FIG. 11A illustrates a structure example of a semiconductor device including the transistor 100 including the second gate electrode (the conductive layer 114) and a transistor 100H not including the second gate electrode (the conductive layer 114). The transistor 100H has a structure similar to that of the transistor 100 except that the conductive layer 114 is not included. It can be said that the transistor 100H is a transistor having a shorter channel length than the transistor 100 because of not including the conductive layer 114. Thus, the semiconductor device illustrated in FIG. 11A can be regarded as a semiconductor device in which the transistor 100 having excellent on-state current saturation characteristics and the transistor 100H having a high on-state current are combined. The transistor 100 and the transistor 100H can be manufactured through common steps except for some steps (a manufacturing process of the conductive layer 114). As described above, in the semiconductor device of one embodiment of the present invention, the transistor including the second gate electrode (the conductive layer 114) and the transistor not including the second gate electrode (the conductive layer 114) can be separately formed in the same substrate plane, and the semiconductor device can utilize the features of the transistors and achieve high performance.

Note that although the semiconductor device illustrated in FIG. 11A employs the transistor 100 as the transistor including the second gate electrode (the conductive layer 114), one embodiment of the present invention is not limited thereto. Any of the transistor 100A to the transistor 100G may be employed as the transistor including the second gate electrode (the conductive layer 114). Although the semiconductor device illustrated in FIG. 11A employs the structure not including the conductive layer 114 of the transistor 100 (the transistor 100H) as a transistor not including the second gate electrode (the conductive layer 114), one embodiment of the present invention is not limited thereto. As the transistor not including the second gate electrode (the conductive layer 114), a structure not including the conductive layer 114 of any of the transistor 100A to the transistor 100G may be employed.

### Structure Example 10

FIG. 11B illustrates an example of a semiconductor device including the transistor 100 and a transistor 100I having a structure in which the first gate electrode (the conductive layer 104) is omitted from the transistor 100C illustrated in FIG. 7A.

As described above, the semiconductor layer 108 in the transistor 100C can have both the function of the semiconductor layer including the channel formation region and the function of the other of the source electrode and the drain electrode. The same applies to the transistor 100I. That is, in the transistor 100I, a region of the semiconductor layer 108 facing the conductive layer 114 with the insulating layer 110s therebetween can function as a channel formation region. The region positioned outside the channel formation region (the region in contact with the top surface of the insulating layer 110b) can function as the other of the source electrode and the drain electrode.

As described above, the semiconductor device of one embodiment of the present invention may include a transistor including two gate electrodes, such as the transistor 100 or the like, and a transistor including only one gate electrode, such as the transistor 100H or the transistor 100I. The transistor 100 and the transistor 100I can be manufactured through common steps except for some steps (a manufacturing process of the conductive layer 104). As described above, in the semiconductor device of one embodiment of the present invention, the transistor including the second gate electrode (the conductive layer 104 in this case) and the transistor not including the second gate electrode (the conductive layer 104 in this case) can be separately formed in the same substrate plane, and the semiconductor device can utilize the features of the transistors and achieve high performance.

### Structure Example 11

FIG. 11C illustrates an example of a semiconductor device including the transistor 100I illustrated in FIG. 11B and a transistor 100J having a structure in which the second gate electrode (the conductive layer 114) is omitted from the transistor 100C.

The above content of description can be referred to for the transistor 100I. In the transistor 100J, a region of the semiconductor layer 108 facing the conductive layer 104 with the insulating layer 106 therebetween can function as the channel formation region. The region positioned outside the channel formation region (the region in contact with the top surface of the insulating layer 110b) can function as the other of the source electrode and the drain electrode.

Although each of the transistor 100I and the transistor 100J has a structure including only one gate electrode, conductive layers formed over different layers are used as the gate electrodes. The transistor 100I and the transistor 100J can be manufactured in common steps except for some steps (a manufacturing process of the conductive layer 114 and the conductive layer 104). As described above, transistors having different structures can be separately formed in the same substrate plane in the semiconductor device of one embodiment of the present invention; thus, the degree of flexibility in manufacturing the semiconductor device can be increased.

### Manufacturing Method Example

A method for manufacturing the transistor of one embodiment of the present invention will be described below with reference to drawings. Here, description will be made using the transistor 100 illustrated in FIG. 1B and the like as an example.

Note that thin films that form the semiconductor device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like.

Examples of the sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

The CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. The thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, or the like can be used.

The CVD method and the ALD method are different from the sputtering method in which particles ejected from a target or the like are deposited. Thus, the CVD method and the ALD method are deposition methods that enable good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low film formation speed, and thus is preferably used in combination with another deposition method with a high deposition speed, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the semiconductor device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

The thin films that form the semiconductor device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

When the thin films that form the semiconductor device are processed, a photolithography method or the like can be used for the processing. Alternatively, a nanoimprinting method, a sandblasting method, a lift-off method, or the like may be used for the processing of the thin films. Island-shaped thin films may be directly formed by a deposition method using a blocking mask such as a metal mask.

There are the following two typical examples of a photolithography method. In one of the methods, a resist mask is formed over a thin film that is to be processed, the thin film is processed by etching or the like, and the resist mask is removed. In the other method, a photosensitive thin film is formed and then the thin film is processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. In addition, light exposure may be performed by liquid immersion exposure technique. As the light used for light exposure, extreme ultraviolet (EUV) light, X-rays, or the like may be used. Instead of the light used for light exposure, an electron beam can be used. It is preferable to use extreme ultraviolet light, X-rays, or an electron beam because extremely fine processing can be performed. Note that in the case of performing light exposure by scanning of a beam such as an electron beam, a photomask is not needed.

For etching of a thin film, a dry etching method, a wet etching method, or a sandblasting method can be used, for example.

For planarization treatment of thin films, typically, a polishing method such as a CMP method can be suitably used. A reflow method in which a conductive layer is fluidized by heat treatment can be suitably used. Alternatively, a combination of the reflow method and the CMP method may be used. Alternatively, dry etching treatment or plasma treatment may be used. Note that polishing treatment, dry etching treatment, or plasma treatment may be performed a plurality of times, or these treatments may be performed in combination. In the case where the treatments are performed in combination, the order of steps is not particularly limited and may be set as appropriate depending on the roughness of a surface to be processed.

In order to accurately process the thin film to have a desired thickness, for example, the CMP method is employed. In that case, first, polishing is performed at a constant processing rate until part of the top surface of the thin film is exposed. After that, polishing is performed under a condition with a lower processing rate until the thin film has a desired thickness, so that highly accurate processing can be performed.

Examples of a method for detecting the end of the polishing include an optical method in which the surface to be processed is irradiated with light and a change in the reflected light is detected; a physical method in which a change in the polishing resistance received by the processing apparatus from the surface to be processed is detected; and a method in which a magnetic line is applied to the surface to be processed and a change in the magnetic line due to the generated eddy current is used.

After the top surface of the thin film is exposed, polishing treatment is performed under a condition with a low processing rate while the thickness of the thin film is monitored by an optical method using a laser interferometer or the like, whereby the thickness of the thin film can be controlled with high accuracy. Note that the polishing treatment may be performed a plurality of times until the thin film has a desired thickness, as necessary.

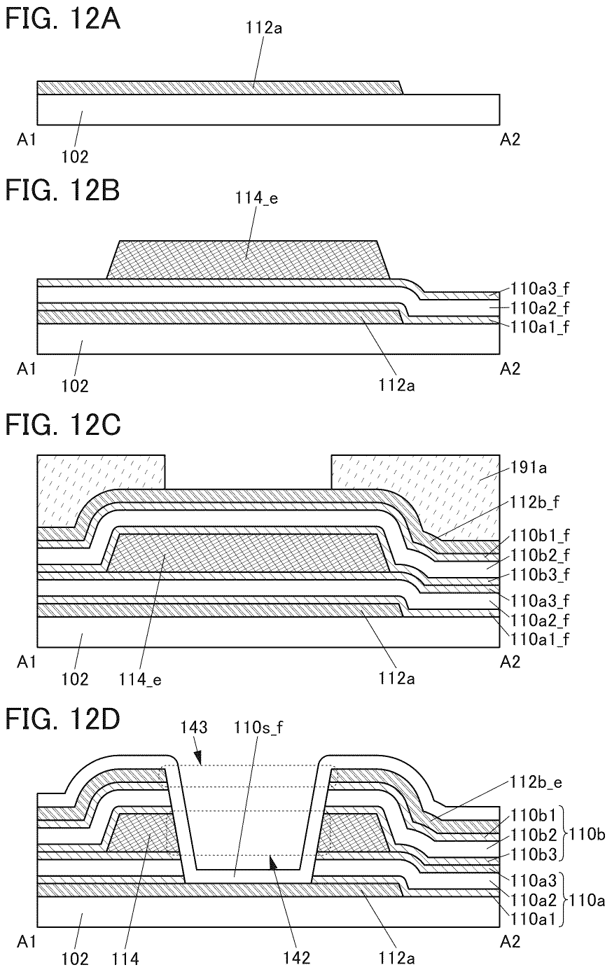

FIG. 12A to FIG. 14C are diagrams illustrating a method for manufacturing the transistor 100. Each drawing is a cross-sectional view along the dashed-dotted line A1-A2 of the plan view illustrated in FIG. 1A.

First, a conductive film to be the conductive layer 112a is formed over the substrate 102, and part of the conductive film is removed to form the conductive layer 112a (FIG. 12A). A sputtering method can be suitably used for forming the conductive film, for example. For processing of the conductive film, one or both of a wet etching method and a dry etching method can be used.

Next, an insulating film 110a1_f is formed over the conductive layer 112a and the substrate 102, an insulating film 110a2_f is formed over the insulating film 110a1_f, and an insulating film 110a3_f is formed over the insulating film 110a2_f.

For the insulating film 110a1_f and the insulating film 110a3_f, any of the materials that can be used for the insulating layer 110a1 and the insulating layer 110a3 described above can be used as appropriate.

For the insulating film 110a1_f and the insulating film 110a3_f, silicon nitride, silicon nitride oxide, aluminum oxide, hafnium oxide, or the like can be suitably used, for example.

Specifically, for the insulating film 110a1_f and the insulating film 110a3_f, silicon nitride can be deposited by a sputtering method, for example. For another example, silicon nitride can be deposited by a PEALD method. For another example, aluminum oxide can be deposited by a sputtering method.

For another example, a structure in which aluminum oxide and silicon nitride are stacked can be used. For example, a stack of aluminum oxide deposited by a sputtering method and silicon nitride deposited by a PEALD method can be used.

For the insulating film 110a2_f, any of the materials that can be used for the insulating layer 110a2 described above can be used as appropriate.

For the insulating film 110a2_f, silicon oxide, silicon oxynitride, or the like can be suitably used, for example.

Specifically, for the insulating film 110a2_f, silicon oxide can be deposited by a sputtering method, for example. For another example, silicon oxide can be deposited by a PECVD method. For another example, silicon oxynitride can be deposited by a PECVD method.

For another example, a stack of silicon oxide deposited by a sputtering method and silicon oxide or silicon oxynitride deposited by a PECVD method can be used.

After the insulating film 110a2_f is formed, heat treatment may be performed. By performing the heat treatment, water and hydrogen can be released from the surface and inside of the insulating film 110a2_f.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere including one or more of a noble gas, nitrogen, and oxygen. As an atmosphere including nitrogen or an atmosphere including oxygen, clean dry air (CDA) may be used. The content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating film 110a2_f can be prevented as much as possible. An oven or a rapid thermal annealing (RTA) apparatus can be used for the heat treatment, for example. The use of the RTA apparatus can shorten the heat treatment time.

After the heat treatment, a step of supplying oxygen to the insulating film 110a2_f may be performed. For example, oxygen may be supplied to the insulating film 110a2_f by forming a metal oxide layer over the insulating film 110a2_f after the formation of the insulating film 110a2_f. After the formation of the metal oxide layer, heat treatment may be performed. By the heat treatment performed after the formation of the metal oxide layer, oxygen can be effectively supplied from the metal oxide layer to the insulating film 110a2_f, and oxygen can be included in the insulating film 110a2_f. Oxygen supplied to the insulating film 110a2_f is supplied to the semiconductor layer 108 in a later step, whereby oxygen vacancies (Vo) and VoH in the semiconductor layer 108 can be reduced.

After the formation of the metal oxide layer or after the above-described heat treatment, oxygen may be further supplied to the insulating film 110a2_f through the metal oxide layer. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of an apparatus in which a gas is made to be plasma by high-frequency power include a plasma etching apparatus and a plasma ashing apparatus.

The metal oxide layer may be an insulating layer or a conductive layer. For the metal oxide layer, aluminum oxide, hafnium oxide, hafnium aluminate, indium oxide, indium tin oxide (ITO), or indium tin oxide including silicon (ITSO) can be used, for example.

An oxide material including one or more elements that are the same as those in the semiconductor layer 108 is preferably used for the metal oxide layer. It is particularly preferable to use an oxide semiconductor material that can be used for the semiconductor layer 108.

When a metal oxide material including indium and gallium is used for the metal oxide layer, a material whose composition (content percentage) of gallium is higher than that in the semiconductor layer 108 can be used for the metal oxide layer. With the use of a material having a high gallium composition (content percentage) for the metal oxide layer, an oxygen blocking property can be further increased. This is preferable because oxygen supplied to the insulating film 110a2_f can be inhibited from being released to the outside through the metal oxide layer.

The metal oxide layer is preferably formed in, for example, an oxygen-containing atmosphere. It is particularly preferable that the metal oxide layer be formed by a sputtering method in an oxygen-containing atmosphere. In that case, oxygen can be suitably supplied to the insulating film 110a2_f at the time of forming the metal oxide layer.

Then, the metal oxide layer is removed. For the metal oxide layer, a wet etching method can be suitably used, for example.

The treatment for supplying oxygen to the insulating film 110a2_f is not necessarily performed by the above-described method. An oxygen radical, an oxygen atom, an oxygen atomic ion, an oxygen molecular ion, or the like is supplied to the insulating film 110a2_f by an ion doping method, an ion implantation method, plasma treatment, or the like, for example. Alternatively, a film that inhibits oxygen release may be formed over the insulating film 110a2_f, and then oxygen may be supplied to the insulating film 110a2_f through the film. It is preferable to remove the film after supply of oxygen. As the above film that inhibits oxygen release, a conductive film or a semiconductor film including one or more of indium, zinc, gallium, tin, aluminum, chromium, tantalum, titanium, molybdenum, nickel, iron, cobalt, and tungsten can be used.

Next, a conductive film to be a conductive layer 114_e is formed over the insulating film 110a3_f and the conductive film is partly removed to be processed, so that the conductive layer 114_e is formed (FIG. 12B). The conductive layer 114_e is formed to include a region overlapping with the conductive layer 112a. Note that an opening is provided in the conductive layer 114_e in a structure described later, so that the conductive layer 114 can be formed.

Next, an insulating film 110b3_f is deposited over the insulating film 110a3_f and the conductive layer 114_e, an insulating film 110b2_f is deposited over the insulating film 110b3_f, and an insulating film 110b1_f is deposited over the insulating film 110b2_f.

For the insulating film 110b2_f, any of the materials that can be used for the insulating layer 110b2 described above can be used as appropriate. For each of the insulating film 110b1_f, and the insulating film 110b3_f, any of the above-described materials that can be used for the insulating layer 110b1 and the insulating layer 110b3 can be used as appropriate.

For the material and the deposition method that can be used for the insulating film 110b2_f, refer to the description of the insulating film 110a2_f. For the material and the deposition method that can be used for the insulating film 110b1_f and the insulating film 110b3_f, refer to the description of the insulating film 110a1_f and the insulating film 110a3_f.

Note that after the insulating film 110b2_f is deposited, a step of supplying oxygen to the insulating film 110b2_f may be performed. For the step, refer to the above description of the step of supplying oxygen to the insulating film 110a2_f.

Next, a conductive film 112b_f is deposited over the insulating film 110b1_f. For the conductive film 112b_f, any of the materials that can be used for the conductive layer 112b described above can be used as appropriate.

Next, a resist mask 191a is formed over the conductive film 112b_f by photolithography (FIG. 12C).

Next, the conductive film 112b_f, the insulating film 110b1_f, the insulating film 110b2_f, the insulating film 110b3_f, the conductive layer 114_e, the insulating film 110a3_f, the insulating film 110a2_f, and the insulating film 110a1_f are partly removed using the resist mask 191a as a mask, so that a conductive layer 112b_e having an opening (the opening 143), the insulating layer 110b1 having an opening, the insulating layer 110b2 having an opening, the insulating layer 110b3 having an opening, the conductive layer 114 having an opening (the opening 142), the insulating layer 110a3 having an opening, the insulating layer 110a2 having an opening, and the insulating layer 110a1 having an opening are formed in this order, and the top surface of the conductive layer 112a that does not overlap with the resist mask 191a is exposed. After that, the resist mask 191a is removed.

Next, an insulating film 110s_f is formed in contact with the top surface of the conductive layer 112b_e, a sidewall of the opening (the opening 143) in the conductive layer 112b_e (i.e., the side surface of the conductive layer 112b_e on the side facing the opening 143), a sidewall of the opening in the insulating layer 110b1 (i.e., the side surface of the insulating layer 110b1 on the side facing the opening), a sidewall of the opening in the insulating layer 110b2 (i.e., the side surface of the insulating layer 110b2 on the side facing the opening), a sidewall of the opening in the insulating layer 110b3 (i.e., the side surface of the insulating layer 110b3 on the side facing the opening), a sidewall of the opening (the opening 142) in the conductive layer 114 (i.e., the side surface of the conductive layer 114 facing the opening), a sidewall of the opening in the insulating layer 110a3 (i.e., the side surface of the insulating layer 110a3 facing the opening), a sidewall of the opening in the insulating layer 110a2 (i.e., the side surface of the insulating layer 110a2 facing the opening), a sidewall of the opening in the insulating layer 110a1 (i.e., the side surface of the insulating layer 110a1 facing the opening), and the top surface of the exposed conductive layer 112a (FIG. 12D).

For the insulating film 110s_f, any of the materials that can be used for the insulating layer 110s described above can be used as appropriate.

The insulating film 110s_f is preferably deposited by a CVD method, an ALD method, or the like, in which case the insulating film 110s_f can suitably cover the sidewall of the opening in the conductive layer 112b_e, the sidewall of the opening in the insulating layer 110b, the sidewall of the opening in the conductive layer 114, and the sidewall of the opening in the insulating layer 110a, for example.

Next, the insulating film 110s_f is partly removed by etching to form the insulating layer 110s. Specifically, part of the insulating film 110s_f (a region in contact with the top surface of the conductive layer 112a and a region in contact with the top surface of the conductive layer 112b_e) is removed by etching such that regions of the insulating film 110s_f that are in contact with the sidewall of the opening in the conductive layer 112b_e, the sidewall of the opening in the insulating layer 110b, the sidewall of the opening in the conductive layer 114, and the sidewall of the opening in the insulating layer 110a remain, whereby the insulating layer 110s can be formed. An upper end portion of the insulating layer 110s has a curved shape.

Anisotropic etching can be used as etching of the insulating film 110s_f, for example. Specifically, the insulating layer 110s can be formed by performing highly anisotropic etching in dry etching, for example.

Note that a step in which a planarization film is formed on the surface of an uneven film and highly anisotropic etching (e.g., dry etching) is performed on the uneven film together with the planarization film to reduce the unevenness of the film is sometimes referred to as an “etch-back step”.

By changing the conditions of the anisotropic etching, the level of the upper end portion of the insulating layer 110s can be adjusted as illustrated in FIG. 4A to FIG. 4D.

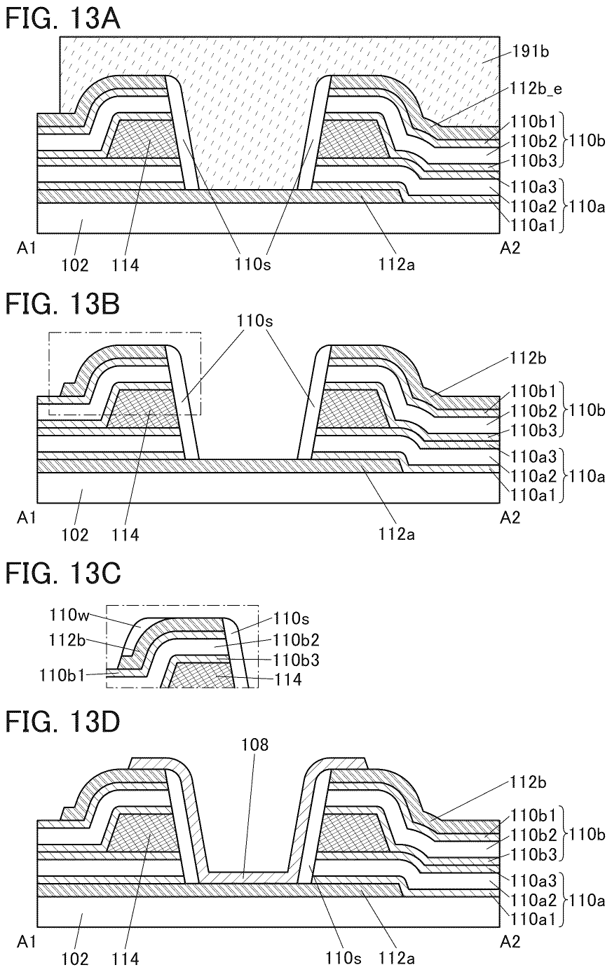

Next, a resist mask 191b is formed to cover the top surface of the conductive layer 112b_e and the like (FIG. 13A). After that, the conductive layer 112b_e is partly removed using the resist mask 191b as a mask to form the conductive layer 112b. After the formation of the conductive layer 112b, the resist mask 191b is removed (FIG. 13B).

Before the resist mask 191a is formed in FIG. 12C, the resist mask 191b may be formed over the conductive film 112b_f, the conductive film 112b_f may be processed, the resist mask 191b may be removed, the resist mask 191a may be formed, and then the conductive film 112b_f, the insulating film 110b1_f, the insulating film 110b2_f, the insulating film 110b3_f, the conductive layer 114_e, the insulating film 110a3_f, the insulating film 110a2_f, and the insulating film 110a1_f may be processed.

Note that as illustrated in FIG. 13C, a sidewall insulating layer 110w is sometimes formed on the side surface of the conductive layer 112b depending on the formation conditions of the conductive layer 112b. FIG. 13C corresponds to a region surrounded by a dashed line in FIG. 13B. In the case where the conductive film 112b_f is partly removed before the deposition of the insulating film 110s_f to form a pattern, for example, a sidewall insulating layer is sometimes formed at an end portion of the pattern. Such insulating layer 110w can be formed not only on the side surface of the conductive layer 112b but also on a portion of the formation surface of the insulating film 110s_f that has unevenness.

Next, a semiconductor film to be the semiconductor layer 108 is formed to cover the exposed top surface of the conductive layer 112a, the sidewall of the insulating layer 110s (that is, the side surface and a curved portion of the insulating layer 110s), the top surface of the conductive layer 112b, and the top surface of the insulating layer 110b1. After that, the semiconductor film is partly removed by etching to form the semiconductor layer 108 (FIG. 13D).

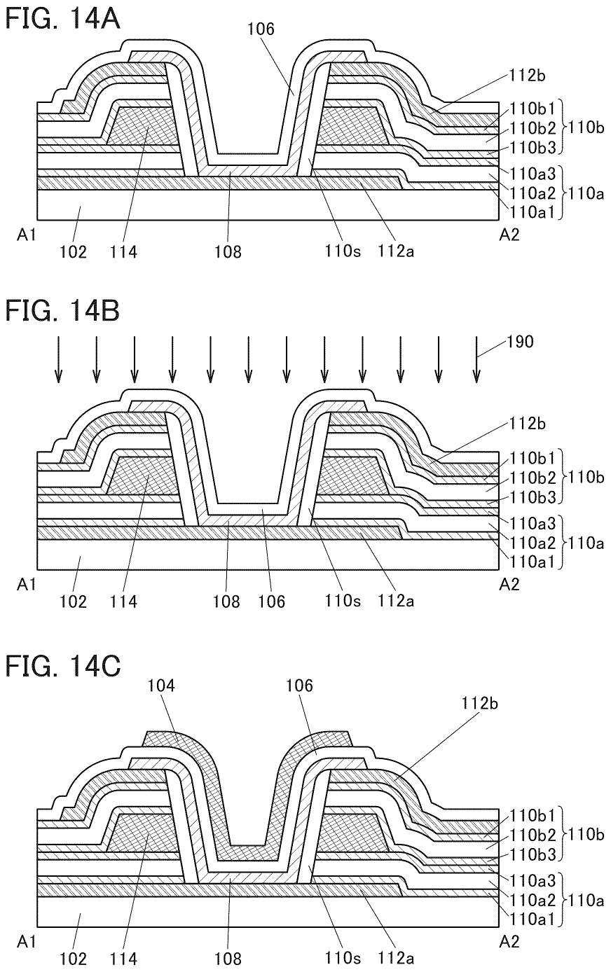

Next, the insulating layer 106 is formed to cover the semiconductor layer 108, the conductive layer 112b, and the insulating layer 110b1 (FIG. 14A).

As the semiconductor layer 108, a film having as uniform thickness as possible is preferably formed on the sidewall of the insulating layer 110s. Thus, the film is preferably deposited by an ALD method.

As a specific example, a deposition method such as a thermal ALD method or a PEALD method is preferably used. A thermal ALD method is preferable because it offers extremely high step coverage. The PEALD method is preferable because of its capability of depositing a film at low temperatures, in addition to its capability of offering high step coverage.

For example, in the case where a metal oxide is used for the semiconductor layer 108, the semiconductor layer can be deposited by an ALD method using an oxidizer and a precursor including a constituent metal element.

In the case of depositing a film of In—Ga—Zn oxide, for example, three precursors of a precursor including indium, a precursor including gallium, and a precursor including zinc can be used. Alternatively, two precursors of a precursor including indium and a precursor including gallium and zinc may be used.

As the precursor including indium, triethylindium, tris(2,2,6,6-tetramethyl-3,5-heptanedionato)indium, cyclopentadienylindium, indium(III) chloride, or the like can be used.

As the precursor including gallium, trimethylgallium, triethylgallium, gallium trichloride, tris(dimethylamido)gallium(III), gallium(III) acetylacetonate, tris(2,2,6,6-tetramethyl-3,5-heptanedionato)gallium, dimethylchlorogallium, diethylchlorogallium, gallium(III) chloride, or the like can be used.

As the precursor including zinc, dimethylzinc, diethylzinc, bis(2,2,6,6-tetramethyl-3,5-heptanedionato)zinc, zinc chloride, or the like can be used.

Ozone, oxygen, water, or the like can be used as the oxidizer, for example.

As an example of a method for controlling the composition of a film to be obtained, adjusting the flow rate ratio of the source gases, the flowing time of the source gases, the flowing order of the source gases, or the like is given. By adjusting such conditions, a film whose composition is continuously changed can be deposited. Furthermore, films having different compositions can be deposited successively.

Heat treatment may be performed after the semiconductor film to be the semiconductor layer 108 is deposited. The heat treatment can reduce water and hydrogen included in the semiconductor film and allows oxygen to be supplied from the insulating layer 110a, the insulating layer 110b, the insulating layer 110s, and the like to the semiconductor film. Note that the heat treatment may be performed after the semiconductor film is processed.

Note that the semiconductor layer 108 is not necessarily deposited by an ALD method and another film formation method can be used as long as the sidewall of the insulating layer 110s can be adequately covered. For example, a sputtering method is preferably used, in which case a film with a low hydrogen content can be obtained relatively easily.

The substrate temperature at the time of forming the semiconductor layer 108 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

The higher the substrate temperature (the stage temperature) in the formation of the metal oxide layer is, the higher the crystallinity of the metal oxide layer can be. Furthermore, the higher the oxygen flow rate ratio is, the higher the crystallinity of the metal oxide layer can be.

Like the semiconductor layer 108, the insulating layer 106 is preferably deposited by a film formation method that offers high step coverage, and is preferably formed by an ALD method. Note that the insulating layer 106 may be formed by a method other than an ALD method, e.g., a deposition method such as a PECVD method or a sputtering method, as long as the semiconductor layer 108 can be adequately covered.

Next, treatment for supplying an impurity 190 to the semiconductor layer 108 through the insulating layer 106 is performed (FIG. 14B). As the impurity 190, an impurity that can be included in the region 108Da, the region 108Db, and part of the region 108L (the region on the region 108Db side) described with reference to FIG. 3, for example, one or more of hydrogen, boron, carbon, nitrogen, phosphorus, sulfur, arsenic, aluminum, magnesium, silicon, and a noble gas are given. Typical examples of a noble gas include helium, neon, argon, krypton, and xenon. In particular, the impurity 190 is preferably one or more of boron, phosphorus, aluminum, magnesium, and silicon. The impurity 190 can be supplied by, for example, an ion implantation method, an ion doping method, a plasma immersion ion implantation method, or plasma treatment.

Note that the supply of the impurity 190 is performed to reduce the resistance of the source region and the drain region (the region 108Da and the region 108Db illustrated in FIG. 3) in the semiconductor layer 108. For this reason, it is preferable that the impurity 190 be supplied only to the source region and the drain region and not to the channel formation region (the region 108I illustrated in FIG. 3). Thus, the impurity 190 is preferably supplied from the direction perpendicular to the substrate surface. The thickness of the insulating layer 106 with respect to the substrate surface is larger in a region provided along the side surface of the insulating layer 110s than in a region provided along the top surface of the conductive layer 112a or the top surface of the conductive layer 112b. Accordingly, when the impurity 190 is supplied from the direction perpendicular to the substrate surface, the impurity 190 can be supplied mainly to the source region and the drain region in the semiconductor layer 108, whereby the resistance of the regions can be selectively reduced.

For example, treatment for supplying the impurity 190 to a component under manufacture is preferably performed by an ion doping method from the direction perpendicular to the substrate surface. In the case where hydrogen is included in the source gas, in the ion doping method in which the source gas is ionized and the ions is supplied to a target without mass separation, all the source gas components (ions) including hydrogen can be supplied to the semiconductor layer 108 as the impurity 190. Hydrogen supplied to the semiconductor layer 108 forms VoH in the semiconductor layer 108, whereby the semiconductor layer 108 is likely to have a low resistance. Thus, the resistance of the source region and the drain region of the semiconductor layer 108 can be easily reduced.

For example, in the case where treatment for supplying the impurity 190 to a component under manufacture is performed by an ion doping method using diborane (B₂H₆) as a source gas from the direction perpendicular to the substrate surface, both boron (B) and hydrogen (H) described above can be supplied as the impurity 190 to the semiconductor layer 108 at the same time. In that case, the resistance of the source region and the drain region in the semiconductor layer 108 can be reduced more efficiently than in the case of using an ion implantation method in which the source gas is ionized and the ion is subjected to mass separation and then supplied to a target in some cases.

Note that an ion implantation method may be used as a method for supplying the impurity 190. For example, as illustrated in FIG. 14(B), in the case where the sidewall of the insulating layer 110s is provided to be inclined with respect to the substrate surface (in the case of having a tapered shape), using an ion doping method for treatment for supplying the impurity 190 may result in impurities such as hydrogen being supplied not only to the source region and the drain region but also to the channel formation region, even when the impurity 190 is supplied from a direction perpendicular to the substrate surface. As described above, it is preferable that hydrogen in the channel formation region be reduced as much as possible. Thus, in some cases, depending on the angle formed by the sidewall of the insulating layer 110s and the substrate surface, an ion implantation method in which the source gas is ionized and the ion is subjected to mass separation to supply only a desired element is preferably used.

For example, with an ion implantation method, even when diborane (B₂H₆) including hydrogen (H) is used as a source gas, boron (B) can be exclusively supplied as the impurity 190 to the semiconductor layer 108 by mass separation. Thus, the resistance of the source region and the drain region can be reduced while impurities such as hydrogen are prevented from being supplied to the channel formation region.

Note that a source gas that can be used at the time of supplying the above impurity 190 is not limited to diborane (B₂H₆) and may be a source gas that does not include hydrogen (H) such as boron trifluoride (BF₃), for example.

Subsequently, a conductive film to be the conductive layer 104 is deposited over the insulating layer 106. Any of the above-described conductive materials can be used for the conductive film as appropriate. The conductive film may be deposited by a sputtering method, a CVD method, an MBE method, a PLD method, an ALD method, or the like as appropriate. Here, the conductive film is preferably formed in contact with the insulating layer 106 that faces the sidewall of the insulating layer 110s. Thus, the conductive film is preferably deposited by a formation method enabling favorable coverage or a good filling property, and is further preferably deposited by a CVD method, an ALD method, or the like.

Subsequently, the conductive film to be the conductive layer 104 is processed, thereby forming the conductive layer 104 (FIG. 14C). The conductive layer 104 is formed to include a region overlapping with the semiconductor layer 108 and the insulating layer 110s in the plan view. The conductive layer 104 can be formed by a photolithography method. A dry etching method or a wet etching method can be employed for the processing. Processing by a dry etching method is suitable for microfabrication.

Note that the treatment for supplying the impurity 190 may be performed not after the formation of the insulating layer 106 but after the formation of the conductive layer 104. In this case, the impurity 190 is supplied only to a region of the source region and the drain region of the semiconductor layer 108 that is on the side not overlapping with the conductive layer 104 (part of the region 108Db illustrated in FIG. 3), and the impurity 190 can be prevented from being supplied to the channel formation region overlapping with the conductive layer 104 (the region 108I illustrated in FIG. 3). Accordingly, even in the case where a tapered shape with a taper angle of less than 90° between the sidewall of the insulating layer 110s and the substrate surface is included, there is no possibility that the impurity 190 is supplied to the channel formation region. Note that the treatment for supplying the impurity 190 may be performed both after the formation of the insulating layer 106 and after the formation of the conductive layer 104.

Subsequently, the insulating layer 195 is formed to cover the conductive layer 104 and the insulating layer 106 (FIG. 1B).

The insulating layer 195 can be formed using a material and a method similar to those for the insulating layer 110a1, the insulating layer 110a3, the insulating layer 110b1, and the insulating layer 110b3, for example.

Through the above process, the semiconductor device including the transistor 100 can be manufactured.

This embodiment can be combined with any of the other embodiments or an example as appropriate. In this specification, in the case where a plurality of structure examples are shown in one embodiment, the structure examples can be combined as appropriate.

### Embodiment 2

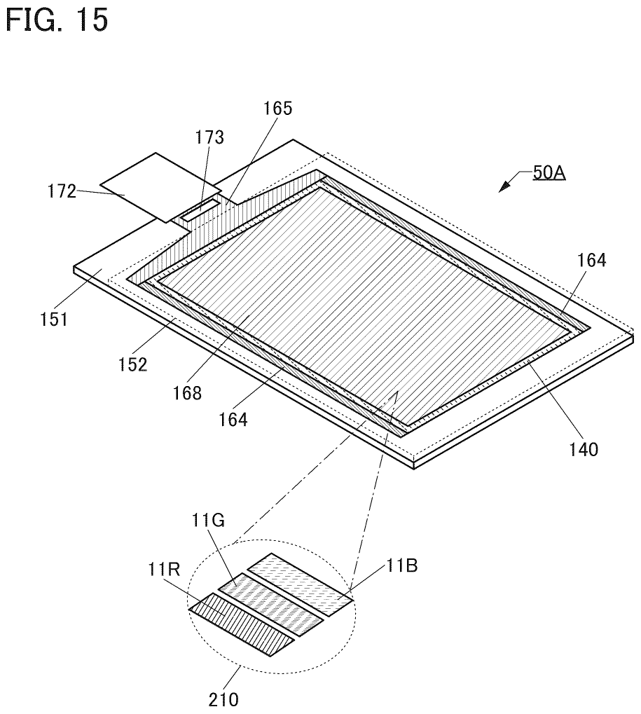

In this embodiment, display apparatuses of one embodiment of the present invention will be described with reference to FIG. 15 to FIG. 20.

The display apparatus in this embodiment can be a high-resolution display apparatus or a large-sized display apparatus. Accordingly, the display apparatus in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

The display apparatus of this embodiment can be a high-definition display apparatus. Accordingly, the display apparatus of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display apparatus or a module including the display apparatus. Examples of the module including the display apparatus include a module in which a connector such as a flexible printed circuit board (hereinafter, referred to as an FPC) or a TCP (Tape Carrier Package) is attached to the display apparatus and a module that is mounted with an integrated circuit (IC) by a COG (Chip On Glass) method, a COF (Chip On Film) method, or the like.

### Display Apparatus 50A

FIG. 15 illustrates a perspective view of a display apparatus 50A.

In the display apparatus 50A, a substrate 152 and a substrate 151 are bonded to each other. In FIG. 15, the substrate 152 is indicated by a dashed line.

The display apparatus 50A includes a display portion 168, a connection portion 140, a circuit portion 164, a wiring 165, and the like. FIG. 15 shows an example in which an IC 173 and an FPC 172 are mounted on the display apparatus 50A. Thus, the structure illustrated in FIG. 15 can be regarded as a display module including the display apparatus 50A, the IC, and the FPC.

The connection portion 140 is provided outside the display portion 168. The connection portion 140 can be provided along one or more sides of the display portion 168. The number of connection portions 140 may be one or more. FIG. 15 illustrates an example in which the connection portion 140 is provided to surround the four sides of the display portion. In the connection portion 140, a common electrode of a display element is connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The wiring 165 has a function of supplying a signal and power to the display portion 168 and the circuit portion 164. The signal and power are input to the wiring 165 from the outside through the FPC 172 or input to the wiring 165 from the IC 173.

FIG. 15 illustrates an example in which the IC 173 is provided on the substrate 151 by a COG method, a COF method, or the like. An IC including one or both of a scan line driver circuit and a signal line driver circuit can be used as the IC 173, for example. Note that the display apparatus 50A and the display module are not necessarily provided with an IC. The IC may be mounted on the FPC by a COF method or the like.

The transistor of one embodiment of the present invention can be used for one or both of the display portion 168 and the circuit portion 164 of the display apparatus 50A, for example.

In the case where the transistor of one embodiment of the present invention is used for a pixel circuit of the display apparatus, the area occupied by the pixel circuit can be reduced and the display apparatus can have a high resolution, for example. In the case where the transistor of one embodiment of the present invention is used for a driver circuit (e.g., one or both of a gate line driver circuit and a source line driver circuit) of the display apparatus, the area occupied by the driver circuit can be reduced and the display apparatus can have a narrow bezel, for example. Since the transistor of one embodiment of the present invention has excellent electrical characteristics, a display apparatus can have increased reliability by using the transistor.

The display portion 168 of the display apparatus 50A is a region where an image is to be displayed, and includes a plurality of pixels 210 that are periodically arranged. FIG. 15 shows an enlarged view of one pixel 210.

There is no particular limitation on the arrangement of the pixels in the display apparatus of this embodiment, and any of a variety of methods can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 15 includes a subpixel 11R that emits red light, a subpixel 11G that emits green light, and a subpixel 11B that emits blue light.

The subpixel 11R, the subpixel 11G, and the subpixel 11B each include a display element and a circuit for controlling the driving of the display element.

Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

Examples of a display apparatus that includes a liquid crystal element include a transmissive liquid crystal display apparatus, a reflective liquid crystal display apparatus, and a transflective liquid crystal display apparatus.

Examples of the light-emitting element include self-luminous light-emitting elements such as an LED, an OLED (Organic LED), and a semiconductor laser. As the LED, for example, a mini LED, a micro LED, or the like can be used.

Examples of a light-emitting substance included in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescence (TADF) material), and an inorganic compound (e.g., a quantum dot material).

The emission color of the light-emitting element can be infrared, red, green, blue, cyan, magenta, yellow, white, or the like. When the light-emitting element has a microcavity structure, the color purity can be increased.

One of a pair of electrodes included in the light-emitting element functions as an anode, and the other electrode functions as a cathode.

In this embodiment, the case where a light-emitting element is used as the display element is mainly described as an example.

The display apparatus of one embodiment of the present invention can have any of a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

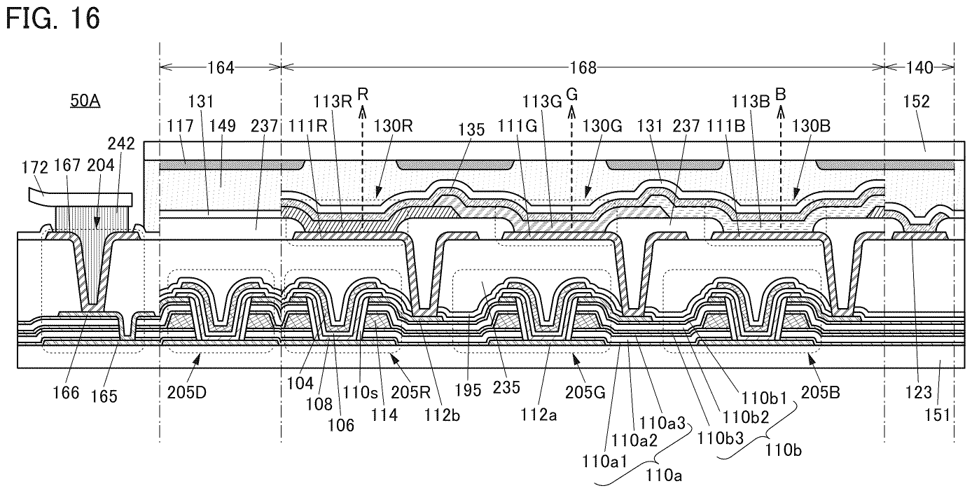

FIG. 16 illustrates an example of cross sections of part of a region including the FPC 172, part of the circuit portion 164, part of the display portion 168, part of the connection portion 140, and part of a region including the end portion of the display apparatus 50A.

The display apparatus 50A illustrated in FIG. 16 includes a transistor 205D, a transistor 205R, a transistor 205G, and a transistor 205B, a light-emitting element 130R, a light-emitting element 130G, a light-emitting element 130B, and the like between the substrate 151 and the substrate 152. The light-emitting element 130R is a display element included in the subpixel 11R that emits red light, the light-emitting element 130G is a display element included in the subpixel 11G that emits green light, and the light-emitting element 130B is a display element included in the subpixel 11B that emits blue light.

The display apparatus 50A employs an SBS structure. The SBS structure can optimize materials and structures of light-emitting elements and thus can extend freedom of choice of materials and structures, whereby the luminance and the reliability can be easily improved.

The display apparatus 50A has a top-emission structure. The aperture ratio of pixels in a top-emission structure can be higher than that of pixels in a bottom-emission structure because a transistor and the like can be provided to overlap with a light-emitting region of a light-emitting element in the top-emission structure.

The transistor 205D, the transistor 205R, the transistor 205G, and the transistor 205B are each formed over the substrate 151. These transistors can be manufactured using the same material through the same process.

This embodiment describes an example where OS transistors are used as the transistor 205D, the transistor 205R, the transistor 205G, and the transistor 205B. Any of the transistors of embodiments of the present invention can be used as the transistor 205D, the transistor 205R, the transistor 205G, and the transistor 205B. In other words, the display apparatus 50A includes the transistor of one embodiment of the present invention in both the display portion 168 and the circuit portion 164. When the display portion 168 includes the transistor of one embodiment of the present invention, the pixel size can be reduced and a high resolution can be achieved. When the circuit portion 164 includes the transistor of one embodiment of the present invention, the area occupied by the circuit portion 164 can be reduced and a narrower bezel can be achieved. The description in the above embodiment can be referred to for the transistors of one embodiment of the present invention.

Specifically, each of the transistor 205D, the transistor 205R, the transistor 205G, and the transistor 205B includes the conductive layer 104 functioning as a first gate electrode, the conductive layer 114 functioning as a second gate electrode, the insulating layer 106 functioning as a first gate insulating layer, the insulating layer 110s functioning as a second gate insulating layer, the conductive layer 112a functioning as one of a source electrode and a drain electrode, the conductive layer 112b functioning as the other of the source electrode and the drain electrode, and the semiconductor layer 108 including a metal oxide.

Note that the transistor included in the display apparatus of this embodiment is not limited to the transistor of one embodiment of the present invention. For example, the display apparatus may include both the transistor of one embodiment of the present invention and a transistor having another structure.

The display apparatus of this embodiment may include one or more of a planar transistor, a staggered transistor, and an inverted staggered transistor. A transistor included in the display apparatus of this embodiment may have either a top-gate structure or a bottom-gate structure. Gates may be provided above and below a semiconductor layer where a channel is formed.

The display apparatus of this embodiment may include a transistor using silicon in its channel formation region (a Si transistor).

Examples of silicon include single crystal silicon, polycrystalline silicon, and amorphous silicon. In particular, a transistor including LTPS in a semiconductor layer (hereinafter, also referred to as an LTPS transistor) can be used. The LTPS transistor has high field-effect mobility and excellent frequency characteristics.

To increase the emission luminance of the light-emitting element included in the pixel circuit, it is necessary to increase the amount of current flowing through the light-emitting element. To increase the amount of current, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Thus, with the use of an OS transistor as a driving transistor included in the pixel circuit, the amount of current flowing through the light-emitting element can be increased, resulting in an increase in emission luminance of the light-emitting element.

When a transistor operates in a saturation region, a change in source-drain current relative to a change in gate source voltage can be smaller in an OS transistor than in a Si transistor. Accordingly, when an OS transistor is used as the driving transistor included in the pixel circuit, the amount of current flowing between the source and the drain can be finely set by a change in gate source voltage; thus, the amount of current flowing through the light-emitting element can be controlled. Therefore, the number of gray levels in the pixel circuit can be increased.

Regarding saturation characteristics of current flowing when a transistor operates in a saturation region, current (saturation current) can flow more stably in an OS transistor than in a Si transistor even when the source-drain voltage gradually increases. Thus, with the use of an OS transistor as a driving transistor, current can be made to flow stably through the light-emitting element, for example, even when a variation in current-voltage characteristics of an EL element occurs. In other words, when the OS transistor operates in the saturation region, the source-drain current hardly changes with a change in the source-drain voltage; thus, the emission luminance of the light-emitting element can be stable.

The transistor included in the circuit portion 164 and the transistor included in the display portion 168 may have the same structure or different structures. The same structure or two or more kinds of structures may be employed for a plurality of transistors included in the circuit portion 164. Similarly, the same structure or two or more kinds of structures may be employed for a plurality of transistors included in the display portion 168.

All of the transistors included in the display portion 168 may be OS transistors or all of the transistors included in the display portion 168 may be Si transistors; alternatively, some of the transistors included in the display portion 168 may be OS transistors and the others may be Si transistors.

For example, when both an LTPS transistor and an OS transistor are used in the display portion 168, the display apparatus can have low power consumption and high drive capability. A structure in which an LTPS transistor and an OS transistor are combined is referred to as LTPO in some cases. As a more suitable example, a structure is given in which an OS transistor is used as a transistor or the like functioning as a switch for controlling electrical continuity and discontinuity between wirings and an LTPS transistor is used as a transistor or the like for controlling current.

For example, one of the transistors included in the display portion 168 functions as a transistor for controlling current flowing through the light-emitting element and can also be referred to as a driving transistor. One of a source and a drain of the driving transistor is connected to the pixel electrode of the light-emitting element. An LTPS transistor is preferably used as the driving transistor. In that case, the amount of current flowing through the light-emitting element can be increased in the pixel circuit.

By contrast, another transistor included in the display portion 168 functions as a switch for controlling selection or non-selection of a pixel and can also be referred to as a selection transistor. A gate of the selection transistor is connected to a gate line, and one of a source and a drain thereof is connected to a source line (signal line). An OS transistor is preferably used as the selection transistor. Accordingly, the gray level of the pixel can be maintained even with an extremely low frame frequency (e.g., 1 fps or lower); thus, power consumption can be reduced by stopping the driver in displaying a still image.

The insulating layer 195 is provided so as to cover the transistor 205D, the transistor 205R, the transistor 205G, and the transistor 205B, and an insulating layer 235 is provided over the insulating layer 195.

The insulating layer 195 preferably functions as a protective layer of the transistors. A material that does not easily allow diffusion of impurities such as water and hydrogen is preferably used for the insulating layer 195. Thus, the insulating layer 195 can function as a barrier layer. Such a structure can effectively inhibit diffusion of impurities into the transistors from the outside and increase the reliability of the display apparatus.

The insulating layer 195 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. Accordingly, a concave portion can be inhibited from being formed in the insulating layer 235 in processing a pixel electrode 111R, a pixel electrode 111G, and a pixel electrode 111B, for example. Alternatively, a concave portion may be formed in the insulating layer 235 in processing the pixel electrode 111R, the pixel electrode 111G, and the pixel electrode 111B, for example.

The light-emitting element 130R, the light-emitting element 130G, and the light-emitting element 130B are provided over the insulating layer 235.

The light-emitting element 130R includes the pixel electrode 111R over the insulating layer 235, an EL layer 113R over the pixel electrode 111R, and a common electrode 135 over the EL layer 113R. The light-emitting element 130R illustrated in FIG. 16 emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 135 over the EL layer 113G. The light-emitting element 130G illustrated in FIG. 16 emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 135 over the EL layer 113B. The light-emitting element 130B illustrated in FIG. 16 emits blue light (B). The EL layer 113B includes a light-emitting layer that emits blue light.

Although FIG. 16 illustrates the EL layer 113R, the EL layer 113G, and the EL layer 113B that have the same thickness, the present invention is not limited thereto. The EL layer 113R, the EL layer 113G, and the EL layer 113B may have different thicknesses. For example, the thicknesses of the EL layer the EL layer 113R, the EL layer 113G, and the EL layer 113B are preferably set to match an optical path length that intensifies light emitted from each EL layer. In that case, a microcavity structure is obtained, and the color purity of light emitted from each light-emitting element can be improved.

The pixel electrode 111R is connected to the conductive layer 112b included in the transistor 205R through an opening provided in the insulating layer 106, the insulating layer 195, and the insulating layer 235. Similarly, the pixel electrode 111G is connected to the conductive layer 112b included in the transistor 205G, and the pixel electrode 111B is connected to the conductive layer 112b included in the transistor 205B.

The end portions of the pixel electrode 111R, the pixel electrode 111G, and the pixel electrode 111B are covered with an insulating layer 237. The insulating layer 237 functions as a partition (also referred to as a bank or a spacer). The insulating layer 237 can have a single-layer structure or a stacked-layer structure including one or both of an inorganic insulating material and an organic insulating material. A material that can be used for the insulating layer 195 and a material that can be used for the insulating layer 235 can be used for the insulating layer 237, for example. With the insulating layer 237, the pixel electrode and the common electrode can be insulated from each other. Furthermore, with the insulating layer 237, adjacent light-emitting elements can be insulated from each other.

The common electrode 135 is one continuous film shared by the light-emitting element 130R, the light-emitting element 130G, and the light-emitting element 130B. The common electrode 135 shared by the plurality of light-emitting elements is connected to a conductive layer 123 provided in the connection portion 140. A conductive layer formed using the same material through the same process as the pixel electrode 111R, the pixel electrode 111G, and the pixel electrode 111B is preferably used as the conductive layer 123.

In the display apparatus of one embodiment of the present invention, a conductive film that transmits visible light is used for the electrode through which light is extracted, which is either the pixel electrode or the common electrode. A conductive film that reflects visible light is preferably used for the electrode through which light is not extracted.

A conductive film that transmits visible light may be used also for the electrode through which light is not extracted. In that case, this electrode is preferably provided between a reflective layer and the EL layer. In other words, light emitted from the EL layer may be reflected by the reflective layer to be extracted from the display apparatus.

As a material that forms the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy including any of these metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy including aluminum (aluminum alloy), such as an alloy of aluminum, nickel, and lanthanum (Al—Ni—La), and an alloy including silver, such as an alloy of silver and magnesium and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy including an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1'10⁻² ωcm.

The EL layer 113R, the EL layer 113G, and the EL layer 113B are each provided to have an island shape. In FIG. 16, an end portion of the EL layer 113R and an end portion of the EL layer 113G adjacent to each other overlap with each other, an end portion of the EL layer 113G and an end portion of the EL layer 113B adjacent to each other overlap with each other, and an end portion of the EL layer 113R and an end portion of the EL layer 113B adjacent to each other overlap with each other. When island-shaped EL layers are deposited using a fine metal mask, end portions of the EL layers adjacent to each other may overlap with each other as illustrated in FIG. 16; however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display apparatus.

Each of the EL layer 113R, the EL layer 113G, and the EL layer 113B includes at least a light-emitting layer. The light-emitting layer includes one or more kinds of light-emitting substances. As the light-emitting substance, a substance whose emission color is blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

The light-emitting layer may include one or more kinds of organic compounds (a host material, an assist material, and the like) in addition to the light-emitting substance (a guest material). As the one or more kinds of organic compounds, one or both of a substance with a good hole-transport property (a hole-transport material) and a substance with a good electron-transport property (an electron-transport material) can be used. As the one or more kinds of organic compounds, a substance with a bipolar property (a substance with a good electron-transport property and a good hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a high hole-injection property (a hole-injection layer), a layer including a hole-transport material (a hole-transport layer), a layer including a substance having a high electron-blocking property (an electron-blocking layer), a layer including a substance having a high electron-injection property (an electron-injection layer), a layer including an electron-transport material (an electron-transport layer), and a layer including a substance having a high hole-blocking property (a hole-blocking layer). The EL layer may further include one or both of a bipolar material and a TADF material.

Either a low molecular compound or a high molecular compound can be used for the light-emitting element, and an inorganic compound may also be included. Each layer included in the light-emitting element can be formed by an evaporation method (including a vacuum evaporation method), a transfer method, a printing method, an inkjet method, a coating method, or the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when voltage is applied between the pair of electrodes. A tandem structure enables a light-emitting element capable of emitting light with high luminance. Furthermore, the tandem structure can reduce the amount of a current needed for obtaining the same luminance as compared with a single structure, and thus can improve the reliability. Note that the tandem structure may be referred to as a stack structure.

In the case of using a tandem light-emitting element in FIG. 16, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting element 130R, the light-emitting element 130G, and the light-emitting element 130B. The protective layer 131 and the substrate 152 are bonded to each other with an adhesive layer 149. The substrate 152 is provided with a light-blocking layer 117. A solid sealing structure or a hollow sealing structure can be employed to seal the light-emitting elements, for example. In FIG. 16, a solid sealing structure is employed, in which a space between the substrate 152 and the substrate 151 is filled with the adhesive layer 149. Alternatively, a hollow sealing structure may be employed, in which the space is filled with an inert gas (e.g., nitrogen or argon). In that case, the adhesive layer 149 may be provided not to overlap with the light-emitting elements. Alternatively, the space may be filled with a resin different from that of the frame-shaped adhesive layer 149.

The protective layer 131 is provided at least in the display portion 168, and preferably provided to cover the entire display portion 168. The protective layer 131 is preferably provided to cover not only the display portion 168 but also the connection portion 140 and the circuit portion 164. It is also preferable that the protective layer 131 be provided to extend to the end portion of the display apparatus 50A. Meanwhile, a connection portion 204 has a portion not provided with the protective layer 131 so that the FPC 172 and a conductive layer 167 are connected to each other.

By providing the protective layer 131 over the light-emitting element 130R, the light-emitting element 130G, and the light-emitting element 130B, the reliability of the light-emitting elements can be increased.

The protective layer 131 may have a single-layer structure or a stacked-layer structure of two or more layers. There is no limitation on the conductivity of the protective layer 131. As the protective layer 131, at least one type of an insulating film, a semiconductor film, and a conductive film can be used.

The protective layer 131 including an inorganic film can inhibit deterioration of the light-emitting elements by preventing oxidation of the common electrode 135 and inhibiting entry of impurities (e.g., moisture and oxygen) into the light-emitting elements, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Specific examples of these inorganic insulating film are as described above. In particular, the protective layer 131 preferably includes a nitride insulating film or a nitride oxide insulating film, and further preferably includes a nitride insulating film.

An inorganic film including ITO, In—Zn oxide, Ga—Zn oxide, Al—Zn oxide, IGZO, or the like can be used for the protective layer 131. The inorganic film preferably has high resistance, specifically, higher resistance than the common electrode 135. The inorganic film may further include nitrogen.

When light emitted from the light-emitting element is extracted through the protective layer 131, the protective layer 131 preferably has a high visible-light-transmitting property. For example, an ITO, an IGZO, and an aluminum oxide are preferable because they are each an inorganic material having a high visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 204 is provided in a region of the substrate 151 that does not overlap with the substrate 152. In the connection portion 204, the wiring 165 is connected to the FPC 172 through a conductive layer 166, the conductive layer 167, and a connection layer 242. An example is illustrated in which the wiring 165 has a single-layer structure of a conductive layer obtained by processing the same conductive film as the conductive layer 112a. An example is illustrated in which the conductive layer 166 has a single-layer structure of a conductive layer obtained by processing the same conductive film as the conductive layer 112b. An example is illustrated in which the conductive layer 167 has a single-layer structure of a conductive layer obtained by processing the same conductive film as the pixel electrode 111R, the pixel electrode 111G, and the pixel electrode 111B. On the top surface of the connection portion 204, the conductive layer 167 is exposed. Thus, the connection portion 204 and the FPC 172 can be connected to each other through the connection layer 242.

The display apparatus 50A has a top-emission structure. Light emitted from the light-emitting element is emitted toward the substrate 152 side. For the substrate 152, a material having a high visible-light-transmitting property is preferably used. The pixel electrode 111R, the pixel electrode 111G, and the pixel electrode 111B include a material that reflects visible light, and the counter electrode (the common electrode 135) includes a material that transmits visible light.

The light-blocking layer 117 is preferably provided on the surface of the substrate 152 on the substrate 151 side. The light-blocking layer 117 can be provided between adjacent light-emitting elements, in the connection portion 140, and in the circuit portion 164, for example.

A coloring layer such as a color filter may be provided on the surface of the substrate 152 on the substrate 151 side or over the protective layer 131. When the color filter is provided to overlap with the light-emitting element, the color purity of light emitted from the pixel can be increased.

Moreover, a variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer side of the substrate 152. For example, a glass layer or a silica layer (SiOₓ layer) is preferably provided as the surface protective layer to inhibit the surface contamination and the generation of a scratch. For the surface protective layer, DLC (diamond-like carbon), aluminum oxide (AlOₓ), a polyester-based material, a polycarbonate-based material, or the like may be used. For the surface protective layer, a material having a high visible light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side where light from the light-emitting element is extracted, a material that transmits the light is used. When the substrate 151 and the substrate 152 are formed using a flexible material, the flexibility of the display apparatus can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for at least one of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence). Examples of a film having high optical isotropy include a triacetyl cellulose (TAC, also referred to as cellulose triacetate) film, a cycloolefin polymer (COP) film, a cycloolefin copolymer (COC) film, and an acrylic film.

For the adhesive layer 149, any of a variety of curable adhesives, e.g., a reactive curable adhesive, a thermosetting curable adhesive, an anaerobic adhesive, or a photocurable adhesive such as an ultraviolet curable adhesive, can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

For the connection layer 242, an anisotropic conductive film (ACF), an anisotropic conductive paste (ACP), or the like can be used.

### Display Apparatus 50B

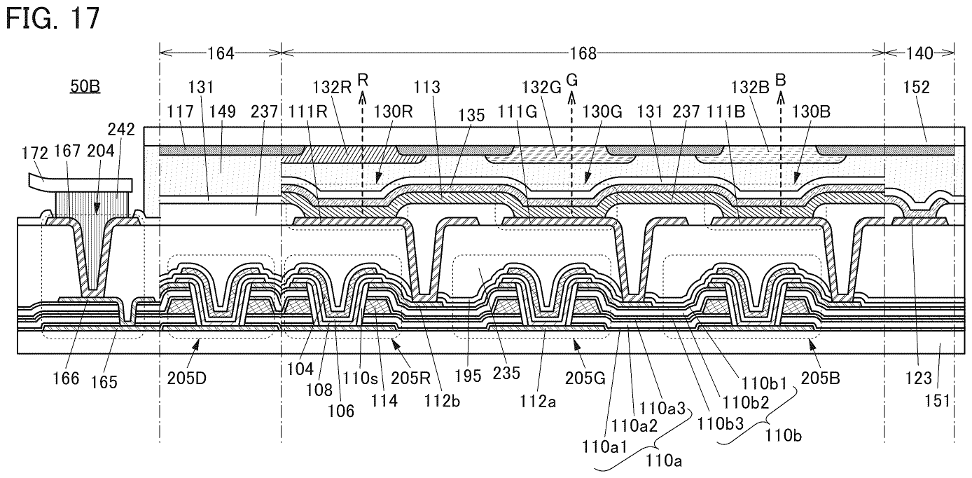

A display apparatus 50B illustrated in FIG. 17 is different from the display apparatus 50A mainly in that the subpixels of different colors include respective coloring layers (color filters or the like) and the light-emitting elements that include a common EL layer 113. Note that in the following description of display apparatus, the description of portions similar to those of the above-described display apparatus may be omitted.

The display apparatus 50B illustrated in FIG. 17 includes, between the substrate 151 and the substrate 152, the transistor 205D, the transistor 205R, the transistor 205G, and the transistor 205B, the light-emitting element 130R, the light-emitting element 130G, and the light-emitting element 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 135 over the EL layer 113. Light emitted from the light-emitting element 130R is extracted as red light to the outside of the display apparatus 50B through the coloring layer 132R.

The light-emitting element 130G includes the pixel electrode 111G, the EL layer 113 over the pixel electrode 111G, and the common electrode 135 over the EL layer 113. Light emitted from the light-emitting element 130G is extracted as green light to the outside of the display apparatus 50B through the coloring layer 132G.

The light-emitting element 130B includes the pixel electrode 111B, the EL layer 113 over the pixel electrode 111B, and the common electrode 135 over the EL layer 113. Light emitted from the light-emitting element 130B is extracted as blue light to the outside of the display apparatus 50B through the coloring layer 132B.

The EL layer 113 and the common electrode 135 are shared between the light-emitting element 130R, the light-emitting element 130G, and the light-emitting element 130B. The number of manufacturing steps can be smaller in the case where the EL layer 113 is shared between the subpixels of different colors than in the case where the subpixels of different colors include respective EL layers.

The light-emitting element 130R, the light-emitting element 130G, and the light-emitting element 130B illustrated in FIG. 17 emit white light, for example. When white light emitted from the light-emitting element 130R, the light-emitting element 130G, and the light-emitting element 130B passes through the coloring layer 132R, the coloring layer 132G, and the coloring layer 132B, light of desired colors can be obtained.

The light-emitting element that emits white light preferably includes two or more light-emitting layers. When two light-emitting layers are used to obtain white light, the two light-emitting layers are selected such that emission colors of the light-emitting layers are complementary colors. For example, when the emission color of the first light-emitting layer and the emission color of the second light-emitting layer are complementary colors, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer including a light-emitting substance that emits blue light and a light-emitting layer including a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellowish green, or green light, and a light-emitting unit that emits blue light are stacked in this order; and a three-unit tandem structure in which a light-emitting unit that emits blue light, a light-emitting unit that emits yellow, yellowish green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Alternatively, the light-emitting element 130R, the light-emitting element 130G, and the light-emitting element 130B illustrated in FIG. 17 emit blue light, for example. In that case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or 130G is converted into light with a longer wavelength, whereby red or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted without being converted by the color conversion layer. When light transmitted through the color conversion layer is extracted through the coloring layer, light other than light of the desired color can be absorbed by the coloring layer, and color purity of light exhibited by a subpixel can be improved.

### Display Apparatus 50C

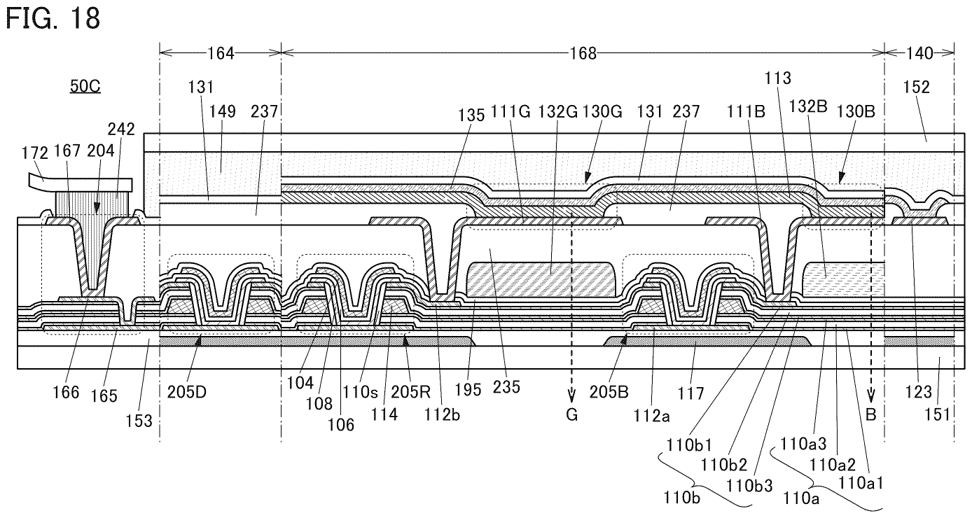

A display apparatus 50C illustrated in FIG. 18 is different from the display apparatus 50B mainly in being a bottom-emission display apparatus.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 18 illustrates an example in which the light-blocking layer 117 is provided over the substrate 151, an insulating layer 153 is provided over the light-blocking layer 117, and the transistor 205D, the transistor 205R (not illustrated), the transistor 205G, the transistor 205B, and the like are provided over the insulating layer 153. In addition, the coloring layer 132R (not illustrated), the coloring layer 132G, and the coloring layer 132B are provided over the insulating layer 195, and the insulating layer 235 is provided over the coloring layer 132R (not illustrated), the coloring layer 132G, and the coloring layer 132B.

The light-emitting element 130G overlapping with the coloring layer 132G includes the pixel electrode 111G, the EL layer 113, and the common electrode 135.

The light-emitting element 130B overlapping with the coloring layer 132B includes the pixel electrode 111B, the EL layer 113, and the common electrode 135.

A material having a high visible-light-transmitting property is used for each of the pixel electrode 111G and the pixel electrode 111B. A material that reflects visible light is preferably used for the common electrode 135. In the bottom-emission display apparatus, a metal or the like having low resistance can be used for the common electrode 135; thus, a voltage drop due to the resistance of the common electrode 135 can be suppressed and the display quality can be high.

The transistor of one embodiment of the present invention can be miniaturized and the area occupied by the transistor can be reduced, so that the aperture ratio of the pixel can be increased or the pixel size can be reduced in the display apparatus having a bottom-emission structure.

### Display Apparatus 50D

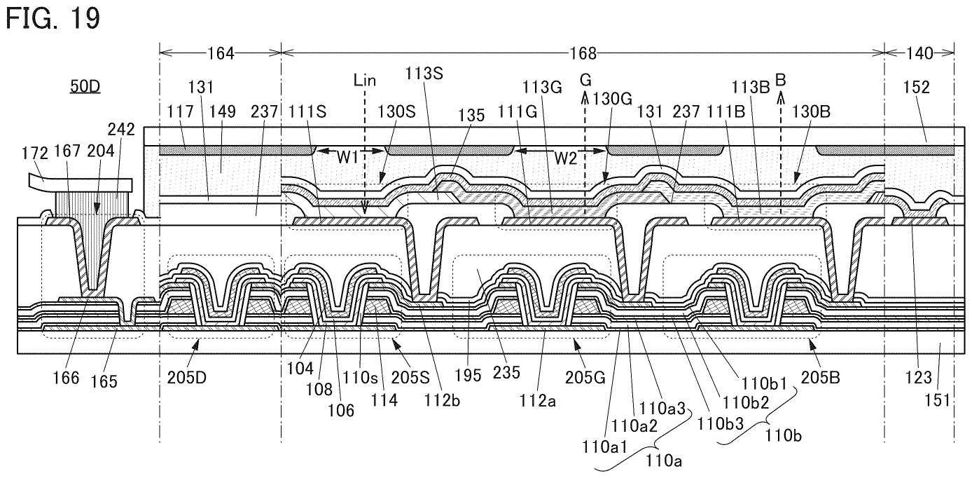

A display apparatus 50D illustrated in FIG. 19 is different from the display apparatus 50A mainly in including a light-receiving element 130S.

The display apparatus 50D includes light-emitting elements and a light-receiving element in a pixel. In the display apparatus 50D, it is preferable to use organic EL elements as the light-emitting elements and an organic photodiode as the light-receiving element. The organic EL elements and the organic photodiode can be formed over the same substrate. Thus, the organic photodiode can be incorporated in a display apparatus using the organic EL elements.

The display apparatus 50D can detect the touch or approach of an object while displaying an image because the pixel includes the light-emitting elements and the light-receiving element and thus has a light-receiving function. Accordingly, the display portion 168 has one or both of an image capturing function and a sensing function in addition to an image displaying function. For example, all the subpixels included in the display apparatus 50D can display an image; alternatively, some of the subpixels can emit light as a light source, some of the rest of the subpixels can detect light, and the other subpixels can display an image.

Accordingly, a light-receiving portion and a light source do not need to be provided separately from the display apparatus 50D; hence, the number of components of an electronic device can be reduced. For example, a biometric authentication device provided in the electronic device, a capacitive touch panel for scroll operation, or the like is not necessarily provided separately. Thus, with the use of the display apparatus 50D, the electronic device can be provided at lower manufacturing costs.

When the light-receiving element is used as an image sensor, the display apparatus 50D can capture an image using the light-receiving element. For example, image capturing for personal authentication with the use of a fingerprint, a palm print, the iris, the shape of a blood vessel (including the shape of a vein and the shape of an artery), a face, or the like is possible by using the image sensor.

Moreover, the light-receiving element can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display apparatus and the object come in direct contact with each other. Furthermore, the contactless sensor can detect the object even when the object is not in contact with the display apparatus.

The light-receiving element 130S includes a pixel electrode 111S over the insulating layer 235, a functional layer 113S over the pixel electrode 111S, and the common electrode 135 over the functional layer 113S. Light Lin enters the functional layer 113S from the outside of the display apparatus 50D.

The pixel electrode 111S is connected to the conductive layer 112b included in a transistor 205S through an opening provided in the insulating layer 106, the insulating layer 195, and the insulating layer 235.

An end portion of the pixel electrode 111S is covered with the insulating layer 237.

The common electrode 135 is one continuous film shared by the light-receiving element 130S, the light-emitting element 130R (not illustrated), the light-emitting element 130G, and the light-emitting element 130B. The common electrode 135 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example in which an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer including any of a substance having a high hole-transport property, a substance having a high electron-transport property, a substance having a bipolar property (a substance having a high electron-transport property and a high hole-transport property), and the like. Without limitation to the above, a layer including a substance having a high hole-injection property, a hole-blocking material, a substance having a high electron-injection property, an electron-blocking material, or the like may be further included. Layers other than the active layer included in the light-receiving element can be formed using a material that can be used for the light-emitting element, for example.

Either a low molecular compound or a high molecular compound can be used in the light-receiving element, and an inorganic compound may also be included. Each layer included in the light-receiving element can be formed by an evaporation method (including a vacuum evaporation method), a transfer method, a printing method, an inkjet method, a coating method, or the like.

### Display Apparatus 50E

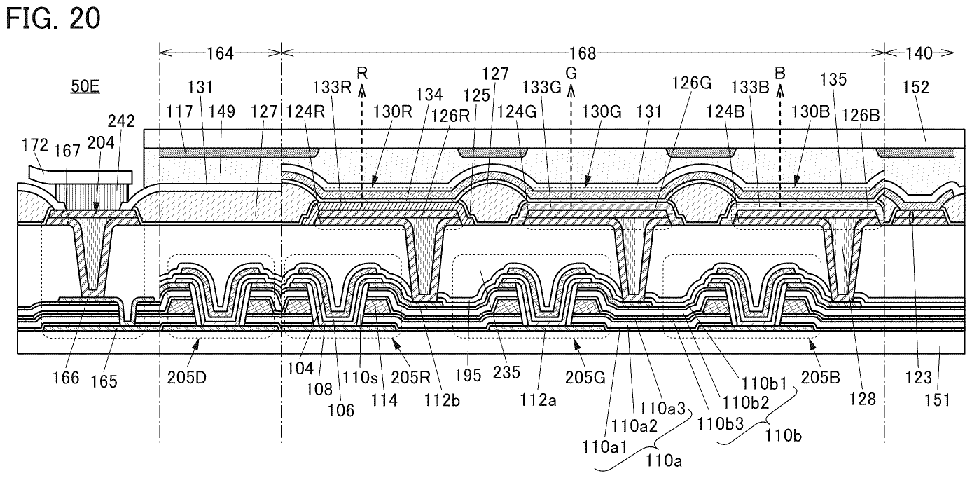

A display apparatus 50E illustrated in FIG. 20 is an example of a display apparatus having an MML (metal maskless) structure. In other words, the display apparatus 50E includes a light-emitting element that is formed without using a fine metal mask. The stacked-layer structure from the substrate 151 to the insulating layer 235 and the stacked-layer structure from the protective layer 131 to the substrate 152 are similar to those in the display apparatus 50A; therefore, description thereof is omitted.

In FIG. 20, the light-emitting element 130R, the light-emitting element 130G, and the light-emitting element 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 134 over the layer 133R, and the common electrode 135 over the common layer 134. The light-emitting element 130R illustrated in FIG. 20 emits red light (R). The layer 133R includes a light-emitting layer that emits red light. In the light-emitting element 130R, the layer 133R and the common layer 134 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 134 over the layer 133G, and the common electrode 135 over the common layer 134. The light-emitting element 130G illustrated in FIG. 20 emits green light (G). The layer 133G includes a light-emitting layer that emits green light. In the light-emitting element 130G, the layer 133G and the common layer 134 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 134 over the layer 133B, and the common electrode 135 over the common layer 134. The light-emitting element 130B illustrated in FIG. 20 emits blue light (B). The layer 133B includes a light-emitting layer that emits blue light. In the light-emitting element 130B, the layer 133B and the common layer 134 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 134. Note that in this specification and the like, the layer 133R, the layer 133G, and the layer 133B are sometimes referred to as island-shaped EL layers, EL layers formed in an island shape, or the like, in which case the common layer 134 is not included.

The layer 133R, the layer 133G, and the layer 133B are separated from one another. When the EL layer is provided to have an island shape for each light-emitting element, leakage current between adjacent light-emitting elements can be inhibited. This can prevent crosstalk-induced unintended light emission, so that a display apparatus with extremely high contrast can be obtained.

Although the layer 133R, the layer 133G, and the layer 133B have the same thickness in FIG. 20, the present invention is not limited thereto. The layer 133R, the layer 133G, and the layer 133B may have different thicknesses.

The conductive layer 124R is electrically connected to the conductive layer 112b included in the transistor 205R through an opening provided in the insulating layer 106, the insulating layer 195, and the insulating layer 235. Similarly, the conductive layer 124G is connected to the conductive layer 112b included in the transistor 205G, and the conductive layer 124B is connected to the conductive layer 112b included in the transistor 205B.

The conductive layer 124R, the conductive layer 124G, and the conductive layer 124B are formed to cover the openings provided in the insulating layer 235. A layer 128 is embedded in each of the depressed portions of the conductive layer 124R, the conductive layer 124G, and the conductive layer 124B.

The layer 128 has a planarization function for the concave portions of the conductive layer 124R, the conductive layer 124G, and the conductive layer 124B. The conductive layer 126R, the conductive layer 126G, and the conductive layer 126B connected to the conductive layer 124R, the conductive layer 124G, and the conductive layer 124B, respectively, are provided over the conductive layer 124R, the conductive layer 124G, the conductive layer 124B, and the layer 128. Thus, regions overlapping with the concave portions of the conductive layer 124R, the conductive layer 124G, and the conductive layer 124B can also be used as light-emitting regions, increasing the aperture ratio of the pixels. The conductive layer 124R and the conductive layer 126R each preferably include a conductive layer serving as a reflective electrode.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 20 illustrates an example in which the top surface of the layer 128 includes a flat portion, the shape of the layer 128 is not particularly limited. The top surface of the layer 128 can include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portion of the pixel electrode has a tapered shape, the layer 133R provided along the side surface of the pixel electrode also has a tapered shape. When the side surface of the pixel electrode has a tapered shape, coverage with an EL layer provided along the side surface of the pixel electrode can be improved.

Since the conductive layer 124G and the conductive layer 126G and the conductive layer 124B and the conductive layer 126B are similar to the conductive layer 124R and the conductive layer 126R, the detailed description thereof is omitted.

The top surface and the side surface of the conductive layer 126R are covered with the layer 133R. Similarly, the top surface and the side surface of the conductive layer 126G are covered with the layer 133G, and the top surface and the side surface of the conductive layer 126B are covered with the layer 133B. Accordingly, regions provided with the conductive layer 126R, the conductive layer 126G, and the conductive layer 126B can be entirely used as the light-emitting regions of the light-emitting element 130R, the light-emitting element 130G, and the light-emitting element 130B, thereby increasing the aperture ratio of the pixels.

The side surface and part of the top surface of each of the layer 133R, the layer 133G, and the layer 133B are covered with the insulating layer 125 and the insulating layer 127. The common layer 134 is provided over the layer 133R, the layer 133G, the layer 133B, and the insulating layer 125 and the insulating layer 127, and the common electrode 135 is provided over the common layer 134. The common layer 134 and the common electrode 135 are each one continuous film shared by the plurality of light-emitting elements.

In FIG. 20, the insulating layer 237 illustrated in FIG. 16 or the like is not provided between the conductive layer 126R and the layer 133R. That is, an insulating layer (also referred to as a partition, a bank, a spacer, or the like) covering and in contact with an upper end portion of the pixel electrode is not provided in the display apparatus 50E. Thus, the distance between adjacent light-emitting elements can be significantly shortened. Accordingly, the display apparatus can have a high resolution or a high definition. In addition, a mask for forming the insulating layer is not needed, which leads to a reduction in manufacturing cost of the display apparatus.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include the light-emitting layer and a carrier-blocking layer (a hole-blocking layer or an electron-blocking layer) over the light-emitting layer. Alternatively, the layer 133R, the layer 133G, and the layer 133B each preferably include the light-emitting layer, a carrier-blocking layer over the light-emitting layer, and a carrier-transport layer over the carrier-blocking layer. Since the surfaces of the layer 133R, the layer 133G, and the layer 133B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting elements can be increased.

The common layer 134 includes, for example, an electron-injection layer or a hole-injection layer. Alternatively, the common layer 134 may include a stack of an electron-transport layer and an electron-injection layer, or may include a stack of a hole-transport layer and a hole-injection layer. The common layer 134 is shared by the light-emitting element 130R, the light-emitting element 130G, and the light-emitting element 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and parts of the top surfaces) of the layer 133R, the layer 133G, and the layer 133B are covered with at least one of the insulating layer 125 and the insulating layer 127, so that the common layer 134 (or the common electrode 135) can be inhibited from being in contact with the side surfaces of the pixel electrodes and the layer 133R, the layer 133G, and the layer 133B, leading to inhibition of a short circuit of the light-emitting elements. Thus, the reliability of the light-emitting elements can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting elements can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers; hence, extreme unevenness of the formation surface of the layers (e.g., the carrier-injection layer and the common electrode) provided over the island-shaped layers can be reduced, and the formation surface can be made flatter. Consequently, coverage with the carrier-injection layer, the common electrode, and the like can be improved.

The common layer 134 and the common electrode 135 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display apparatus of one embodiment of the present invention, the step can be planarized with the insulating layer 125 and the insulating layer 127, and the coverage with the common layer 134 and the common electrode 135 can be improved. Thus, connection defects caused by step disconnection can be inhibited. In addition, an increase in electric resistance, which is caused by local thinning of the common electrode 135 due to the step, can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a smooth convex shape with high flatness.

The insulating layer 125 can be an insulating layer including an inorganic material. As the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. Aluminum oxide is particularly preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a targeted substance (also referred to as having low permeability). Alternatively, a barrier property refers to a function of capturing or fixing (also referred to as gettering) a targeted substance.

When the insulating layer 125 has a function of a barrier insulating layer or a gettering function, entry of impurities (typically, at least one of water and oxygen) that would diffuse into the light-emitting elements from the outside can be inhibited. With this structure, a highly reliable light-emitting element and a highly reliable display apparatus can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a planarization function for the extreme unevenness of the insulating layer 125, which is formed between adjacent light-emitting elements. In other words, the insulating layer 127 has an effect of improving the flatness of the formation surface of the common electrode 135.

As the insulating layer 127, an insulating layer including an organic material can be suitably used. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. For the insulating layer 127, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. A photoresist may be used as the photosensitive resin. As the photosensitive organic resin, either a positive-type material or a negative-type material may be used.

For the insulating layer 127, a material absorbing visible light may be used. When the insulating layer 127 absorbs light emitted from the light-emitting element, light leakage (stray light) from the light-emitting element to the adjacent light-emitting element through the insulating layer 127 can be inhibited. Thus, the display quality of the display apparatus can be improved. Since no polarizing plate is required to improve the display quality of the display apparatus, the weight and thickness of the display apparatus can be reduced.

Examples of the material absorbing visible light include a material including a pigment of black or the like, a material including a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

The transistor of one embodiment of the present invention can be miniaturized and the area occupied by the transistor can be reduced, so that the aperture ratio of the pixel can be increased or the pixel size can be reduced in the display apparatus having a bottom-emission structure.

This embodiment can be combined with any of the other embodiments or an example as appropriate.

### Embodiment 3

In this embodiment, a structure example of a display apparatus that can employ the semiconductor device of one embodiment of the present invention will be described.

Since the semiconductor device of one embodiment of the present invention can be extremely minute, a display apparatus using the semiconductor device of one embodiment of the present invention can have an extremely high resolution. For example, the display apparatus of one embodiment of the present invention can be used for display portions of information terminals (wearable devices) such as watch-type and bracelet-type information terminals and display portions of devices capable of being worn on a head, such as VR devices like HMDs and glasses-type AR devices.

### Display Module

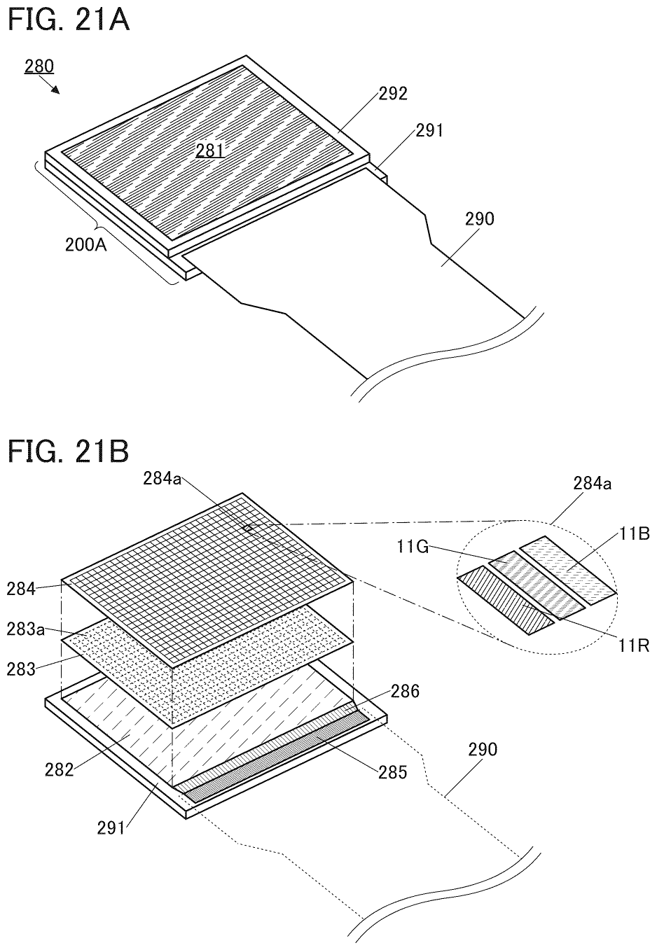

FIG. 21A is a perspective view of a display module 280. The display module 280 includes a display apparatus 200A and an FPC 290. Note that a display panel included in the display module 280 is not limited to the display apparatus 200A and may be either a display apparatus 200B or a display apparatus 200C described later.

The display module 280 includes a substrate 291 and a substrate 292. The display module 280 includes a display portion 281. The display portion 281 is a region where an image is displayed.

FIG. 21B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. In addition, a terminal portion 285 to be connected to the FPC 290 is provided in a portion that is over the substrate 291 and does not overlap with the pixel portion 284. The terminal portion 285 and the circuit portion 282 are connected to each other through a wiring portion 286 formed of a plurality of wirings.

The pixel portion 284 includes a plurality of pixels 284a arranged periodically. An enlarged view of one pixel 284a is illustrated on the right side in FIG. 21B. The pixel 284a includes the subpixel 11R emitting red light, the subpixel 11G emitting green light, and the subpixel 11B emitting blue light.

The pixel circuit portion 283 includes a plurality of pixel circuits 283a arranged periodically. One pixel circuit 283a is a circuit for controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may further include at least one of an arithmetic circuit, a memory circuit, a power supply circuit, and the like. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. In addition, an IC may be mounted on the FPC 290.

The display module 280 can have a structure in which one or both of the pixel circuit portion 283 and the circuit portion 282 are provided to be stacked below the pixel portion 284; thus, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have an extremely high resolution. For example, the pixels 284a are preferably arranged in the display portion 281 with a resolution higher than or equal to 2000 ppi and lower than or equal to 30000 ppi, preferably higher than or equal to 3000 ppi and lower than or equal to 20000 ppi, still further preferably higher than or equal to 5000 ppi and lower than or equal to 20000 ppi, still further preferably higher than or equal to 6000 ppi and lower than or equal to 20000 ppi.

Such a display module 280 has an extremely high resolution, and thus can be suitably used for a VR device such as a head-mounted display or a glasses-type AR device. For example, even in the case of a structure in which the display portion of the display module 280 is seen through a lens, pixels of the extremely-high-resolution display portion 281 included in the display module 280 are not seen even when the display portion is enlarged by the lens, so that display providing a high sense of immersion can be performed. Without being limited thereto, the display module 280 can also be suitably used for an electronic device having a relatively small display portion. For example, the display module 280 can be suitably used for a display portion of a wearable electronic device such as a wristwatch.

### Display Apparatus 200a

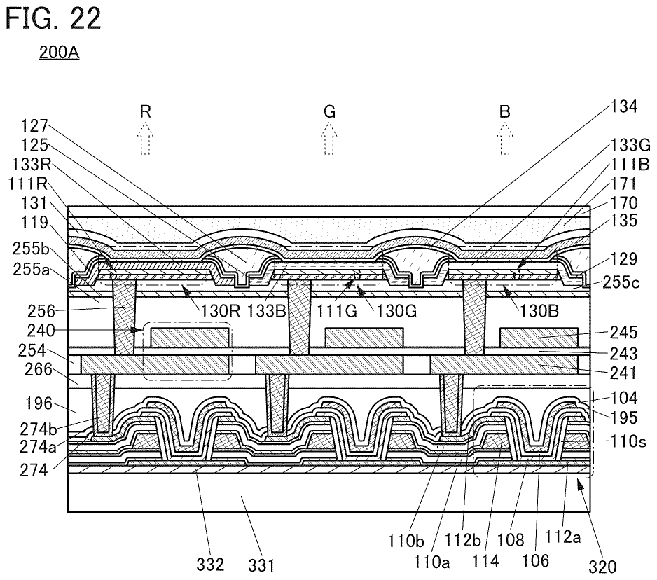

The display apparatus 200A illustrated in FIG. 22 includes a substrate 331, the light-emitting element 130R, the light-emitting element 130G, the light-emitting element 130B, a capacitor 240, and a transistor 320. The light-emitting element 130R is a display element included in the subpixel 11R that emits red light, the light-emitting element 130G is a display element included in the subpixel 11G that emits green light, and the light-emitting element 130B is a display element included in the subpixel 11B that emits blue light.

The substrate 331 corresponds to the substrate 291 in FIG. 21A.

The transistor 320 is a vertical-channel transistor using an oxide semiconductor in a semiconductor layer where a channel is formed. As the transistor 320, a variety of transistors described in Embodiment 1 can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 108 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 112a is provided over the insulating layer 332. Over the conductive layer 112a, the insulating layer 110a, the conductive layer 114 over the insulating layer 110a, the insulating layer 110b over the conductive layer 114, and the conductive layer 112b over the insulating layer 110b are provided. Openings are provided in the insulating layer 110a, the conductive layer 114, the insulating layer 110b, and the conductive layer 112b, and the insulating layer 110s is provided along the sidewall of the opening. The semiconductor layer 108 is provided to cover the top surface of the conductive layer 112a, the sidewall of the insulating layer 110s, and the top surface of the conductive layer 112b, the insulating layer 106 is provided over the semiconductor layer 108, and the conductive layer 104 is provided over the insulating layer 106. The insulating layer 195 is provided over the insulating layer 106 and the conductive layer 104. An insulating layer 196 is provided over the insulating layer 195. The top surface of the insulating layer 196 is planarized, and an insulating layer 266 is provided over the insulating layer 196.

The insulating layer 196 and the insulating layer 266 each function as an interlayer insulating layer. A barrier layer that prevents diffusion of impurities such as water or hydrogen from the insulating layer 266 or the like into the transistor 320 may be provided between the insulating layer 266 and the insulating layer 196. As the barrier layer, an insulating film similar to the insulating layer 332 can be used.

The plug 274 connected to the conductive layer 112b is provided to be embedded in the insulating layer 266, the insulating layer 196, the insulating layer 195, and the insulating layer 106. Here, the plug 274 preferably includes a conductive layer 274a covering the side surfaces of openings in the insulating layer 266, the insulating layer 196, the insulating layer 195, and the insulating layer 106 and part of the top surface of the conductive layer 112b, and a conductive layer 274b in contact with the top surface of the conductive layer 274a. In that case, for the conductive layer 274a, a conductive material that does not easily allow diffusion of hydrogen and oxygen is preferably used.

In addition, the capacitor 240 is provided over the insulating layer 266. The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 266 and is embedded in an insulating layer 254. The conductive layer 241 is connected to the conductive layer 112b of the transistor 320 through the plug 274. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240. An insulating layer 255b is provided over the insulating layer 255a. An insulating layer 255c is provided over the insulating layer 255b.

An inorganic insulating film can be suitably used as each of the insulating layer 255a, the insulating layer 255b, and the insulating layer 255c. For example, it is preferable that a silicon oxide film be used as each of the insulating layer 255a and the insulating layer 255c and a silicon nitride film be used as the insulating layer 255b. This enables the insulating layer 255b to function as an etching protective film. Although this embodiment shows an example where the insulating layer 255c is partly etched and a concave portion is formed, the concave portion is not necessarily provided in the insulating layer 255c.

The light-emitting element 130R, the light-emitting element 130G, and the light-emitting element 130B are provided over the insulating layer 255c. The contents described in Embodiment 2 can be referred to for the details of the light-emitting element 130R, the light-emitting element 130G, and the light-emitting element 130B.

The light-emitting element 130R includes the pixel electrode 111R, the layer 133R, the common layer 134, and the common electrode 135. The light-emitting element 130G includes the pixel electrode 111G, the layer 133G, the common layer 134, and the common electrode 135. The light-emitting element 130B includes the pixel electrode 111B, the layer 133B, the common layer 134, and the common electrode 135. The common layer 134 and the common electrode 135 are provided to be shared by the light-emitting element 130R, the light-emitting element 130G, and the light-emitting element 130B.

The layer 133R included in the light-emitting element 130R includes at least a light-emitting organic compound that emits red light. The layer 133G included in the light-emitting element 130G includes at least a light-emitting organic compound that emits green light. The layer 133B included in the light-emitting element 130B includes at least a light-emitting organic compound that emits blue light. Each of the layer 133R, the layer 133G, and the layer 133B can also be referred to as an EL layer and includes at least a layer including a light-emitting organic compound (a light-emitting layer).

In the display apparatus 200A, since the light-emitting devices of different colors are separately formed, a change in chromaticity between light emission at low luminance and light emission at high luminance is small. Furthermore, since the layer 133R, the layer 133G, and the layer 133B are apart from each other, crosstalk generated between adjacent subpixels can be inhibited even when the display panel has a high resolution. It is thus possible to achieve a display panel that has a high resolution and a high display quality.

In a region between adjacent light-emitting elements, the insulating layer 125, the insulating layer 127, and the layer 129 are provided.

The pixel electrode 111R, the pixel electrode 111G, and the pixel electrode 111B of the light-emitting elements are connected to the conductive layer 112b of the transistor 320 through a plug 256 that is embedded in the insulating layer 255a, the insulating layer 255b, and the insulating layer 255c, the conductive layer 241 that is embedded in the insulating layer 254, and the plug 274. The top surface of the insulating layer 255c and the top surface of the plug 256 are level with or substantially level with each other. A variety of conductive materials can be used for the plugs.

The protective layer 131 is provided over the light-emitting element 130R, the light-emitting element 130G, and the light-emitting element 130B. A substrate 170 is attached onto the protective layer 131 with an adhesive layer 171.

An insulating layer covering an end portion of the top surface of the pixel electrode 111 is not provided between two adjacent pixel electrodes 111. Thus, the distance between adjacent light-emitting elements can be significantly shortened. Accordingly, the display apparatus can have a high resolution or a high definition.

### Display Apparatus 200b

A display apparatus whose structure is partly different from the above-described structure will be described below. Note that the above description is referred to for portions common to those described above and the description is omitted in some cases.

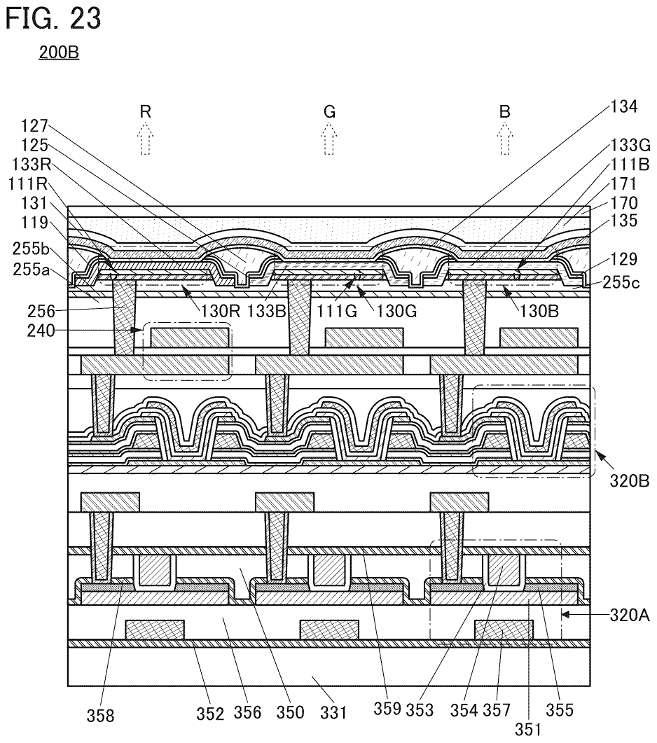

The display apparatus 200B illustrated in FIG. 23 is an example in which a transistor 320A that is a planar transistor whose semiconductor layer is formed on a plane and a transistor 320B that is a vertical-channel transistor are stacked. The transistor 320B has a structure similar to that of the transistor 320 in the display apparatus 200A.

The transistor 320A includes a semiconductor layer 351, an insulating layer 353, a conductive layer 354, a pair of conductive layers 355, an insulating layer 356, and a conductive layer 357.

An insulating layer 352 is provided over the substrate 331. The insulating layer 352 functions as a barrier layer that prevents diffusion of impurities such as water and hydrogen from the substrate 331 into the transistor 320 and release of oxygen from the semiconductor layer 351 to the insulating layer 352 side. As the insulating layer 352, for example, a film in which hydrogen or oxygen is less likely to diffuse than in a silicon oxide film, such as an aluminum oxide film, a hafnium oxide film, or a silicon nitride film, can be used.

The conductive layer 357 is provided over the insulating layer 352, and the insulating layer 356 is provided to cover the conductive layer 357. The conductive layer 357 functions as a first gate electrode of the transistor 320A, and part of the insulating layer 356 functions as a first gate insulating layer. An oxide insulating film such as a silicon oxide film is preferably used for at least part of the insulating layer 356 that is in contact with the semiconductor layer 351. The top surface of the insulating layer 356 is preferably planarized.

The semiconductor layer 351 is provided over the insulating layer 356. The semiconductor layer 351 preferably includes a metal oxide (also referred to as oxide semiconductor) film exhibiting semiconductor characteristics. The pair of conductive layers 355 is provided over and in contact with the semiconductor layer 351, and functions as a source electrode and a drain electrode.

An insulating layer 358 and an insulating layer 350 are provided to cover the top surfaces and the side surfaces of the pair of conductive layers 355, the side surface of the semiconductor layer 351, and the like. The insulating layer 358 functions as a barrier layer that prevents diffusion of impurities such as water and hydrogen into the semiconductor layer 351 and release of oxygen from the semiconductor layer 351. As the insulating layer 358, an insulating film similar to the insulating layer 352 can be used.

An opening reaching the semiconductor layer 351 is provided in the insulating layer 358 and the insulating layer 350. The conductive layer 354 and the insulating layer 353 that is in contact with the top surface of the semiconductor layer 351 are embedded in the opening. The conductive layer 354 functions as a second gate electrode, and the insulating layer 353 functions as a second gate insulating layer.

The top surface of the conductive layer 354, the top surface of the insulating layer 353, and the top surface of the insulating layer 350 are planarized so as to be level or substantially level with each other, and an insulating layer 359 is provided to cover these layers. The insulating layer 359 functions as a barrier layer that prevents diffusion of impurities such as water and hydrogen into the transistor 320. As the insulating layer 359, an insulating film similar to the insulating layer 352 can be used.

A structure in which the semiconductor layer where a channel is formed is interposed between two gates is employed for the transistor 320. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

### Display Apparatus 200C

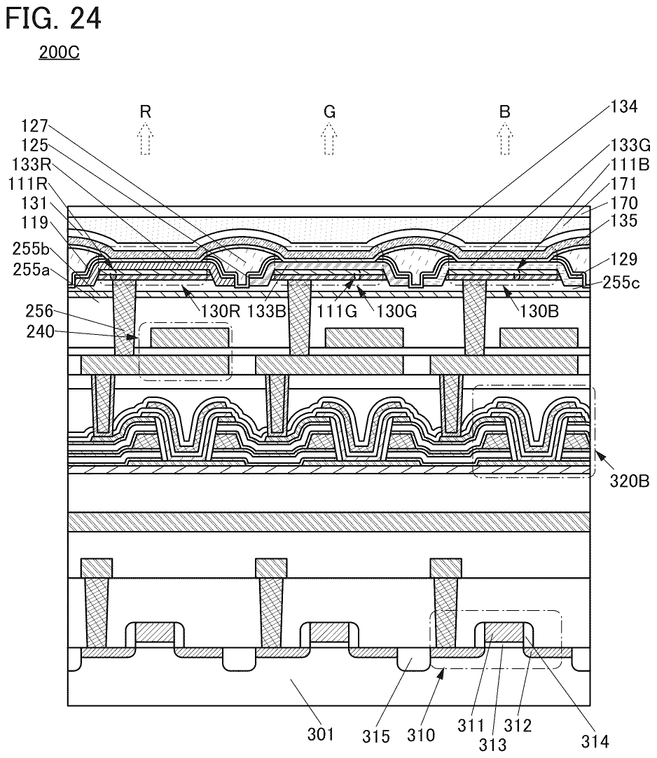

The display apparatus 200C illustrated in FIG. 24 has a structure in which a transistor 310 whose channel is formed in a semiconductor substrate and the transistor 320B that is a vertical-channel transistor are stacked.

The transistor 310 is a transistor that includes a channel formation region in a substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

In addition, an element isolation layer 315 is provided between two adjacent transistors 310 to be embedded in the substrate 301.

At least part of this embodiment can be implemented in combination with the other embodiments or the example described in this specification as appropriate.

### Embodiment 4

In this embodiment, a circuit, a layout, and the like that can be employed in the display apparatus of one embodiment of the present invention will be described.

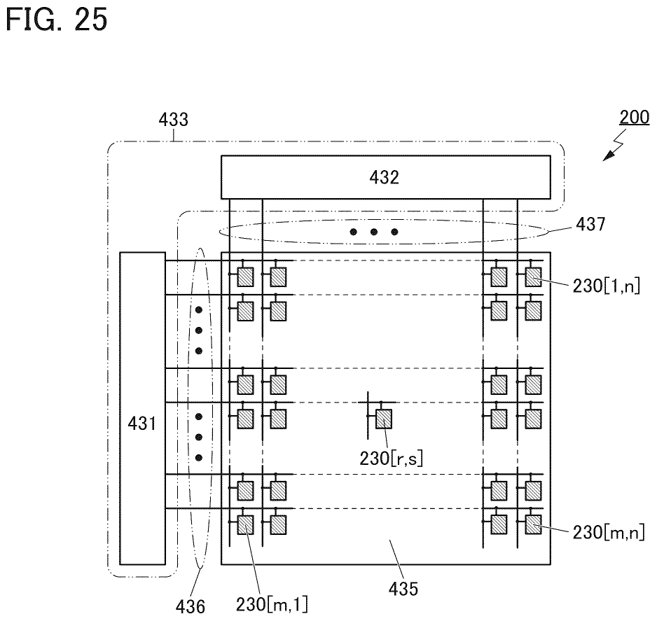

FIG. 25 is a block diagram illustrating the display apparatus 200. The display apparatus 200 includes a display portion 435, a first driver circuit portion 431, and a second driver circuit portion 432.

The display portion 435 includes a plurality of pixels 230 arranged in a matrix of m rows (m is an integer greater than or equal to 1) and n columns (n is an integer greater than or equal to 1).

The display portion 435 corresponds to the display portion 168 in FIG. 15, and the pixel 230 corresponds to the subpixel 11R, the subpixel 11G, the subpixel 11B, and the pixel 210 in FIG. 15, for example.

The display portion 435 corresponds to the display portion 281 in FIG. 21, and the pixel 230 corresponds to the subpixel 11R, the subpixel 11G, the subpixel 11B, and the pixel 284a in FIG. 21, for example.

In FIG. 25, the pixel 230 in the first row and the n-th column is denoted as a pixel 230[1,n], the pixel 230 in the m-th row and the first column is denoted as a pixel 230[m,1], and the pixel 230 in the m-th row and the n-th column is denoted as a pixel 230[m,n]. A given pixel 230 included in the display portion 435 is sometimes denoted as a pixel 230[r,s]. Note that r is an integer greater than or equal to 1 and less than or equal to m, and s is an integer greater than or equal to 1 and less than or equal to n.

A circuit included in the first driver circuit portion 431 functions as, for example, a scan line driver circuit. A circuit included in the second driver circuit portion 432 functions as, for example, a signal line driver circuit. Note that some sort of circuit may be provided at a position facing the first driver circuit portion 431 with the display portion 435 therebetween. Some sort of circuit may be provided at a position facing the second driver circuit portion 432 with the display portion 435 therebetween. Note that circuits included in the first driver circuit portion 431 and the second driver circuit portion 432 are collectively referred to as a peripheral driver circuit 433.

Any of various circuits such as a shift register circuit, a level shifter circuit, an inverter circuit, a latch circuit, an analog switch circuit, a multiplexer circuit, a demultiplexer circuit, and a logic circuit can be used as the peripheral driver circuit 433. In the peripheral driver circuit 433, the transistor 100 and the like of one embodiment of the present invention can be used. Transistors included in the peripheral driver circuit may be formed in the same step as the transistors included in the pixels 230.

The display apparatus 200 includes m wirings 436 which are arranged substantially parallel to each other and whose potentials are controlled by the circuit included in the first driver circuit portion 431, and n wirings 437 which are arranged substantially parallel to each other and whose potentials are controlled by the circuit included in the second driver circuit portion 432.

FIG. 25 illustrates an example in which the wirings 436 and the wirings 437 are connected to the pixels 230. Note that the wirings 436 and the wirings 437 are examples, and the wirings connected to the pixels 230 are not limited to the wirings 436 and the wirings 437.

### Structure Example of Pixel Circuit

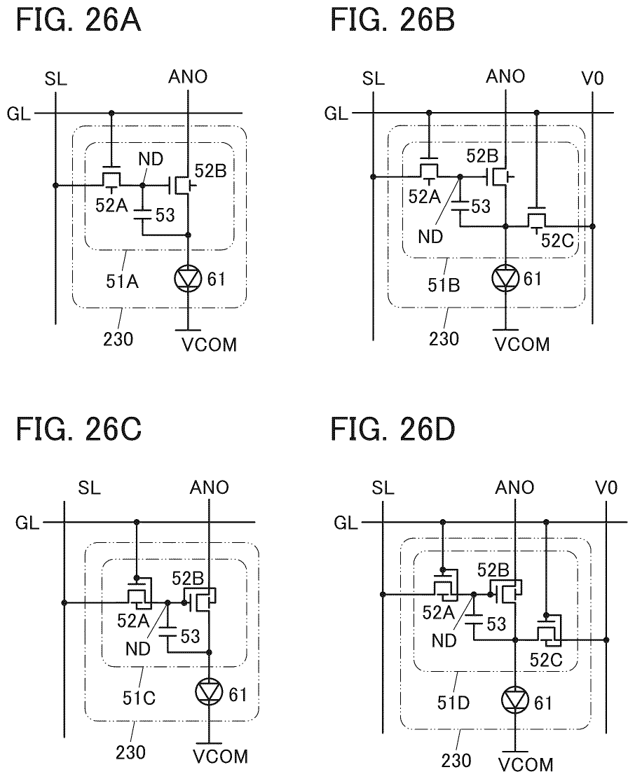

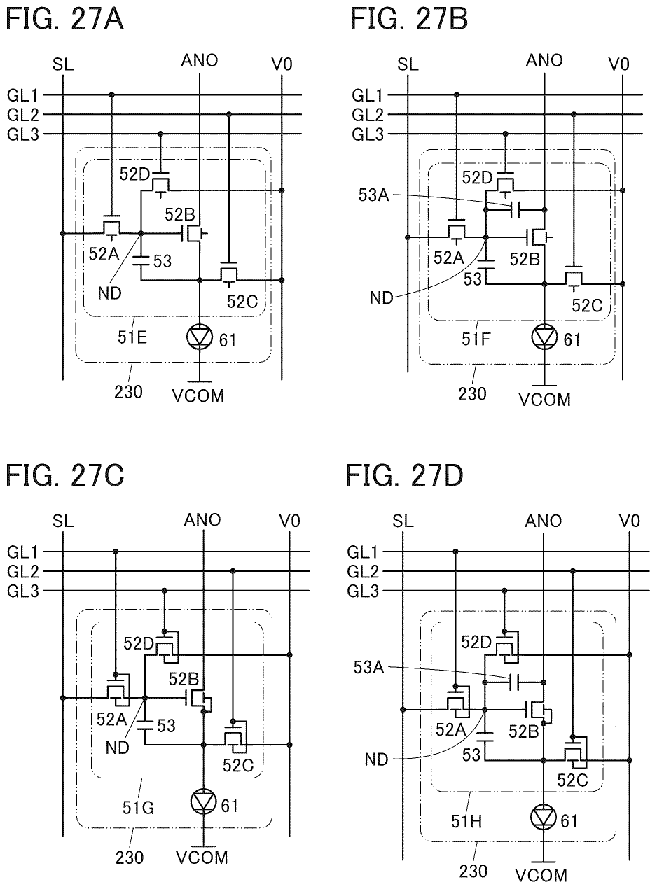

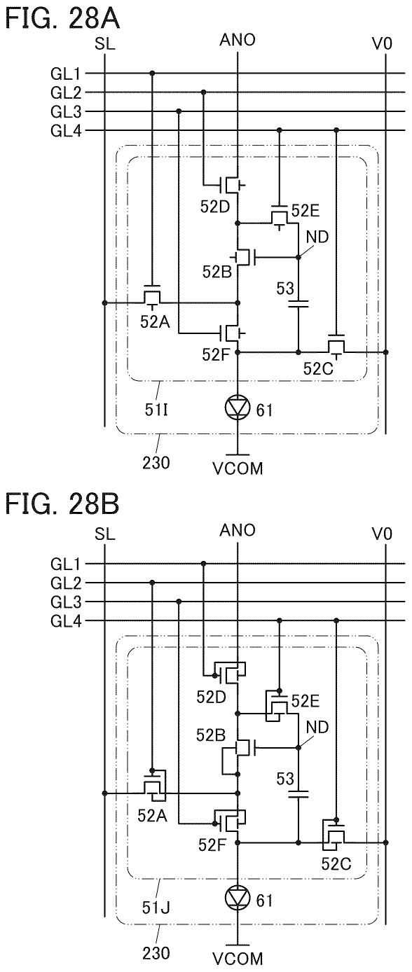

FIG. 26A to FIG. 26D, FIG. 27A to FIG. 27D, and FIG. 28A and FIG. 28B illustrate structure examples of the pixel 230. The pixel 230 includes a pixel circuit 51 (a pixel circuit 51A, a pixel circuit 51B, a pixel circuit 51C, a pixel circuit 51D, a pixel circuit 51E, a pixel circuit 51F, a pixel circuit 51G, a pixel circuit 51H, a pixel circuit 51I, or a pixel circuit 51J) and a light-emitting element 61.

The light-emitting element (also referred to as a light-emitting device) described in this embodiment and the like refers to a self-luminous display element such as an organic EL element (also referred to as an OLED). Note that the light-emitting element connected to the pixel circuit can be a self-luminous light-emitting element such as an LED, a micro LED, a QLED, or a semiconductor laser.

The pixel circuit 51A illustrated in FIG. 26A is a 2Tr1C-type pixel circuit including a transistor 52A, a transistor 52B, and a capacitor 53.

One of a source and a drain of the transistor 52A is electrically connected to a wiring SL, and a gate of the transistor 52A is connected to a wiring GL. One of the source and the drain of the transistor 52A is connected to a gate of the transistor 52B and one terminal of the capacitor 53. One of a source and a drain of the transistor 52B is connected to a wiring ANO. The other of the source and the drain of the transistor 52B is connected to the other terminal of the capacitor 53 and an anode of the light-emitting element 61. A cathode of the light-emitting element 61 is connected to a wiring VCOM. A region where the other of the source and the drain of the transistor 52A, the gate of the transistor 52B, and the one terminal of the capacitor 53 are connected to one another functions as a node ND.

The wiring GL corresponds to the wiring 436, and the wiring SL corresponds to the wiring 437. The wiring VCOM is a wiring for supplying a potential for supplying current to the light-emitting element 61. The transistor 52A has a function of controlling electrical continuity between the wiring SL and the gate of the transistor 52B in accordance with the potential of the wiring GL. For example, VDD is supplied to the wiring ANO, and VSS is supplied to the wiring VCOM.

When the transistor 52A is turned on, an image signal is supplied from the wiring SL to the node ND. After that, when the transistor 52A is turned off, the image signal is held in the node ND. In order to surely hold the image signal supplied to the node ND, a transistor with a low off-state current is preferably used as the transistor 52A. For example, an OS transistor is preferably used as the transistor 52A.

The transistor 52B has a function of controlling the amount of current flowing through the light-emitting element 61. The capacitor 53 has a function of holding a gate potential of the transistor 52B. The intensity of light emitted from the light-emitting element 61 is controlled in accordance with an image signal supplied to the gate of the transistor 52B (the node ND).

In the pixel circuit 51A illustrated in FIG. 26A, the transistor 52A and the transistor 52B each have a back gate. A signal line or a power supply line can be connected to the back gate to supply a given potential. The back gate may be connected to the ground potential. The back gate may be connected to the gate. The back gate may be connected to the source or the drain. Although an example in which all the transistors have back gates is illustrated here, only some of the transistors may have back gates.

The pixel circuit 51B illustrated in FIG. 26B is a 3Tr1C-type pixel circuit including the transistor 52A, the transistor 52B, a transistor 52C, and the capacitor 53. The pixel circuit 51B illustrated in FIG. 26B has a structure in which the transistor 52C is added to the pixel circuit 51A illustrated in FIG. 26A.

One of a source and a drain of the transistor 52C is connected to the other of the source and the drain of the transistor 52B. The other of the source and the drain of the transistor 52C is connected to a wiring V0. A reference potential is supplied to the wiring V0, for example.

The transistor 52C has a function of controlling electrical continuity between the wiring V0 and the other of the source and the drain of the transistor 52B in accordance with the potential of the wiring GL. The wiring V0 is a wiring for supplying a reference potential. In the case where an n-channel transistor is used as the transistor 52B, a variation in the gate-source potential of the transistor 52B can be reduced by the reference voltage of the wiring V0 supplied through the transistor 52C.

A current value that can be used for setting pixel parameters can be obtained using the wiring VO. Specifically, the wiring V0 can function as a monitor line for outputting current flowing through the transistor 52B or current flowing through the light-emitting element 61 to the outside. Current output to the wiring V0 can be converted into voltage by a source follower circuit or the like and can be output to the outside. For another example, the current can be converted into a digital signal by an A-D converter or the like and can be output to the outside.

In the pixel circuit 51B illustrated in FIG. 26B, the transistor 52A, the transistor 52B, and the transistor 52C each have a back gate. A signal line or a power supply line can be connected to the back gate to supply a given potential. The back gate may be connected to a wiring supplying a ground potential. The back gate may be connected to the gate. The back gate may be connected to the source or the drain. Although an example in which all the transistors have back gates is illustrated here, only some of the transistors may have back gates.

The pixel circuit 51C illustrated in FIG. 26C is an example of the case where a transistor which includes a back gate and in which the back gate is connected to a gate is used as each of the transistor 52A and the transistor 52B in the pixel circuit 51A. The pixel circuit 51D illustrated in FIG. 26D is an example of the case where such transistors are used in the pixel circuit 51B. Thus, current that can flow through the transistors can be increased. Although a transistor in which a gate and a back gate are connected to each other is used as each of the transistors here, one embodiment of the present invention is not limited thereto. A transistor which includes a gate and a back gate and in which the gates are connected to different wirings may be used. For example, with the use of a transistor in which one of a gate and a back gate is connected to a source, the reliability can be increased.

The pixel circuit 51E illustrated in FIG. 27A has a structure in which a transistor 52D is added to the pixel circuit 51B illustrated in FIG. 26B. The pixel circuit 51E illustrated in FIG. 27A is a 4Tr1C-type pixel circuit including the transistor 52A, the transistor 52B, the transistor 52C, the transistor 52D, and the capacitor 53.

One of a source and a drain of the transistor 52D is connected to the node ND, and the other is connected to the wiring V0. The transistor 52D has a back gate.

A wiring GL1, a wiring GL2, and a wiring GL3 are connected to the pixel circuit 51E. The wiring GL1 is connected to the gate of the transistor 52A, the wiring GL2 is connected to the gate of the transistor 52C, and the wiring GL3 is connected to a gate of the transistor 52D. Note that in this embodiment and the like, the wiring GL1, the wiring GL2, and the wiring GL3 are sometimes collectively referred to as the wiring GL. Thus, the wiring GL may be one wiring or a plurality of wirings.

When the transistor 52C and the transistor 52D are turned on at the same time, the source and the gate of the transistor 52B have the same potential, so that the transistor 52B can be turned off. Thus, current flowing to the light-emitting element 61 can be blocked forcibly. Such a pixel circuit is suitable for the case of using a display method in which a display period and an off period are alternately provided.

The pixel circuit 51F illustrated in FIG. 27B is an example of the case where a capacitor 53A is added to the pixel circuit 51E. The capacitor 53A functions as a storage capacitor. The pixel circuit 51E illustrated in FIG. 27A is a 4Tr1C-type pixel circuit. The pixel circuit 51F illustrated in FIG. 27B is a 4Tr2C-type pixel circuit.

The pixel circuit 51G illustrated in FIG. 27C and the pixel circuit 51H illustrated in FIG. 27D have structures changed from those of the pixel circuit 51E and the pixel circuit 51F, respectively; the back gates of the transistor 52A, the transistor 52C, and the transistor 52D are connected to the respective gates, and the back gate of the transistor 52B is connected to the source thereof.

The pixel circuit 51I illustrated in FIG. 28A is a 6Tr1C-type pixel circuit including the transistor 52A, the transistor 52B, the transistor 52C, the transistor 52D, a transistor 52E, a transistor 52F, and the capacitor 53. The transistor 52A to the transistor 52F each have a back gate.

One of the source and the drain of the transistor 52A is connected to the wiring SL, and the gate of the transistor 52A is connected to the wiring GL1. One of the source and the drain of the transistor 52D is connected to the wiring ANO, and the gate of the transistor 52D is connected to the wiring GL2. The other of the source and the drain of the transistor 52D is connected to one of the source and the drain of the transistor 52B. The other of the source and the drain of the transistor 52B is connected to the other of the source and the drain of the transistor 52A and one of a source and a drain of the transistor 52F. A gate of the transistor 52F is connected to the wiring GL3.

One of a source and a drain of the transistor 52E is connected to the other of the source and the drain of the transistor 52D and the one of the source and the drain of the transistor 52B. The other of the source and the drain of the transistor 52E is connected to the gate of the transistor 52B and one terminal of the capacitor 53. The other terminal of the capacitor 53 is connected to the other of the source and the drain of the transistor 52F, the anode of the light-emitting element 61, and one of the source and the drain of the transistor 52C. A gate of the transistor 52E and the gate of the transistor 52C are connected to a wiring GL4. The other of the source and the drain of the transistor 52C is connected to the wiring V0. A region where the other of the source and the drain of the transistor 52E, the gate of the transistor 52B, and the one terminal of the capacitor 53 are connected to one another functions as the node ND.

FIG. 28B illustrates a structure in which the back gates of the transistor 52A, the transistor 52C, the transistor 52D, the transistor 52E, and the transistor 52F are connected to the respective gates, and the back gate of the transistor 52B is connected to the other of the source and the drain thereof.

With the use of the transistors of one embodiment of the present invention for a pixel circuit of a display apparatus, the area occupied by the pixel circuit can be reduced. Thus, the resolution of the display apparatus can be improved. For example, a display apparatus with a resolution higher than or equal to 1000 ppi and lower than or equal to 10000 ppi, preferably higher than or equal to 2000 ppi and lower than or equal to 9000 ppi, further preferably higher than or equal to 3000 ppi and lower than or equal to 8000 ppi, still further preferably higher than or equal to 4000 ppi and lower than or equal to 8000 ppi, yet further preferably higher than or equal to 5000 ppi and lower than or equal to 8000 ppi, yet still further preferably higher than or equal to 6000 ppi and lower than or equal to 8000 ppi can be achieved.

The reduction in the area occupied by the pixel circuit can increase the number of pixels of the display apparatus (can increase the definition). For example, a display apparatus with an extremely high definition of HD (number of pixels: 1280×720), FHD (number of pixels: 1920×1080), WQHD (number of pixels: 2560×1440), WQXGA (number of pixels: 2560×1600), 4K 2K (number of pixels: 3840×2160), or 8K4K (number of pixels: 7680×4320) can be achieved.

Accordingly, the use of the transistors of one embodiment of the present invention for a pixel circuit of the display apparatus can increase the display quality of the display apparatus. A bottom-emission display apparatus using an EL element can have a high aperture ratio of a pixel. A pixel with a high aperture ratio can have a lower current density than a pixel with a low aperture ratio when the pixel with a high aperture ratio and the pixel with a low aperture ratio emit light with the same luminance. Thus, the reliability of the display apparatus can be improved.

The structure described in this embodiment can be used in an appropriate combination with any of the structures described in the other embodiments or the example.

### Embodiment 5

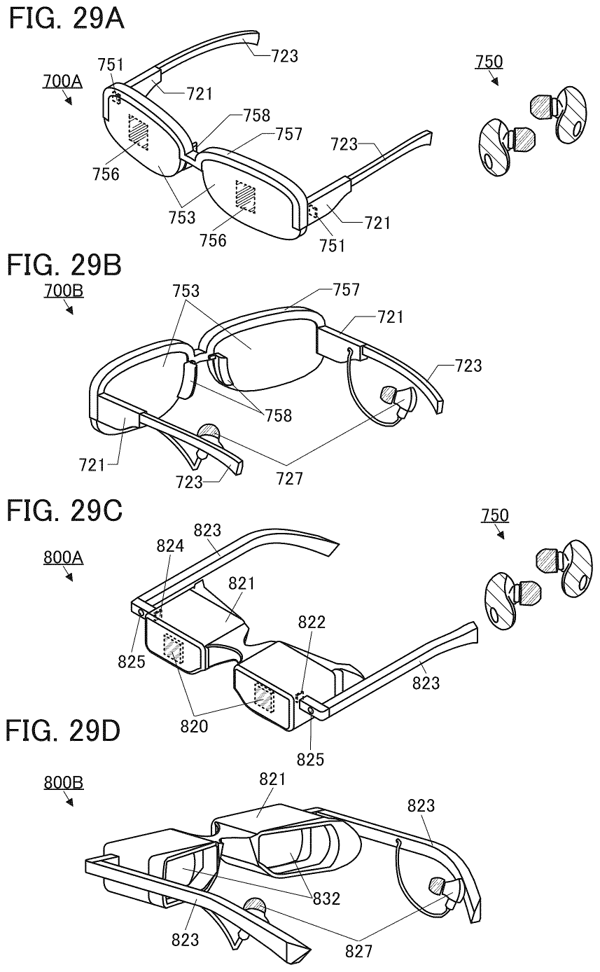

In this embodiment, electronic devices of one embodiment of the present invention will be described with reference to FIG. 29A to FIG. 31G.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for display portions of a variety of electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of such a display apparatus having one or both of a high definition and a high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 29A to FIG. 29D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 29A and an electronic device 700B illustrated in FIG. 29B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with an extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery (not illustrated) so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 29C and an electronic device 800B illustrated in FIG. 29D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with an extremely high resolution. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. FIG. 29C or the like illustrates an example in which the wearing portions 823 have a shape like a temple (also referred to as a joint) of glasses; however, one embodiment of the present invention is not limited thereto. The wearing portions 823 can have any shape with which the user can wear the electronic device, for example, a shape of a helmet or a band.

The image capturing portion 825 has a function of obtaining information on the external environment. Data obtained by the image capturing portion 825 can be output to the display portions 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object is provided. That is, the image capturing portion 825 is one embodiment of the sensing portion. As the sensing portion, an image sensor or a distance image sensor such as LIDAR (Light Detection And Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portions 820, the housing 821, and the wearing portions 823. Thus, without additionally requiring an audio device such as headphones, earphones, or a speaker, the user can enjoy videos and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 29A has a function of transmitting information to the earphones 750 with the wireless communication function. For another example, the electronic device 800A illustrated in FIG. 29C has a function of transmitting information to the earphones 750 with the wireless communication function.

The electronic device may include earphone portions. The electronic device 700B illustrated in FIG. 29B includes earphone portions 727. For example, the earphone portions 727 and the control portion can be connected to each other by wire. Part of a wiring that connects the earphone portions 727 and the control portion may be positioned inside the housing 721 or the wearing portions 723.

Similarly, the electronic device 800B illustrated in FIG. 29D includes earphone portions 827. For example, the earphone portions 827 and the control portion 824 can be connected to each other by wire. Part of a wiring that connects the earphone portions 827 and the control portion 824 may be positioned inside the housing 821 or the wearing portions 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

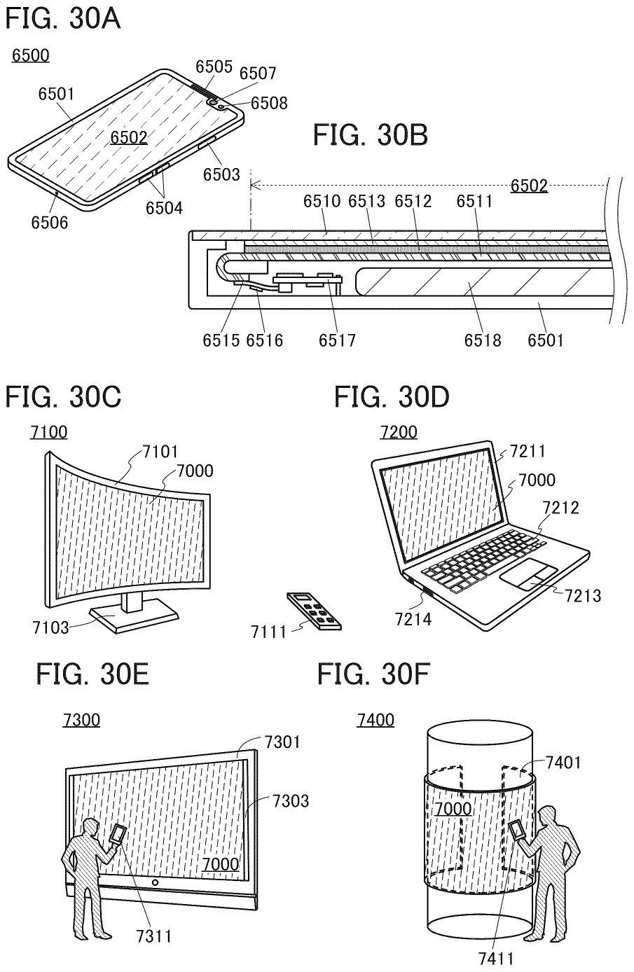

An electronic device 6500 illustrated in FIG. 30A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 30B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted without an increase in the thickness of the electronic device. Moreover, part of the display panel 6511 is folded back such that a connection portion with the FPC 6515 is provided on the back side of the display portion 6502, whereby an electronic device with a narrow bezel can be obtained.

FIG. 30C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000.

The operation of the television device 7100 illustrated in FIG. 30C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 30D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000.

FIG. 30E and FIG. 30F illustrate examples of digital signage.

Digital signage 7300 illustrated in FIG. 30E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 30F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 30E and FIG. 30F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 30E and FIG. 30F, it is preferable that the digital signage 7300 or the digital signage 7400 be capable of working with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

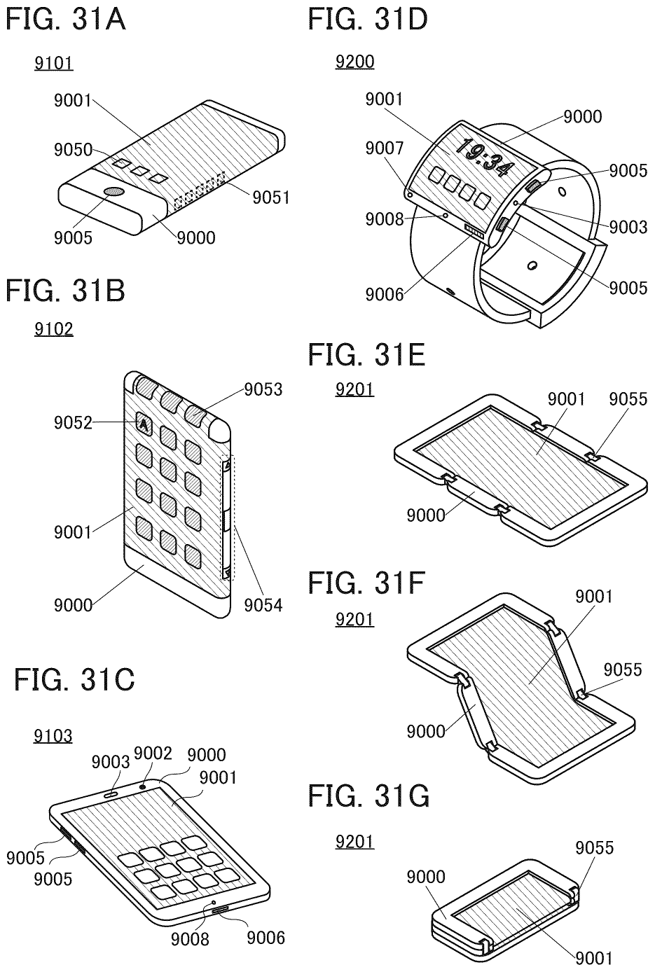

Electronic devices illustrated in FIG. 31A to FIG. 31G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays), a microphone 9008, and the like.

In FIG. 31A to FIG. 31G, the display apparatus of one embodiment of the present invention can be used in the display portion 9001.

The electronic devices illustrated in FIG. 31A to FIG. 31G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a recording medium (an external recording medium or a recording medium incorporated in the camera), a function of displaying the taken image on the display portion, or the like.

The electronic device illustrated in FIG. 31A to FIG. 31G are described in detail below.

FIG. 31A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display characters and image information on its plurality of surfaces. FIG. 31A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 31B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example. FIG. 31C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on left side surface of the housing 9000; and the connection terminal 9006 on the bottom surface of the housing 9000.

FIG. 31D is a perspective view illustrating a watch-type portable information terminal 9200. The portable information terminal 9200 can be used as a Smartwatch (registered trademark), for example. The display surface of the display portion 9001 is curved, and display can be performed along the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 31E to FIG. 31G are perspective views illustrating a foldable portable information terminal 9201. FIG. 31E is a perspective view of an opened state of the portable information terminal 9201, FIG. 31G is a perspective view of a folded state thereof, and FIG. 31F is a perspective view of a state in the middle of change from one of FIG. 31E and FIG. 31G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments or an example as appropriate.

### Example

In this example, a transistor was manufactured with use of the manufacturing method of one embodiment of the present invention and a cross-sectional STEM (Scanning Transmission Electron Microscope) image was observed.

In this example, a sample including the transistor 100C illustrated in FIG. 7A and FIG. 7B were manufactured with use of part of the method illustrated in FIG. 12A to FIG. 14C.

First, a 100-nm-thick copper film was formed over the substrate 102 by a sputtering method, and after the copper film was processed, a 100-nm-thick In—Sn—Si oxide (ITSO) film was formed thereover by a sputtering method, and was processed to obtain the conductive film having the ITSO film, the conductive layer 112a having a stacked-layer structure of copper and ITSO. Note that a glass substrate was used as the substrate 102.

Next, a 100-nm-thick silicon nitride film was formed over the conductive layer 112a and the substrate 102 by a PECVD method to obtain the insulating film 110a1_f.

Then, a 100-nm-thick silicon oxynitride film was formed over the insulating film 110a1_f by a PECVD method to obtain the insulating film 110a2_f.

After that, a 10-nm thick aluminum oxide film was formed over the insulating film 110a2_f by a sputtering method to obtain the insulating film 110a3_f.

Then, a 300-nm-thick aluminum film was formed over the insulating film 110a3_f by a sputtering method and processed to obtain the conductive layer 114_e.

Next, a 20-nm-thick aluminum oxide film was formed over the conductive layer 114_e and the insulating film 110a3_f by a sputtering method to obtain the insulating film 110b3_f.

After that, a 100-nm-thick silicon oxynitride film was formed over the insulating film 110b3_f by a PECVD method to obtain the insulating film 110b2_f.

Next, a 5-nm-thick aluminum oxide film was formed over the insulating film 110b2_f by a sputtering method, and treatment for supplying oxygen to the insulating film 110b2_f was performed.

Then, a 100-nm-thick silicon nitride film was formed over the aluminum oxide film by a PECVD method to obtain the insulating film 110b1_f.

After that, the resist mask 191a was formed over the insulating film 110b1_f.

Then, the insulating film 110b1_f, the insulating film 110b2_f, the insulating film 110b3_f, the conductive layer 114_e, the insulating film 110a3_f, the insulating film 110a2_f, and the insulating film 110a1_f were processed using the resist mask 191a as a mask to form the insulating layer 110b (the insulating layer 110b1, the insulating layer 110b2, and the insulating layer 110b3), the conductive layer 114, and the insulating layer 110a (the insulating layer 110a3, the insulating layer 110a2, and the insulating layer 110a1 ). A dry etching method was used for the processing.

Next, the Resist Mask 191a Was Removed.

Next, a 300-nm-thick silicon oxynitride film was formed over the conductive layer 112a, the insulating layer 110a, the conductive layer 114, and the insulating layer 110b by a PECVD method to obtain the insulating film 110s_f.

Then, the insulating film 110s_f was processed to obtain the insulating layer 110s. A dry etching method was used for the processing.

Next, a 50-nm-thick metal oxide film was formed over the conductive layer 112a, the insulating layer 110s, and the insulating layer 110b. The metal oxide film was formed by a sputtering method using an IGZO sputtering target with an atomic ratio of metal elements of In:Ga:Zn=1:1:1. Note that the substrate temperature at the time of the formation was room temperature, a mixed gas of an oxygen gas and an argon gas was used as a deposition gas, and the oxygen flow rate ratio was 10%.

Next, heat treatment was performed at 350° C. in a dry air atmosphere for one hour.

Then, the metal oxide film was processed to obtain the semiconductor layer 108. A wet etching method was used for the processing.

Then, a 50-nm-thick silicon oxynitride film was formed over the semiconductor layer 108 by a PECVD method to obtain the insulating layer 106.

Next, heat treatment was performed at 350° C. in a dry air atmosphere for one hour.

Then, over the insulating layer 106, a stacked film of a 50-nm-thick titanium film, a 200-nm-thick aluminum film, and a 50-nm-thick titanium film was formed by a sputtering method, and then the stacked film was processed to obtain the conductive layer 104.

Through the above steps, the transistor 100C was manufactured.

Next, a 300-nm-thick silicon nitride oxide film was formed by a PECVD method to cover the manufactured transistor 100C to obtain the insulating layer 195.

Then, heat treatment was performed at 300° C. in a dry air atmosphere for one hour.

Next, a 1.5-μm-thick polyimide resin was formed to cover the insulating layer 195.

Then, heat treatment was performed at 250° C. in a nitrogen atmosphere for one hour.

In the above manner, the sample including the transistor 100C was manufactured.

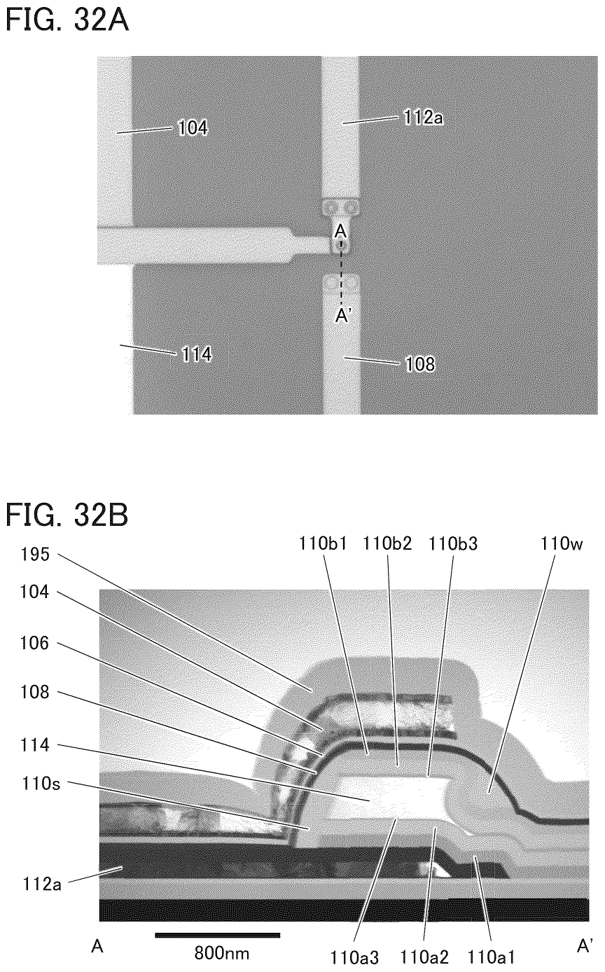

A cross-sectional STEM image of the above sample was taken, and the results are shown in FIG. 32A and FIG. 32B. Here, FIG. 32A is an optical micrograph of the above sample, and FIG. 32B is a cross-sectional STEM image corresponding to the dashed line A-A′ in FIG. 32A. Note that the image of the samples were taken with a scanning transmission electron microscope (STEM) manufactured by Hitachi High-Tech Corporation (model number: HD-2300), with an acceleration voltage of 200 kV.

As shown in FIG. 32B, it was confirmed that the conductive layer 114 was formed over the insulating layer 110a (the insulating layer 110a1, the insulating layer 110a2, and the insulating layer 110a3). It was also confirmed that the insulating layer 110s was formed along the sidewall of the opening in the insulating layer 110b (the insulating layer 110b1, the insulating layer 110b2, and the insulating layer 110b3), the sidewall of the opening in the conductive layer 114, and the sidewall of the opening in the insulating layer 110a. It was also confirmed that the sidewall insulating layer 110w was formed along the side surface of the conductive layer 114, which is opposite to the side surface where the insulating layer 110s was formed, with the insulating layer 110b therebetween, and the semiconductor layer 108 was provided in contact with the top surface of the conductive layer 112a, the side surface of the insulating layer 110s, the top surface of the insulating layer 110b, and the top surface of the sidewall insulating layer 110w. It was also confirmed that the insulating layer 106 and the conductive layer 104 were formed to have shapes along the top surface of the semiconductor layer 108 without being disconnected.

As described above, it was confirmed that the transistor 100C was manufactured by the manufacturing method of one embodiment of the present invention.

This example can be combined with any of the other embodiments as appropriate.

### REFERENCE NUMERALS

11B: subpixel, 11G: subpixel, 11R: subpixel, 50A: display apparatus, 50B: display apparatus, 50C: display apparatus, 50D: display apparatus, 50E: display apparatus, 51: pixel circuit, 51A: pixel circuit, 51B: pixel circuit, 51C: pixel circuit, 51D: pixel circuit, 51E: pixel circuit, 51F: pixel circuit, 51G: pixel circuit, 51H: pixel circuit, 51I: pixel circuit, 51J: pixel circuit, 52A: transistor, 52B: transistor, 52C: transistor, 52D: transistor, 52E: transistor, 52F: transistor, 53: capacitor, 53A: capacitor, 61: light-emitting element, 100: transistor, 100A: transistor, 100B: transistor, 100C: transistor, 100D: transistor, 100E: transistor, 100F: transistor, 100G: transistor, 100H: transistor, 100I: transistor, 100J: transistor, 102: substrate, 104: conductive layer, 106: insulating layer, 108Da: region, 108Db: region, 108I: region, 108L: region, 108: semiconductor layer, 110a: insulating layer, 110a1: insulating layer, 110a1_f: insulating film, 110a2: insulating layer, 110a2_f: insulating film, 110a3: insulating layer, 110a3_f: insulating film, 110b: insulating layer, 110b1: insulating layer, 110b1_f: insulating film, 110b2: insulating layer, 110b2_f: insulating film, 110b3: insulating layer, 110b3_f: insulating film, 110g: insulating layer, 110s: insulating layer, 110s1: insulating layer, 110s2: insulating layer, 110s_f: insulating film, 110w: sidewall insulating layer, 111B: pixel electrode, 111G: pixel electrode, 111R: pixel electrode, 111S: pixel electrode, 111: pixel electrode, 112a: conductive layer, 112a_1: conductive layer, 112a_2: conductive layer, 112b: conductive layer, 112b_e: conductive layer, 112b_f: conductive film, 113B: EL layer, 113G: EL layer, 113R: EL layer, 113S: functional layer, 113: EL layer, 114_e: conductive layer, 114: conductive layer, 115: insulating layer, 117: light-blocking layer, 123: conductive layer, 124B: conductive layer, 124G: conductive layer, 124R: conductive layer, 125: insulating layer, 126B: conductive layer, 126G: conductive layer, 126R: conductive layer, 127: insulating layer, 128: layer, 129: layer, 130B: light-emitting element, 130G: light-emitting element, 130R: light-emitting element, 130S: light-receiving element, 131: protective layer, 132B: coloring layer, 132G: coloring layer, 132R: coloring layer, 133B: layer, 133G: layer, 133R: layer, 134: common layer, 135: common electrode, 140: connection portion, 141: sidewall, 142: opening, 143: opening, 149: adhesive layer, 150: region, 151: substrate, 152: substrate, 153: insulating layer, 161: region, 162: region, 164: circuit portion, 165: wiring, 166: conductive layer, 167: conductive layer, 168: display portion, 170: substrate, 171: adhesive layer, 172: FPC, 173: IC, 190: impurity, 191a: resist mask, 191b: resist mask, 195: insulating layer, 196: insulating layer, 200A: display apparatus, 200B: display apparatus, 200C: display apparatus, 200: display apparatus, 204: connection portion, 205B: transistor, 205D: transistor, 205G: transistor, 205R: transistor, 205S: transistor, 210: pixel, 230: pixel, 235: insulating layer, 237: insulating layer, 240: capacitor, 241: conductive layer, 242: connection layer, 243: insulating layer, 245: conductive layer, 254: insulating layer, 255a: insulating layer, 255b: insulating layer, 255c: insulating layer, 256: plug, 266: insulating layer, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 320A: transistor, 320B: transistor, 320: transistor, 331: substrate, 332: insulating layer, 350: insulating layer, 351: semiconductor layer, 352: insulating layer, 353: insulating layer, 354: conductive layer, 355: conductive layer, 356: insulating layer, 357: conductive layer, 358: insulating layer, 359: insulating layer, 431: first driver circuit portion, 432: second driver circuit portion, 433: peripheral driver circuit, 435: display portion, 436: wiring, 437: wiring, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: a speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: a speaker, 7311: information terminal, 7400: digital signage, 7401: pillar, 7411: information terminal, 9000: housing, 9001: display portion, 9002: camera, 9003: a speaker, 9005: control key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a semiconductor layer, a first conductive layer, a second conductive layer, a third conductive layer, a fourth conductive layer, a first insulating layer, a second insulating layer, a third insulating layer, and a fourth insulating layer,
wherein the first insulating layer is over the first conductive layer,
wherein the second conductive layer is over the first insulating layer and comprises a first opening overlapping with the first conductive layer,
wherein the second insulating layer is over the second conductive layer,
wherein the third conductive layer is over the second insulating layer and comprises a second opening overlapping with the first opening,
wherein the third insulating layer is in contact with a sidewall of the first opening,
wherein the semiconductor layer is over the first conductive layer, the third insulating layer, and the third conductive layer and comprises a first region in contact with a top surface of the first conductive layer, a second region in contact with a side surface of the third insulating layer, and a third region in contact with a top surface of the third conductive layer,
wherein the fourth insulating layer is over the semiconductor layer,
wherein the fourth conductive layer is over the fourth insulating layer and faces the second conductive layer with the fourth insulating layer, the semiconductor layer, and the third insulating layer therebetween, and
wherein the second region has a higher resistance than one or both of the first region and the third region.

2. The semiconductor device according to claim 1, wherein the semiconductor layer comprises a metal oxide.

3. The semiconductor device according to claim 1, wherein each of the first insulating layer and the second insulating layer comprises one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride.

4. The semiconductor device according to claim 1,
wherein the third insulating layer comprises a fifth insulating layer and a sixth insulating layer,
wherein the fifth insulating layer is in contact with the sidewall of the first opening and comprises one or more of silicon nitride, silicon nitride oxide, hafnium oxide, and aluminum oxide, and
wherein the sixth insulating layer is over the fifth insulating layer to face the sidewall of the first opening with the fifth insulating layer therebetween and comprises one or more of silicon oxide and silicon oxynitride.

5. A semiconductor device comprising:
a semiconductor layer, a first conductive layer, a second conductive layer, a third conductive layer, a first insulating layer, a second insulating layer, a third insulating layer, and a fourth insulating layer,
wherein the first insulating layer is over the first conductive layer,
wherein the second conductive layer is over the first insulating layer and comprises an opening overlapping with the first conductive layer,
wherein the second insulating layer is over the second conductive layer,
wherein the third insulating layer is in contact with a sidewall of the opening,
wherein the semiconductor layer is over the first conductive layer and the third insulating layer, is in contact with a top surface of the first conductive layer, a side surface of the third insulating layer, and a top surface of the second insulating layer, and comprises a region extending beyond the first conductive layer and the second conductive layer in a plan view,
wherein the fourth insulating layer is over the semiconductor layer, and
wherein the third conductive layer is over the fourth insulating layer and faces the second conductive layer with the fourth insulating layer, the semiconductor layer, and the third insulating layer therebetween.

6. The semiconductor device according to claim 5, wherein the semiconductor layer comprises a metal oxide.

7. The semiconductor device according to claim 5, wherein each of the first insulating layer and the second insulating layer comprises one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride.

8. The semiconductor device according to claim 5,
wherein the third insulating layer comprises a fifth insulating layer and a sixth insulating layer,
wherein the fifth insulating layer is in contact with the sidewall of the opening and comprises one or more of silicon nitride, silicon nitride oxide, hafnium oxide, and aluminum oxide, and
wherein the sixth insulating layer is over the fifth insulating layer to face the sidewall of the opening with the fifth insulating layer therebetween and comprises one or more of silicon oxide and silicon oxynitride.

9. A semiconductor device comprising:
a semiconductor layer, a first conductive layer, a second conductive layer, a first insulating layer, a second insulating layer, and a third insulating layer,
wherein the first insulating layer is over the first conductive layer,
wherein the second conductive layer is over the first insulating layer and comprises an opening overlapping with the first conductive layer,
wherein the second insulating layer is over the second conductive layer,
wherein the third insulating layer is in contact with a sidewall of the opening, and
wherein the semiconductor layer is over the first conductive layer and the third insulating layer, is in contact with a top surface of the first conductive layer, a side surface of the third insulating layer, and a top surface of the second insulating layer, comprises a region extending beyond the first conductive layer and the second conductive layer in a plan view, and faces the second conductive layer with the third insulating layer therebetween.

10. The semiconductor device according to claim 9, wherein the semiconductor layer comprises a metal oxide.

11. The semiconductor device according to claim 9, wherein each of the first insulating layer and the second insulating layer comprises one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride.

12. The semiconductor device according to claim 9,
wherein the third insulating layer comprises a fourth insulating layer and a fifth insulating layer,
wherein the fourth insulating layer is in contact with the sidewall of the opening and comprises one or more of silicon nitride, silicon nitride oxide, hafnium oxide, and aluminum oxide, and
wherein the fifth insulating layer is over the fourth insulating layer to face the sidewall of the opening with the fourth insulating layer therebetween and comprises one or more of silicon oxide and silicon oxynitride.

13. (canceled)

14. (canceled)
